(19) United States
(12) Patent Application Publication
(10) Pub. No.: US 2016/0303829 A1
(43) Pub. Date: Oct. 20, 2016

(54) Surface Treated Copper Foil, Copper Clad Laminate, Printed Wiring Board, Electronic Apparatus and Method for Manufacturing Printed Wiring Board

(71) Applicant: JX NIPPON MINING & METALS CORPORATION, Tokyo (JP)

(72) Inventors: Hideta Arai, Ibaraki (JP); Atsushi Miki, Ibaraki (JP); Kohsuke Arai, Ibaraki (JP); Kaichiro Nakamuro, Ibaraki (JP)

(73) Assignee: JX Nippon Mining & Metals Corporation, Tokyo (JP)

(21) Appl. No.: 15/103,318

(22) PCT Filed: Dec. 10, 2014
(86) PCT No.: PCT/JP2014/082765

§ 371 Date: Jun. 10, 2016

(30) Foreign Application Priority Data
Dec. 10, 2013 (JP) 2013-255464

(51) Int. Cl. B32B 15/08; B32B 15/20; B32B 27/28; H05K 3/38; H05K 1/09; H05K 1/03; H05K 3/36; H05K 3/30; B32B 5/14; C25D 5/16

(52) U.S. Cl. CPC B32B 15/08; B32B 5/147; B32B 15/20; B32B 27/281; C25D 5/16; H05K 1/09; H05K 1/0346; H05K 3/36; H05K 3/30; H05K 3/384; B32B 2457/08; B32B 2307/412; H05K 2201/0154; H05K 2203/0307; H05K 2201/0108; H05K 2203/16

(57) ABSTRACT

A surface treated copper foil which allows the resin to have excellent transparency after removal of the copper foil by etching is provided. The surface treated copper foil has one surface and other surface each surface treated. An Sv defined by the following expression (1) is 3.5 or more:

Sv=(ΔB×0.1)/(t1−t2) (1)

which is determined, after laminating one surface to each of both surfaces of a polyimide resin substrate, removing the copper foil on each of both surfaces by etching, and photographing a printed matter with a linear mark, from the resulting observation spot versus brightness graph; and the surface treated other surface of the copper foil has a TD ten-spot average roughness Rz measured with a laser microscope using laser light having a wavelength of 405 nm, of 0.35 μm or more.

### TECHNICAL FIELD

The present invention relates to a surface treated copper foil, a copper clad laminate, a printed wiring board, an electronic apparatus and a method for manufacturing a printed wiring board, and more specifically, a surface treated copper foil, a copper clad laminate, a printed wiring board, an electronic apparatus and a method for manufacturing a printed wiring board, suitable for applications where transparency of a resin which remains after etching a copper foil is required.

### BACKGROUND ART

A flexible printed wiring board (hereinafter referred to as FPC) is employed in a compact electronic apparatus such as a smart phone and a tablet PC due to the easiness of wiring and the lightness. Due to the recent improvement of functionality of electronic apparatuses, the signal transmission rate has been accelerated, so that impedance matching is an important factor even for an FPC. In order to achieve impedance matching for the increased signal capacity, a resin insulating layer (e.g., polyimide) as the base of an FPC has been thickened. In order to meet the demand for densification of wirings, multilayering of an FPC has been further developed. On the other hand, when an FPC is processed for bonding to a liquid crystal substrate and mounting an IC chip, alignment is performed with a positioning pattern which is visually recognized through a resin insulating layer remained after etching of the copper foil of a laminate composed of the copper foil and the resin insulating layer. The visibility of the resin insulating layer is therefore important.

A copper clad laminate composed of a laminate of a copper foil and a resin insulating layer may be manufactured from a rolled copper foil having a roughened plated surface. The rolled copper foil is usually manufactured from tough pitch copper (oxygen content: 100 to 500 ppm by weight) or oxygen-free copper (oxygen content: 10 ppm by weight or less) as a raw material ingot, which is hot rolled and then subjected to repeated cold rolling and annealing to a predetermined thickness.

Examples of the techniques include the followings. Patent Literature 1 discloses an invention of a copper clad laminate of a polyimide film and a low profile copper foil, which allows a film after etching of the copper foil to have a light transmittance of 40% or more at a wavelength of 600 nm, with a haze value (HAZE) of 30% or less and an adhesive strength of 500 N/m or more.

Patent Literature 2 discloses an invention of a chip on flexible (COF) flexible printed wiring board having an insulating layer on which a conductive layer of electrolytic copper foil is laminated, allowing the insulating layer in an etched region after circuit formation by etching of the conductive layer to have a light transmittance of 50% or more. The electrolytic copper foil includes a rustproof layer of nickel-zinc alloy at the joint area bonded to the insulating layer. The joint area has a surface roughness (Rz) of 0.05 to 1.5 μm and a specular gloss of 250 or more at an incident angle of 60°.

Patent Literature 3 discloses an invention of a method for processing a copper foil for a printed circuit, including forming a cobalt-nickel alloy plated layer after surface roughening treatment of the copper foil surface by plating with a copper-cobalt-nickel alloy, and further forming a zinc-nickel alloy plated layer.

### CITATION LIST

### Patent Literature

### [Patent Literature 1]

Japanese Patent Laid-Open No. 2004-98659

### [Patent Literature 2]

International Publication No. WO 2003/096776

### [Patent Literature 3]

Japanese Patent No. 2849059

### SUMMARY OF INVENTION

### Technical Problem

In Patent Literature 1, the adhesiveness of a low profile copper foil is improved by blackening treatment or with an organic treating agent after plating treatment. The copper foil causes disconnection due to fatigue in some cases for use in need of flexibility of a copper clad laminate, and has poor transparency of a resin in some cases.

In Patent Literature 2, since no roughening treatment is performed, the adhesion strength between a copper foil and a resin is low and insufficient for use other than as a COF flexible printed wiring board.

Furthermore, although a treatment method according to Patent Literature 3 allows for fining of a copper foil with Cu—Co—Ni, a resin bonded to the copper foil has insufficient transparency after removal of the copper foil by etching.

The present invention provides a surface treated copper foil which allows the resin to have excellent transparency after removal of the copper foil by etching.

### Solution to Problem

As a result of earnest research effort, the present inventors found that the transparency of a resin after removal of a copper foil by etching is affected without influence of the type and the thickness of a substrate resin film by the following. A surface treated copper foil is subjected to a predetermined surface treatment. The surface treated surface of the copper foil is laminated and removed so as to form a polyimide substrate, under which a marked printed matter is placed. The printed matter is photographed through the polyimide substrate with a CCD camera. A graph of observation spot versus brightness is produced from the image of the marked part. An attention is paid to the gradient of the brightness curve drawn in the graph in the vicinity of the end of the mark such that the gradient of the brightness curve is controlled.

An aspect of the present invention accomplished based on the finding is a surface treated copper foil having one surface and other surface each surface treated, wherein an Sv defined by the following expression (1) is 3.5 or more based on a brightness curve:

Sv=(ΔB×0.1)/(t1−t2) (1)

wherein the brightness curve is obtained, after laminating one surface of the copper foil to each of both surfaces of a polyimide resin substrate, removing the copper foil on each of both surfaces by etching, placing a printed matter with a linear mark under the exposed polyimide resin substrate, and photographing the printed matter through the polyimide resin substrate with a CCD camera, from an observation spot versus brightness graph of measurement results of the brightness of the photographed image of the printed matter for the respective observation spots along the direction perpendicular to the extending direction of the observed linear mark, and the difference between the top average Bt and the bottom average Bb in the brightness curve extending from an end of the mark to a portion without the mark is represented by ΔB (ΔB=Bt−Bb), and wherein t1 represents a value pointing the position of the intersection closest to the linear mark among the intersections of the brightness curve and Bt in the observation spot versus brightness graph, and t2 represents a value pointing the position of the intersection closest to the linear mark among the intersections of the brightness curve and 0.1ΔB in the range from the intersections of the brightness curve and Bt to a depth of 0.1ΔB with Bt as reference; and

wherein the surface treated other surface of the copper foil has a TD ten-spot average roughness Rz measured with a laser microscope using laser light having a wavelength of 405 nm, of 0.35 μm or more.

One embodiment of the surface treated copper foil of the present invention, the surface treated other surface of the copper foil has a TD arithmetic average roughness Ra measured with a laser microscope using laser light having a wavelength of 405 nm, of 0.05 μm or more.

Another aspect of the present invention is a surface treated copper foil having one surface and other surface each surface treated,

wherein an Sv defined by the following expression (1) is 3.5 or more based on a brightness curve:

Sv=(ΔB×0.1)/(t1−t2) (1)

wherein the brightness curve is obtained, after laminating one surface of the copper foil to each of both surfaces of a polyimide resin substrate, removing the copper foil on each of both surfaces by etching, placing a printed matter with a linear mark under the exposed polyimide resin substrate, and photographing the printed matter through the polyimide resin substrate with a CCD camera, from an observation spot versus brightness graph of measurement results of the brightness of the photographed image of the printed matter for the respective observation spots along the direction perpendicular to the extending direction of the observed linear mark, and the difference between the top average Bt and the bottom average Bb in the brightness curve extending from an end of the mark to a portion without the mark is represented by ΔB (ΔB=Bt−Bb), and wherein t1 represents a value pointing the position of the intersection closest to the linear mark among the intersections of the brightness curve and Bt in the observation spot versus brightness graph, and t2 represents a value pointing the position of the intersection closest to the linear mark among the intersections of the brightness curve and 0.1ΔB in the range from the intersections of the brightness curve and Bt to a depth of 0.1ΔB with Bt as reference; and

wherein the surface treated other surface of the copper foil has a TD arithmetic average roughness Ra measured with a laser microscope using laser light having a wavelength of 405 nm, of 0.05 μm or more.

In another embodiment of the surface treated copper foil of the present invention, the surface treated other surface of the copper foil has a TD root mean square height Rq measured with a laser microscope using laser light having a wavelength of 405 nm, of 0.08 μm or more.

Further another aspect of the present invention is a surface treated copper foil having one surface and other surface each surface treated,

wherein an Sv defined by the following expression (1) is 3.5 or more based on a brightness curve:

Sv=(ΔB×0.1)/(t1−t2) (1)

wherein the brightness curve is obtained, after laminating one surface of the copper foil to each of both surfaces of a polyimide resin substrate, removing the copper foil on each of both surfaces by etching, placing a printed matter with a linear mark under the exposed polyimide resin substrate, and photographing the printed matter through the polyimide resin substrate with a CCD camera, from an observation spot versus brightness graph of measurement results of the brightness of the photographed image of the printed matter for the respective observation spots along the direction perpendicular to the extending direction of the observed linear mark, and the difference between the top average Bt and the bottom average Bb in the brightness curve extending from an end of the mark to a portion without the mark is represented by ΔB (ΔB=Bt−Bb), and wherein t1 represents a value pointing the position of the intersection closest to the linear mark among the intersections of the brightness curve and Bt in the observation spot versus brightness graph, and t2 represents a value pointing the position of the intersection closest to the linear mark among the intersections of the brightness curve and 0.1ΔB in the range from the intersections of the brightness curve and Bt to a depth of 0.1ΔB with Bt as reference; and

wherein the surface treated other surface of the copper foil has a TD root mean square height Rq measured with a laser microscope using laser light having a wavelength of 405 nm, of 0.08 μm or more.

In further another embodiment of the surface treated copper foil of the present invention, the surface treatment of the other surface is a roughening treatment.

In further another embodiment of the surface treated copper foil of the present invention, the difference between the top average Bt and the bottom average Bb in the brightness curve extending from the end of the mark to the portion without the mark ΔB (ΔB=Bt−Bb) is 40 or more.

In another embodiment of the surface treated copper foil of the present invention, ΔB in the observation spot versus brightness graph produced from the photographed image is 50 or more.

In further another embodiment of the surface treated copper foil of the present invention, the Sv defined by the expression (1) in the brightness curve is 3.9 or more.

In further another embodiment of the surface treated copper foil of the present invention, the Sv defined by the expression (1) in the brightness curve is 5.0 or more.

In further another embodiment of the surface treated copper foil of the present invention, the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughened grains to the area B of the roughened grains shown in the plan view from one surface side of the copper foil is 1.90 to 2.40.

In further another embodiment of the surface treated copper foil of the present invention, the MD glossiness at 60 degrees is 90 to 250%.

In further another embodiment of the surface treated copper foil of the present invention, the one surface has a TD ten-spot average roughness Rz measured with a contact roughness measuring tester, of 0.30 to 0.60 μm.

In further another embodiment of the surface treated copper foil of the present invention, the A/B is 2.00 to 2.20.

In further another embodiment of the surface treated copper foil of the present invention, the roughening treated surface has a ratio F of the MD glossiness at 60 degrees to the TD glossiness at 60 degrees (F=(MD glossiness at 60 degrees)/(TD glossiness at 60 degrees)) of 0.80 to 1.40.

In further another embodiment of the surface treated copper foil of the present invention, the roughening treated surface has a ratio F of the MD glossiness at 60 degrees to the TD glossiness at 60 degrees (F=(MD glossiness at 60 degrees)/(TD glossiness at 60 degrees)) of 0.90 to 1.35.

In further another embodiment of the surface treated copper foil of the present invention, the one surface has a root mean square height Rq of 0.14 to 0.63 μm.

In further another embodiment of the surface treated copper foil of the present invention, the one surface has a root mean square height Rq of 0.25 to 0.60 μm.

In further another embodiment of the surface treated copper foil of the present invention, the one surface has a skewness Rsk of −0.35 to 0.53 based on JIS B 0601-2001.

In further another embodiment of the surface treated copper foil of the present invention, the one surface has a skewness Rsk of −0.30 to 0.39.

In further another embodiment of the surface treated copper foil of the present invention, the ratio E/G of the volume E of the projection portion of the surface treated surface to the surface area G of the one surface shown in plan view is 2.11 to 23.91.

In further another embodiment of the surface treated copper foil of the present invention, the ratio E/G is 2.95 to 21.42.

In further another embodiment of the surface treated copper foil of the present invention, the one surface has a TD ten-spot average roughness Rz measured with a contact roughness measuring tester, of 0.20 to 0.64 μm.

In further another embodiment of the surface treated copper foil of the present invention, the one surface has a TD ten-spot average roughness Rz measured with a contact roughness measuring tester, of 0.40 to 0.62 μm.

In further another embodiment of the surface treated copper foil of the present invention, the one surface has a ratio D/C of the three-dimensional surface area D to the two-dimensional surface area (the surface area of the surface in plan view) C of 1.0 to 1.7.

In further another embodiment of the surface treated copper foil of the present invention, the D/C is 1.0 to 1.6.

Further another aspect of the present invention is a copper clad laminate comprising a lamination of the surface treated copper foil of the present invention and a resin substrate.

Further another aspect of the present invention is a printed wiring board comprising the surface treated copper foil of the present invention.

Further another aspect of the present invention is an electronic apparatus comprising the printed wiring board of the present invention.

Further another aspect of the present invention is a method for manufacturing a printed wiring board having two or more connected printed wiring boards comprising connecting two or more of the printed wiring boards of the present invention.

Further another aspect of the present invention is a method for manufacturing a printed wiring board having two or more connected printed wiring boards comprising the step of connecting at least one printed wiring board of the present invention to another printed wiring board of the present invention or to a printed wiring board other than the printed wiring board of the present invention.

Further another aspect of the present invention is an electronic apparatus comprising at least one printed wiring board connected to at least one printed wiring board of the present invention.

Further another aspect of the present invention is a method for manufacturing a printed wiring board, comprising at least the step of connecting the printed wiring board of the present invention to a component.

Further another aspect of the present invention is a method for manufacturing a printed wiring board having two or more connected printed wiring boards, comprising at least the step of connecting at least one printed wiring board of the present invention to another printed wiring board of the present invention or to a printed wiring board other than the printed wiring board of the present invention, and the step of connecting the printed wiring board of the present invention or a printed wiring board having two or more of the connected printed wiring boards of the present invention to a component.

Further another aspect of the present invention is a printed wiring board having an insulating resin substrate and a copper circuit arranged on the insulating resin substrate,

wherein the copper circuit has one surface facing the insulating resin substrate and other surface treated surface;
wherein an Sv defined by the following expression (1) is 3.5 or more based on a brightness curve:

Sv=(ΔB×0.1)/(t1−t2) (1)

wherein the brightness curve is obtained, in photographing the copper circuit through the insulating resin substrate with a CCD camera, from an observation spot versus brightness graph of measurement results of the brightness of the photographed image of the copper circuit for the respective observation spots along the direction perpendicular to the extending direction of the observed copper circuit, the top average and the bottom average in the brightness curve extending from an end of the copper circuit to a portion without the copper circuit are represented by Bt and Bb, respectively, and the difference between the top average Bt and the bottom average Bb is represented by ΔB (ΔB=Bt−Bb), and wherein t1 represents a value pointing the position of the intersection closest to the copper circuit among the intersections of the brightness curve and Bt in the observation spot versus brightness graph, and t2 represents a value pointing the position of the intersection closest to the copper circuit among the intersections of the brightness curve and 0.1ΔB in the range from the intersections of the brightness curve and Bt to a depth of 0.1ΔB with Bt as reference; and

wherein the surface treated other surface of the copper circuit has a TD ten-spot average roughness Rz measured with a laser microscope using laser light having a wavelength of 405 nm, of 0.35 μm or more.

In another embodiment of the printed wiring board of the present invention, the surface treated other surface of the copper foil has a TD arithmetic average roughness Ra measured with a laser microscope using laser light having a wavelength of 405 nm, of 0.05 μm or more.

Further another aspect of the present invention is a printed wiring board having an insulating resin substrate and a copper circuit arranged on the insulating resin substrate,

wherein the copper circuit has one surface facing the insulating resin substrate and other surface treated surface;
wherein an Sv defined by the following expression (1) is 3.5 or more based on a brightness curve:

Sv=(ΔB×0.1)/(t1−t2) (1)

wherein the brightness curve is obtained, in photographing the copper circuit through the insulating resin substrate with a CCD camera, from an observation spot versus brightness graph of measurement results of the brightness of the photographed image of the copper circuit for the respective observation spots along the direction perpendicular to the extending direction of the observed copper circuit, the top average and the bottom average in the brightness curve extending from an end of the copper circuit to a portion without the copper circuit are represented by Bt and Bb, respectively, and the difference between the top average Bt and the bottom average Bb is represented by ΔB (ΔB=Bt−Bb), and wherein t1 represents a value pointing the position of the intersection closest to the copper circuit among the intersections of the brightness curve and Bt in the observation spot versus brightness graph, and t2 represents a value pointing the position of the intersection closest to the copper circuit among the intersections of the brightness curve and 0.1ΔB in the range from the intersections of the brightness curve and Bt to a depth of 0.1ΔB with Bt as reference; and

wherein the surface treated other surface of the copper circuit has a TD arithmetic average roughness Ra measured with a laser microscope using laser light having a wavelength of 405 nm, of 0.05 μm or more.

In further another embodiment of the printed wiring board of the present invention, the surface treated other surface of the copper foil has a TD root mean square height Rq measured with a laser microscope using laser light having a wavelength of 405 nm, of 0.08 μm or more.

Further another aspect of the present invention is a printed wiring board having an insulating resin substrate and a copper circuit arranged on the insulating resin substrate,

wherein the copper circuit has one surface facing the insulating resin substrate and other surface treated surface;
wherein an Sv defined by the following expression (1) is 3.5 or more based on a brightness curve:

Sv=(ΔB×0.1)/(t1−t2) (1)

wherein the brightness curve is obtained, in photographing the copper circuit through the insulating resin substrate with a CCD camera, from an observation spot versus brightness graph of measurement results of the brightness of the photographed image of the copper circuit for the respective observation spots along the direction perpendicular to the extending direction of the observed copper circuit, the top average and the bottom average in the brightness curve extending from an end of the copper circuit to a portion without the copper circuit are represented by Bt and Bb, respectively, and the difference between the top average Bt and the bottom average Bb is represented by ΔB (ΔB=Bt−Bb), and wherein t1 represents a value pointing the position of the intersection closest to the copper circuit among the intersections of the brightness curve and Bt in the observation spot versus brightness graph, and t2 represents a value pointing the position of the intersection closest to the copper circuit among the intersections of the brightness curve and 0.1ΔB in the range from the intersections of the brightness curve and Bt to a depth of 0.1ΔB with Bt as reference; and

wherein the surface treated other surface of the copper circuit has a TD root mean square height Rq measured with a laser microscope using laser light having a wavelength of 405 nm, of 0.08 μm or more.

In further another embodiment of the printed wiring board of the present invention, the surface treatment of the other surface is a roughening treatment.

Further another aspect of the present invention is a copper clad laminate having an insulating resin substrate and a copper foil arranged on the insulating resin substrate,

wherein the copper foil has one surface facing the insulating resin substrate and other surface treated surface;
wherein an Sv defined by the following expression (1) is 3.5 or more based on a brightness curve:

Sv=(ΔB×0.1)/(t1−t2) (1)

wherein the brightness curve is obtained, after etching the copper foil of the copper clad laminate to provide a linear copper foil, and photographing the linear copper foil through the insulating resin substrate with a CCD camera, from an observation spot versus brightness graph of measurement results of the brightness of the photographed image of the linear copper foil for the respective observation spots along the direction perpendicular to the extending direction of the observed linear copper foil, the top average and the bottom average in the brightness curve extending from an end of the linear copper foil to a portion without the linear copper foil are represented by Bt and Bb, respectively, and the difference between the top average Bt and the bottom average Bb is represented by ΔB (ΔB=Bt−Bb), and wherein t1 represents a value pointing the position of the intersection closest to the surface treated linear copper foil among the intersections of the brightness curve and Bt in the observation spot versus brightness graph, and t2 represents a value pointing the position of the intersection closest to the surface treated linear copper foil among the intersections of the brightness curve and 0.1ΔB in the range from the intersections of the brightness curve and Bt to a depth of 0.1ΔB with Bt as reference; and

wherein the surface treated other surface of the copper foil has a TD ten-spot average roughness Rz measured with a laser microscope using laser light having a wavelength of 405 nm, of 0.35 μm or more.

In one embodiment of the copper clad laminate of the present invention, the surface treated other surface of the copper foil has a TD arithmetic average roughness Ra measured with a laser microscope using laser light having a wavelength of 405 nm, of 0.05 μm or more.

Further another aspect of the present invention is a copper clad laminate having an insulating resin substrate and a copper foil arranged on the insulating resin substrate,

wherein the copper foil has one surface facing the insulating resin substrate and other surface treated surface;
wherein an Sv defined by the following expression (1) is 3.5 or more based on a brightness curve:

Sv=(ΔB×0.1)/(t1−t2) (1)

wherein the brightness curve is obtained, after etching the copper foil of the copper clad laminate to provide a linear copper foil, and photographing the linear copper foil through the insulating resin substrate with a CCD camera, from an observation spot versus brightness graph of measurement results of the brightness of the photographed image of the linear copper foil for the respective observation spots along the direction perpendicular to the extending direction of the observed linear copper foil, the top average and the bottom average in the brightness curve extending from an end of the linear copper foil to a portion without the linear copper foil are represented by Bt and Bb, respectively, and the difference between the top average Bt and the bottom average Bb is represented by ΔB (ΔB=Bt−Bb), and wherein t1 represents a value pointing the position of the intersection closest to the surface treated linear copper foil among the intersections of the brightness curve and Bt in the observation spot versus brightness graph, and t2 represents a value pointing the position of the intersection closest to the surface treated linear copper foil among the intersections of the brightness curve and 0.1ΔB in the range from the intersections of the brightness curve and Bt to a depth of 0.1ΔB with Bt as reference; and

wherein the surface treated other surface of the copper foil has a TD arithmetic average roughness Ra measured with a laser microscope using laser light having a wavelength of 405 nm, of 0.05 μm or more.

In another embodiment of the copper clad laminate of the present invention, the surface treated other surface of the copper foil has a TD root mean square height Rq measured with a laser microscope using laser light having a wavelength of 405 nm, of 0.08 μm or more.

Further another aspect of the present invention is a copper clad laminate having an insulating resin substrate and a copper foil arranged on the insulating resin substrate,

wherein the copper foil has one surface facing the insulating resin substrate and other surface treated surface;
wherein an Sv defined by the following expression (1) is 3.5 or more based on a brightness curve:

Sv=(ΔB×0.1)/(t1−t2) (1)

wherein the brightness curve is obtained, after etching the copper foil of the copper clad laminate to provide a linear copper foil, and photographing the linear copper foil through the insulating resin substrate with a CCD camera, from an observation spot versus brightness graph of measurement results of the brightness of the photographed image of the linear copper foil for the respective observation spots along the direction perpendicular to the extending direction of the observed linear copper foil, the top average and the bottom average in the brightness curve extending from an end of the linear copper foil to a portion without the linear copper foil are represented by Bt and Bb, respectively, and the difference between the top average Bt and the bottom average Bb is represented by ΔB (ΔB=Bt−Bb), and wherein t1 represents a value pointing the position of the intersection closest to the surface treated linear copper foil among the intersections of the brightness curve and Bt in the observation spot versus brightness graph, and t2 represents a value pointing the position of the intersection closest to the surface treated linear copper foil among the intersections of the brightness curve and 0.1ΔB in the range from the intersections of the brightness curve and Bt to a depth of 0.1ΔB with Bt as reference; and

wherein the surface treated other surface of the copper foil has a TD root mean square height Rq measured with a laser microscope using laser light having a wavelength of 405 nm, of 0.08 μm or more.

In further another embodiment of the copper clad laminate of the present invention, the surface treatment of the other surface is a roughening treatment.

Further another aspect of the present invention is a printed wiring board manufactured with the copper clad laminate of the present invention.

### Advantageous Effects of Invention

The present invention can provide a surface treated copper foil which allows the resin to have excellent transparency after removal of the copper foil by etching.

### BRIEF DESCRIPTION OF DRAWINGS

FIG. 1 is a schematic diagram for defining Bt and Bb.

FIG. 2 is a schematic diagram for defining t1, t2, and Sv.

FIG. 3 is a schematic diagram illustrating the constitution of a photographic device and a method for measuring the gradient of a brightness curve for evaluation of the gradient of the brightness curve.

FIG. 4a is a SEM observation photograph of the copper foil surface in Example B3-1 for evaluating Rz.

FIG. 4b is a SEM observation photograph of the copper foil surface in Example A3-1 for evaluating Rz.

FIG. 4c is a SEM observation photograph of the copper foil surface in Example A3-2 for evaluating Rz.

FIG. 4d is a SEM observation photograph of the copper foil surface in Example A3-3 for evaluating Rz.

FIG. 4e is a SEM observation photograph of the copper foil surface in Example A3-4 for evaluating Rz.

FIG. 4f is a SEM observation photograph of the copper foil surface in Example A3-5 for evaluating Rz.

FIG. 4g is a SEM observation photograph of the copper foil surface in Example A3-6 for evaluating Rz.

FIG. 4h is a SEM observation photograph of the copper foil surface in Example A3-7 for evaluating Rz.

FIG. 4i is a SEM observation photograph of the copper foil surface in Example A3-8 for evaluating Rz.

FIG. 4j is a SEM observation photograph of the copper foil surface in Example A3-9 for evaluating Rz.

FIG. 4k is a SEM observation photograph of the copper foil surface in Example B4-2 for evaluating Rz.

FIG. 4l is a SEM observation photograph of the copper foil surface in Example B4-3 for evaluating Rz.

FIG. 5 is a schematic view of a surface profile of polyimide (PI) after etching a copper foil for both of a positive skewness Rsk and a negative skewness Rsk of a copper foil surface.

FIG. 6 is a photograph of the external appearance of dirt for use in an Example.

FIG. 7 is a photograph of the external appearance of dirt for use in an Example.

### DESCRIPTION OF EMBODIMENTS

### Aspect of Surface Treated Copper Foil and Manufacturing Method Thereof

The copper foil for use in the present invention is effectively used for a copper foil which is used for manufacturing a laminate by bonding to a resin substrate so as to be removed by etching.

The copper foil for use in the present invention may be any one of an electrolyte copper foil and a rolled copper foil. The joint area of a copper foil to be bonded to a resin substrate (in the present invention, the area is also referred to as “one surface”) may be usually subject to a roughening treatment by electrodeposition for forming a knotty copper foil surface after degreasing, in order to improve the peel strength of the copper foil after lamination. Although an electrolyte copper foil has irregularities when manufactured, the irregularities can be further enlarged with roughening treatment for enhancing the projection portion of the electrolyte copper foil. In the present invention, the roughening treatment is performed by alloy plating such as copper-cobalt-nickel alloy plating, copper-nickel-phosphorus alloy plating and nickel-zinc alloy plating. The roughening treatment can be preferably performed by copper alloy plating. The copper alloy plating bath to be used is, for example, preferably a plating bath including copper and at least one element other than copper, more preferably a plating bath including copper and at least any one selected from the group consisting of cobalt, nickel, arsenicum, tungsten, chromium, zinc, phosphorus, manganese and molybdenum. In the present invention, the roughening treatment is performed at a higher current density for a shorter roughening treatment time, compared with a conventional roughening treatment. Common copper plating or the like may be performed as a pre-treatment before roughening in some cases, and common copper plating or the like may be also performed as a finishing treatment after roughening so as to prevent the detachment of an electrodeposited material in some cases.

Examples of a copper foil of the present invention include a copper alloy foil which contains at least one element such as Ag, Sn, In, Ti, Zn, Zr, Fe, P, Ni, Si, Te, Cr, Nb, and V. With high concentration of the elements (e.g., 10 mass % or more in total), the conductivity may be reduced in some cases. The conductivity of a rolled copper foil is preferably 50% IACS or more, more preferably 60% IACS or more, further preferably 80% IACS or more. The copper alloy foil may include the element other than copper in a total concentration of 0 mass % or more and 50 mass % or less, 0.0001 mass % or more and 40 mass % or less, 0.0005 mass % or more and 30 mass % or less, or 0.001 mass % or more and 20 mass % or less.

One surface of the copper foil for use in the present invention may be provided with a heat-resistant plating layer (heat-resistant layer), a rustproof plating layer (rustproof layer) or a weather-resistant layer, after a roughening treatment or without a roughening treatment. As a treatment for providing the surface with a heat-resistant plating layer or a rustproof plating layer without a roughening treatment, a plating treatment in a Ni plating bath (1) or a Ni—Zn plating bath (2) under the following conditions can be used. The balance of a treatment solution for use in electrolysis, a surface treatment or plating, for use in the present invention, is water, unless especially noted.

### (Ni Plating Bath (1))

Solution composition: Ni 20 to 30 g/L

pH: 2 to 3

Current density: 6 to 7 A/dm²

Bath temperature: 35 to 45° C.

Amount of coulomb: 1.2 to 8.4 As/dm²

Plating time: 0.2 to 1.2 sec.

### (Ni—Zn Plating Bath (2))

Solution composition: nickel: 20 to 30 g/L, zinc: 0.5 to 2.5 g/L

pH: 2 to 3

Current density: 6 to 7 A/dm²

Bath temperature: 35 to 45° C.

Amount of coulomb: 1.2 to 8.4 As/dm²

Plating time: 0.2 to 1.2 sec.

In the case of providing one surface of the copper foil with a heat-resistant layer or a rustproof layer by plating (plating which is neither normal plating nor roughening plating) without a roughening treatment, the plating is required to be performed at a higher current density for a shorter plating time, compared with a conventional case.

The thickness of a copper foil for use in the present invention is not specifically limited, including, for example, 1 μm or more, 2 μm or more, 3 μm or more, 5 μm or more, and, for example, 3,000 μm or less, 1,500 μm or less, 800 μm or less, 300 μm or less, 150 μm or less, 100 μm or less, 70 μm or less, 50 μm or less, and 40 μm or less.

The manufacturing conditions of electrolyte copper foil for use in the present invention are as follows:

### <Electrolyte Composition>

Copper: 90 to 110 g/L;

Sulfuric acid: 90 to 110 g/L;

Chlorine: 50 to 100 ppm;

Leveling agent 1 (bis(3-sulfopropyl)disulfide): 10 to 30 ppm; and

Leveling agent 2 (amine compound): 10 to 30 ppm.

The amine compound represented by the following formula may be used as the above-mentioned amine compound.

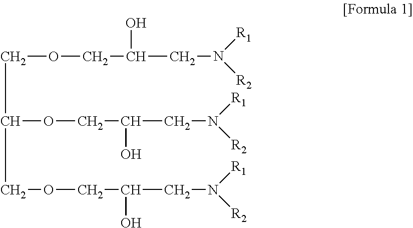

(In the chemical formula, R₁ and R₂ are selected from the group consisting of a hydroxyalkyl group, an ether group, an aryl group, an aromatic substituted alkyl group, an unsaturated hydrocarbon group, and an alkyl group.)

### <Manufacturing Conditions>

Current density: 70 to 100 A/dm²;

Electrolyte temperature: 50 to 60° C.;

Linear velocity of electrolyte: 3 to 5 m/sec; and

Electrolysis time: 0.5 to 10 min.

In copper-cobalt-nickel alloy plating as roughening treatment, electroplating may be performed such that a ternary alloy layer with deposition amounts of copper of 15 to 40 mg/dm², cobalt of 100 to 3000 μg/dm², and nickel of 50 to 1500 μg/dm² is formed, and is preferably performed such that a ternary alloy layer with deposition amounts of copper of 15 to 40 mg/dm², cobalt of 100 to 3000 μg/dm², and nickel of 100 to 1500 μg/dm² is formed. A deposition amount of Co less than 100 μg/dm² may cause degradation of heat resistance and etching properties in some cases. A deposition amount of Co more than 3,000 μg/dm² is not suitable in the case that effects of magnetic properties have to be considered, causing etching stains with reduced acid resistance and chemical resistance in some cases. A deposition amount of Ni less than 50 μg/dm² may cause degradation of heat resistance. On the other hand, a deposition amount of Ni more than 1,500 μg/dm² may increase the amount of etching residue in some cases. The preferable deposition amount of Co is 1,000 to 2,500 μg/dm², and the preferable deposition amount of Nickel is 500 to 1,200 μg/dm². In the specification, the presence of etching stains means that Co remains undissolved in etching with copper chloride, and the presence of etching residue means that Ni remains undissolved in alkali etching with ammonium chloride.

The plating bath and the plating conditions for forming the ternary copper-cobalt-nickel alloy plating are as follows:

Plating bath composition: Cu: 10 to 20 g/L, Co: 1 to 10 g/L, and Ni: 1 to 10 g/L;

pH: 1 to 4;

Temperature: 30 to 50° C.;

Current density Dₖ: 25 to 50 A/dm²; and

Plating time: 0.2 to 3 sec.

One surface of a surface treated copper foil in an embodiment of the present invention is roughened under conditions with a shorter plating time and a higher current density compared with conventional conditions. The roughening treatment under the conditions with a shorter plating time and a higher current density compared with conventional conditions allows finer roughened grains than conventional grains to be formed on the copper foil surface. In the case that the plating current density is set to a higher value in the range, the plating time needs to be set to a lower value in the range.

The conditions for copper-nickel-phosphorus alloy plating as roughening treatment of the present invention are as follows:

Plating bath composition: Cu: 10 to 50 g/L, Ni: 3 to 20 g/L, and P: 1 to 10 g/L;

pH: 1 to 4;

Temperature: 30 to 40° C.;

Current density Dₖ: 30 to 50 A/dm²; and

Plating time: 0.2 to 3 sec

One surface of a surface treated copper foil in an embodiment of the present invention is roughened under conditions with a shorter plating time and a higher current density compared with conventional conditions. The roughening treatment under the conditions with a shorter plating time and a higher current density compared with conventional conditions allows finer roughened grains than conventional grains to be formed on the copper foil surface. In the case that the plating current density is set to a higher value in the range, the plating time needs to be set to a lower value in the range.

The conditions for copper-nickel-cobalt-tungsten alloy plating as roughening treatment of the present invention are as follows:

Plating bath composition: Cu: 5 to 20 g/L, Ni: 5 to 20 g/L, Co: 5 to 20 g/L, and W: 1 to 10 g/L;

pH: 1 to 5;

Temperature: 30 to 50° C.;

Current density Dₖ: 30 to 50 A/dm²; and

Plating time: 0.2 to 3 sec.

One surface of a surface treated copper foil in an embodiment of the present invention is roughened under conditions with a shorter plating time and a higher current density compared with conventional conditions. The roughening treatment under the conditions with a shorter plating time and a higher current density compared with conventional conditions allows finer roughened grains than conventional grains to be formed on the copper foil surface. In the case that the plating current density is set to a higher value in the range, the plating time needs to be set to a lower value in the range.

The conditions for copper-nickel-molybdenum-phosphorus alloy plating as roughening treatment of the present invention are as follows:

Plating bath composition: Cu: 5 to 20 g/L, Ni: 5 to 20 g/L, Mo: 1 to 10 g/L, and P: 1 to 10 g/L;

pH: 1 to 5;

Temperature: 30 to 50° C.;

Current density Dₖ: 30 to 50 A/dm²; and

Plating time: 0.2 to 3 sec.

One surface of a surface treated copper foil in an embodiment of the present invention is roughened under conditions with a shorter plating time and a higher current density compared with conventional conditions. The roughening treatment under the conditions with a shorter plating time and a higher current density compared with conventional conditions allows finer roughened grains than conventional grains to be formed on the copper foil surface. In the case that the plating current density is set to a higher value in the range, the plating time needs to be set to a lower value in the range.

After roughening treatment, at least one layer selected from the group consisting of a heat-resistant layer, a rustproof layer and a weather-resistant layer may also be provided on the roughening treated surface. Such respective layers may be made of a plurality of layers such as two layers and three layers, and may be laminated in any order or may be alternately laminated.

A known heat-resistant layer can be used as the heat-resistant layer. For example, the following surface treatment can be used.

A known heat-resistant layer and a known rustproof layer can be used as the heat-resistant layer and the rustproof layer, respectively. For example, the heat-resistant layer and/or the rustproof layer may be a layer including at least one element selected from the group consisting of nickel, zinc, tin, cobalt, molybdenum, copper, tungsten, phosphorus, arsenicum, chromium, vanadium, titanium, aluminum, gold, silver, a platinum group element, iron and tantalum, or may be a metal layer or an alloy layer made of at least one element selected from the group consisting of nickel, zinc, tin, cobalt, molybdenum, copper, tungsten, phosphorus, arsenicum, chromium, vanadium, titanium, aluminum, gold, silver, a platinum group element, iron and tantalum. The heat-resistant layer and/or the rustproof layer may include an oxide, a nitride, or a silicide including at least one element selected from the group consisting of nickel, zinc, tin, cobalt, molybdenum, copper, tungsten, phosphorus, arsenicum, chromium, vanadium, titanium, aluminum, gold, silver, a platinum group element, iron and tantalum. The heat-resistant layer and/or the rustproof layer may be a layer including a nickel-zinc alloy. The heat-resistant layer and/or the rustproof layer may be a nickel-zinc alloy layer. The nickel-zinc alloy layer may contain 50 wt % to 99 wt % of nickel and 50 wt % to 1 wt % of zinc, excluding unavoidable impurities. The total deposition amount of zinc and nickel in the nickel-zinc alloy layer may be 5 to 1000 mg/m², preferably 10 to 500 mg/m², preferably 20 to 100 mg/m². The ratio of the deposition amount of nickel to the deposition amount of zinc (=deposition amount of nickel/deposition amount of zinc) in the layer including a nickel-zinc alloy or the nickel-zinc alloy layer is preferably 1.5 to 10. The deposition amount of nickel in the layer including a nickel-zinc alloy or the nickel-zinc alloy layer is preferably 0.5 mg/m² to 500 mg/m², more preferably 1 mg/m² to 50 mg/m². When the heat-resistant layer and/or the rustproof layer is the layer including a nickel-zinc alloy, the interface between the copper foil and the resin substrate is hardly eroded by a desmear liquid in contacting of an inner wall portion such as a through-hole and a via hole with a desmear liquid, resulting in an improvement in adhesion properties of the copper foil and the resin substrate. The rustproof layer may be a chromate treated layer. A known chromate treated layer can be used as the chromate treated layer. For example, the chromate treated layer refers to as a layer treated with a solution including chromic anhydride, chromic acid, dichromic acid, a chromic acid salt or a dichromic acid salt. The chromate treated layer may include an element such as cobalt, iron, nickel, molybdenum, zinc, tantalum, copper, aluminum, phosphorus, tungsten, tin, arsenicum and titanium (which may be in the form of any of metal, alloy, oxide, nitride, sulfide, and the like). Specific examples of the chromate treated layer include a pure chromate treated layer and a zinc chromate treated layer. In the present invention, a chromate treated layer treated with chromic anhydride or an aqueous potassium dichromate solution is referred to as a pure chromate treated layer. In the present invention, a chromate treated layer treated with a treatment solution including chromic anhydride or potassium dichromate and zinc is referred to as a zinc chromate treated layer.

For example, the heat-resistant layer and/or the rustproof layer may be one in which a nickel or nickel alloy layer with a deposition amount of 1 mg/m² to 100 mg/m², preferably 5 mg/m² to 50 mg/m², and a tin later with a deposition amount of 1 mg/m² to 80 mg/m², preferably 5 mg/m² to 40 mg/m² are sequentially laminated, and the nickel alloy layer may be configured from any one of nickel-molybdenum, nickel-zinc and nickel-molybdenum-cobalt. In the heat-resistant layer and/or the rustproof layer, the total deposition amount of nickel or a nickel alloy and tin is preferably 2 mg/m² to 150 mg/m², more preferably 10 mg/m² to 70 mg/m². In the heat-resistant layer and/or the rustproof layer, the [deposition amount of nickel in the nickel or nickel alloy]/[the deposition amount of tin] is 0.25 to 10, more preferably 0.33 to 3.

A cobalt-nickel alloy plating layer having deposition amounts of cobalt of 200 to 2000 μg/dm² and nickel of 50 to 700 μg/dm² may be formed as the heat-resistant layer and/or the rustproof layer. This treatment can be regarded as a kind of rustproof treatment in a broad sense. The cobalt-nickel alloy plating layer needs to be formed to an extent not to substantially reduce the adhesion strength between the copper foil and the substrate. A deposition amount of cobalt less than 200 μg/dm² may cause reduction of heat resistant peel strength with degraded oxidation resistance and chemical resistance in some cases. In addition, another reason that a small amount of cobalt is not preferred is that the treated surface has a reddish color.

After the roughening treatment, a cobalt-nickel alloy plating layer having deposition amounts of cobalt of 200 to 3,000 μg/dm² and nickel of 100 to 700 μg/dm² on the roughened surface may be formed. This treatment can be regarded as a kind of rustproof treatment in a broad sense. The cobalt-nickel alloy plating layer needs to be formed to an extent not to substantially reduce the adhesion strength between the copper foil and the substrate. A deposition amount of cobalt less than 200 μg/dm² may cause reduction of heat resistant peel strength with degraded oxidation resistance and chemical resistance in some cases. In addition, another reason that a small amount of cobalt is not preferred is that the treated surface has a reddish color. A deposition amount of cobalt more than 3,000 μg/dm² is not suitable in the case that effects of magnetic properties have to be considered, causing etching stains with reduced acid resistance and chemical resistance in some cases. The preferable deposition amount of cobalt is 500 to 2,500 μg/dm². On the other hand, a deposition amount of nickel less than 100 μg/dm² may cause reduction of heat resistant peel strength with degraded oxidation resistance and chemical resistance in some cases. An amount of nickel more than 1,300 μg/dm² results in poor alkali etching properties. The preferable deposition amount of nickel is 200 to 1,200 μg/dm².

The condition for cobalt-nickel alloy plating is as follows:

Plating bath composition: Co: 1 to 20 g/L and Ni: 1 to 20 g/L;

pH: 1.5 to 3.5;

Temperature: 30 to 80° C.;

Current density Dₖ: 1.0 to 20.0 A/dm²; and

Plating time: 0.5 to 4 sec.

According to the present invention, a zinc plating layer with a deposition amount of 30 to 250 μg/dm² is further formed on a cobalt-nickel alloy plating layer. A deposition amount of zinc less than 30 μg/dm² may eliminate the effect for improving the degradation rate of heat resistance in some cases. On the other hand, a deposition amount of zinc more than 250 μg/dm² may drastically worsen the degradation rate of hydrochloric acid resistance in some cases. The deposition amount of zinc is preferably 30 to 240 μg/dm², more preferably 80 to 220 μg/dm².

The conditions for the zinc plating are as follows:

Plating bath composition: Zn: 100 to 300 g/L;

pH: 3 to 4;

Temperature: 50 to 60° C.;

Current density Dₖ: 0.1 to 0.5 A/dm²; and

Plating time: 1 to 3 sec.

Alternatively, a plating layer of zinc alloy such as that of zinc-nickel alloy may be formed instead of the zinc plating layer. On the outermost surface, a rustproof layer may be further formed by treatment such as chromating or application of a silane coupling agent.

A known weather-resistant layer can be used as the weather-resistant layer. For example, a known silane coupling treated layer, or a silane coupling treated layer formed using the following silane can be used as the weather-resistant layer.

A known silane coupling agent may be used for the silane coupling agent for use in a silane coupling treatment, and for example, an amino-based silane coupling agent, an epoxy-based silane coupling agent, or a mercapto-based silane coupling agent may be used. Vinyltrimethoxysilane, vinylphenyltrimethoxysilane, γ-methacryloxypropyltrimethoxysilane, γ-glycidoxypropyltrimethoxysilane, 4-glycidylbutyltrimethoxysilane, γ-aminopropyltriethoxysilane, N-β(aminoethyl)γ-aminopropyltrimethoxysilane, N-3-(4-(3-aminopropoxy)butoxy)propyl-3-aminopropyltrimethoxysilane, imidazolsilane, triazinesilane, γ-mercaptopropyltrimethoxysilane or the like may be used for the silane coupling agent.

The silane coupling treated layer may be formed with a silane coupling agent such as epoxy-based silane, amino-based silane, methacryloxy-based silane and mercapto-based silane. Such a silane coupling agent may be used as a mixture of two or more. In particular, a silane coupling treated layer formed with an amino-based silane coupling agent or an epoxy-based silane coupling agent is preferable.

The amino-based silane coupling agent referred herein may be selected from the group consisting of N-(2-aminoethyl)-3-aminopropyltrimethoxysilane, 3-(N-styrylmethyl-2-aminoethylamino)propyltrimethoxysilane, 3-aminopropyltriethoxysilane, bis(2-hydroxyethyl)-3-aminopropyltriethoxysilane, aminopropyltrimethoxysilane, N-methylaminopropyltrimethoxysilane, N-phenylaminopropyltrimethoxysilane, N-(3-acryloxy-2-hydroxypropyl)-3-aminopropyltriethoxysilane, 4-aminobutyltriethoxysilane, (aminoethylaminomethyl)phenethyltrimethoxysilane, N-(2-aminoethyl-3-aminopropyl)trimethoxysilane, N-(2-aminoethyl-3-aminopropyl)tris(2-ethylhexoxy)silane, 6-(aminohexylaminopropyl)trimethoxysilane, aminophenyltrimethoxysilane, 3-(1-aminopropoxy)-3,3-dimethyl-1-propenyltrimethoxysilane, 3-aminopropyltris(methoxyethoxyethoxy)silane, 3-aminopropyltriethoxysilane, 3-aminopropyltrimethoxysilane, ω-aminoundecyltrimethoxysilane, 3-(2-N-benzylaminoethylaminopropyl)trimethoxysilane, bis(2-hydroxyethyl)-3-aminopropyltriethoxysilane, (N,N-diethyl-3-aminopropyl)trimethoxysilane, (N,N-dimethyl-3-aminopropyl)trimethoxysilane, N-methylaminopropyltrimethoxysilane, N-phenylaminopropyltrimethoxysilane, 3-(N-styrylmethyl-2-aminoethylamino)propyltrimethoxysilane, γ-aminopropyltriethoxysilane, N-β(aminoethyl)γ-aminopropyltrimethoxysilane and N-3-(4-(3-aminopropoxy)butoxy)propyl-3-aminopropyltrimethoxysilane.

The silane coupling treated layer is desirably provided in the range from 0.05 mg/m² to 200 mg/m², preferably 0.15 mg/m² to 20 mg/m², preferably 0.3 mg/m² to 2.0 mg/m², in terms of a silicon atom. The above range can allow adhesion properties between the substrate resin and the surface treated copper foil to be more enhanced.

The surface treated copper foil of the present invention may have a configuration in which the surface treatment of one surface is a roughening treatment, the roughening treated surface has a TD ten-spot average roughness Rz of 0.30 to 0.80 μm, the roughening treated surface has an MD glossiness at 60 degrees of 80 to 350%, and the ratio A/B of the surface area A of the roughened grains to the area B of the roughened grains shown in the plan view from one surface side of the copper foil is 1.90 to 2.40. The surface roughness Rz (1), the glossiness (2) and the grain surface area ratio (3) of the copper foil having such a configuration are described below.

(1) Surface Roughness Rz

The surface treated copper foil having the configuration preferably has roughened grains on one surface of the copper foil by a roughening treatment, and the roughening treated surface preferably has a TD ten-spot average roughness Rz measured with a contact roughness measuring tester, of 0.20 to 0.80 μm. Such a configuration allows for high peel strength with good adhesion to a resin, and high transparency of the resin after removal of the copper foil by etching. Consequently alignment of an IC chip to be mounted with a positioning pattern which is visually recognized through the resin can be more easily performed. A TD ten-spot average roughness Rz measured with a contact roughness measuring tester, less than 0.20 μm, may result in a concern about the production cost for preparing a super-smooth surface. On the other hand, a TD ten-spot average roughness Rz measured with a contact roughness measuring tester, more than 0.80 μm, may allow irregularities of the resin surface to be enlarged after removal of the copper foil by etching, which may cause a problem of defect in transparency of the resin. The TD ten-spot average roughness Rz of the roughening treated surface, which is measured with a contact roughness measuring tester, is more preferably 0.30 to 0.70 μm, still more preferably 0.35 to 0.60 μm, still more preferably 0.35 to 0.55 μm, still more preferably 0.35 to 0.50 μm. In the case that the surface treated copper foil of the present invention is used in applications where a smaller Rz is needed, the TD ten-spot average roughness Rz of the roughening treated surface of the surface treated copper foil of the present invention, which is measured with a contact roughness measuring tester, is preferably 0.20 to 0.70 μm, more preferably 0.25 to 0.60 μm, still more preferably 0.30 to 0.60 μm, still more preferably 0.30 to 0.55 μm, still more preferably 0.30 to 0.50 μm.

“Roughening treated surface” in the surface treated copper foil of the present invention refers to a surface of the surface treated copper foil, which is surface treated for providing a heat-resistant layer, a rustproof layer, a weather-resistant layer and the like after being roughening treated, in the case that such a surface treatment is performed.

(2) Glossiness

The glossiness of the surface treated surface (for example, roughened surface) of the surface treated copper foil in the rolling direction (MD) at an incident angle of 60 degrees greatly affects the transparency of the above-mentioned resin. That is, the higher the glossiness of the copper foil of the surface treated surface (for example, roughened surface) is, the better transparency of the resin is achieved. Consequently, the surface treated copper foil having the configuration preferably has a glossiness of one surface of 76 to 350%, preferably 80 to 350%, more preferably 90 to 300%, still more preferably 90 to 250%, still more preferably 100 to 250%.

The MD glossiness and the TD surface roughness Rz of one surface of the copper foil before surface treatment can be controlled to thereby control the Sv and the ΔB in the present invention. The TD glossiness and the TD surface roughness Rz of one surface of the copper foil before surface treatment can also be controlled to thereby control the Sv, the Rsk, the Rq and the ratio E/G in the present invention.

Specifically, when one surface of the copper foil has a TD surface roughness (Rz) of 0.30 to 0.80 μm, preferably 0.30 to 0.50 μm and a glossiness in the rolling direction (MD) at an incident angle of 60 degrees of 350 to 800%, preferably 500 to 800%, before the surface treatment, and furthermore the current density is higher and the roughening treatment time is shorter than those in a conventional roughening treatment, the glossiness of the surface treated copper foil after the surface treatment in the rolling direction (MD) at an incident angle of 60 degrees is 90 to 350%. The Sv and the ΔB can be controlled to predetermined values. Such a copper foil can be made by rolling with adjustment of the oil film equivalent of a rolling oil (high gloss rolling), chemical polishing such as chemical etching, or electrolytic polishing in a phosphoric acid solution. Since the TD surface roughness (Rz) and the MD glossiness of the copper foil are thus controlled to be in the range before the surface treatment, the surface roughness (Rz), the surface area, the Sv and the ΔB of the copper foil after the treatment can be easily controlled. In the case that the surface roughness (Rz) of the copper foil after the surface treatment is demanded to be decreased (for example, Rz=0.20 μm), the treated surface of the copper foil before the surface treatment preferably has a TD roughness (Rz) of 0.18 to 0.80 μm, preferably 0.25 to 0.50 μm and a glossiness in the rolling direction (MD) at an incident angle of 60 degrees of 350 to 800%, preferably 500 to 800%, and furthermore the current density is higher and the roughening treatment time is shorter than those in a conventional roughening treatment.

The copper foil before roughening treatment preferably has an MD glossiness of one surface at 60 degrees of 500 to 800%, more preferably 501 to 800%, still more preferably 510 to 750%. An MD glossiness of the copper foil before roughening treatment at 60 degrees, less than 500%, may cause defect in transparency of the resin compared with the case of 500% or more, and an MD glossiness more than 800% may cause a problem of difficulty in manufacturing.

The high gloss rolling may be performed with an oil film equivalent defined by the following expression of 13000 to 24000 or less. If the surface roughness (Rz) of the copper foil after the surface treatment is demanded to be decreased (for example, Rz=0.20 μm), the high gloss rolling is performed with an oil film equivalent defined by the following expression of 12000 or more and 24000 or less.

Oil film equivalent={(rolling oil viscosity [cSt])×(sheet passage rate [mpm]+roll circumferential rate [mpm])}/{(roll biting angle [rad])×(material yield stress [kg/mm²])}

The rolling oil viscosity [cSt] is kinetic viscosity at 40° C.

In order to control the oil film equivalent to be 13000 to 24000, a known method may be used such as use of a low-viscosity rolling oil or slowing down of sheet passage rate.

Chemical polishing is performed with an etching solution of sulfuric acid-hydrogen peroxide-water or ammonia-hydrogen peroxide-water with a concentration lower than normal, for an extended period of time.

The control method is also the same as the case that the roughening treatment is not performed and the heat-resistant layer or the rustproof layer is provided on the copper foil by plating (plating which is neither normal plating nor roughening plating).

The treated surface, for example, the roughening treated surface preferably has a ratio F of the MD glossiness at 60 degrees to the TD glossiness at 60 degrees (F=(MD glossiness at 60 degrees)/(TD glossiness at 60 degrees)), in one surface of the surface treated copper foil, of 0.80 to 1.40. A ratio F of the MD glossiness at 60 degrees to the TD glossiness at 60 degrees of the roughening treated surface, less than 0.80, may cause reduction of transparency of the resin compared with the case of 0.80 or more. A ratio F more than 1.40 may cause reduction of transparency of the resin compared with the case of 1.40 or less. The ratio F is more preferably 0.90 to 1.35, still more preferably 1.00 to 1.30.

(3) Surface Area Ratio of Grains

The ratio A/B of the surface area A of the roughened grains to the area B of the roughened grains shown in the plan view from one surface side of the surface treated copper foil, in one surface of the surface treated copper foil, greatly affects transparency of the resin. That is, the same surface roughness Rz allows transparency of the resin to be better as the ratio A/B of the copper foil is smaller. Consequently, the surface treated copper foil having the configuration preferably has a ratio A/B of 1.90 to 2.40, more preferably 2.00 to 2.20, in the one surface.

The morphology and the packing density of grains are determined by control of the current density and plating time during grain formation, so that the surface roughness Rz, the glossiness, and the surface area ratio A/B in the one surface can be controlled.

As described above, one surface of the surface treated copper foil is controlled so as to have a ratio A/B of the surface area A of the roughened grains to the area B of the roughened grains shown in the plan view from one surface side of the copper foil of 1.90 to 2.40, to have enlarged surface irregularities, and the roughening treated surface is controlled so as to have a TD ten-spot average roughness Rz of 0.30 to 0.80 μm, to eliminate an extremely roughened portion on the surface, while the glossiness of the roughening treated surface can be increased to 80 to 350%. Such control can allow one surface of the surface treated copper foil of the present invention to have a small roughened grain size on the roughening treated surface. While the roughened grain size affects transparency of the resin after removal of the copper foil by etching, such control means reduction of the roughened grain size within an appropriate range, thereby resulting in better transparency of the resin after removal of the copper foil by etching, and also better peel strength.

As described above, one surface of the surface treated copper foil is controlled so as to have a ratio A/B of the surface area A of the roughened grains to the area B of the roughened grains shown in the plan view from one surface side of the copper foil of 1.90 to 2.40, to have enlarged surface irregularities, and the roughening treated surface is controlled so as to have a TD ten-spot average roughness Rz of 0.30 to 0.80 μm, to eliminate an extremely roughened portion on the surface, while the glossiness of the roughening treated surface can be increased to 80 to 350%. Such control can allow one surface of the surface treated copper foil of the present invention to have a small roughened grain size on the roughening treated surface. While the roughened grain size affects transparency of the resin after removal of the copper foil by etching, such control means reduction of the roughened grain size within an appropriate range, thereby resulting in better transparency of the resin after removal of the copper foil by etching, and also better peel strength.

[Root Mean Square Height Rq of Copper Foil Surface]

In the surface treated copper foil of the present invention, the root mean square height Rq of one surface is preferably controlled to be 0.14 to 0.63 μm. Such a configuration allows for high peel strength with good adhesion to a resin, and high transparency of the resin after removal of the copper foil by etching. Consequently alignment of an IC chip to be mounted with a positioning pattern which is visually recognized through the resin can be more easily performed. A root mean square height Rq less than 0.14 μm results in an insufficient roughening treatment of the copper foil surface, which causes a problem of insufficient adhesion to the resin. On the other hand, a root mean square height Rq of one surface more than 0.63 μm allows irregularities of the resin surface to be enlarged after removal of the copper foil by etching, which causes a problem of defect in transparency of the resin. The root mean square height Rq of the roughening treated surface is more preferably 0.25 to 0.60 μm, still more preferably 0.32 to 0.56 μm.

The root mean square height Rq of a surface is an index for representing the degree of irregularities in surface roughness measurement with a non-contact roughness measuring tester in accordance with JIS B 0601 (2001), being represented by the following expression, which is a height of irregularities (peaks) of the surface roughness in the Z-axis direction, and the root mean square of the peak height Z(x) in the reference length lr.

The root mean square height Rq of the peak height in the reference length lr:

√{(1/lr)×∫Z²(x)dx

(wherein the integral represents the integrated value from 0 to lr)}

The root mean square height Rq of a surface is controlled as follows. In the case of a non-roughened surface treated surface, the treatment is performed with a low current density such that no irregularities are formed on a plating film as described above. In the case of a roughening treated surface, the treatment is performed with a high current density. Roughened grains are thus down-sized, and a surface with small roughness can be formed with a reduced plating time.

### (Skewness Rsk of Copper Foil Surface)

The skewness Rsk represents the cubic mean of Z(x) in a dimensionless reference length as the cube of root mean square height Rq.

The root mean square height Rq is an index for representing the degree of irregularities in surface roughness measurement with a non-contact roughness measuring tester in accordance with JIS B 0601 (2001), being represented by the following expression (A), which is a height of irregularities (peaks) of the surface roughness in the Z-axis direction, and the root mean square of the peak height Z(x) in the reference length lr.

The root mean square height of the peak height in the reference length lr:

$$\begin{matrix}[ Expression 1 ] & \\ Rq = \sqrt{\frac{1}{lr} {\int }_{0}^{lr} {Z}^{2} ( x ) d x} & ( A )\end{matrix}$$

The skewness Rsk is represented by the following expression (B), using the root mean square height Rq.

$$\begin{matrix}[ Expression 2 ] & \\ Rsk = \frac{1}{{Rq}^{3}} \sqrt{\frac{1}{lr} {\int }_{0}^{lr} {Z}^{3} ( x ) d x} & ( B )\end{matrix}$$

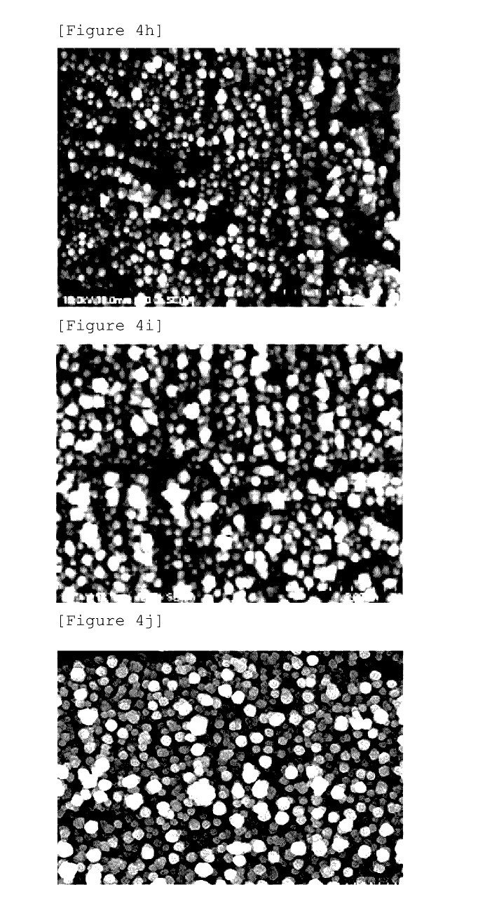

The skewness Rsk of a copper foil surface is an index for representing symmetry of the irregularities on the copper foil surface relative to the averaged surface as the center of a surface with irregularities of the copper foil surface. As shown in FIG. 5, in the case of Rsk<0, the height distribution is biased to the upper side relative to the averaged surface, while in the case of Rsk>0, the height distribution is biased to the lower side relative to the averaged surface. With a large bias to the upper side, the polyimide (PI) surface in a concave shape is formed when the copper foil is removed by etching after being attached to the PI, enhancing diffused reflection inside the PI when irradiated with light from a light source. With a large bias to the lower side, the polyimide (PI) surface in a convex shape is formed when the copper foil is removed by etching after being attached to the PI, enhancing diffused reflection at the PI surface when irradiated with light from a light source.

One surface of a surface treated copper foil of the present invention is preferably controlled to have a skewness Rsk of −0.35 to 0.53. Such a configuration allows for high peel strength with good adhesion to a resin, and high transparency of the resin after removal of the copper foil by etching. Consequently, the alignment during mounting an IC chip can be easily performed through a positioning pattern which is visually recognized through the resin. A skewness Rsk less than −0.35 may result in an insufficient surface treatment such as roughening treatment of the copper foil surface, which causes a problem of insufficient adhesion to the resin. On the other hand, a skewness Rsk more than 0.53 may allow irregularities of the resin surface to be enlarged after removal of the copper foil by etching, which causes a problem of defect in transparency of the resin. The skewness Rsk of the treated surface of a copper foil is preferably −0.30 or more, or −0.20 or more and −0.10 or less. Alternatively, the skewness Rsk of one of the treated surfaces of a copper foil is preferably 0.15 or more, or 0.20 or more and 0.50 or less, 0.45 or less, or 0.40 or less, or more preferably 0.39 or less. Alternatively, the skewness Rsk of the treated surface of a copper foil is preferably −0.30 or more and 0.50 or less, more preferably 0.39 or less.

The surface skewness Rsk is controlled as follows. In the case of a non-roughened surface treated surface, the treatment is performed with a low current density such that no irregularities are formed on a plating film as described above. In the case of roughening treated surface, the treatment is performed with a high current density. Roughened grains are thus down-sized, and a surface with small roughness can be formed with a reduced plating time.

[Ratio E/G of Projection Portion Volume E to Surface Area G of Copper Foil Surface]

One surface of the surface treated copper foil of the present invention is preferably controlled so as to have a ratio E/G of the projection portion volume E of a surface to the surface area G of a surface shown in plan view of 2.11 to 23.91. Such a configuration allows for high peel strength with good adhesion to a resin, and high transparency of the resin after removal of the copper foil by etching. Consequently alignment of an IC chip to be mounted with a positioning pattern which is visually recognized through the resin can be more easily performed. A ratio E/G less than 2.11 μm results in an insufficient roughening treatment of the copper foil surface, which causes a problem of insufficient adhesion to the resin. On the other hand, a ratio E/G more than 23.91 μm allows irregularities of the resin surface to be enlarged after removal of the copper foil by etching, which causes a problem of defect in transparency of the resin. The ratio E/G is more preferably 2.95 to 21.42 μm, still more preferably 10.54 to 13.30 μm.

“Surface area G of a surface shown in plan view” means the total surface area of a peak portion and a valley portion based on a certain height (threshold).

“Projection portion volume E of a surface” means the total volume of a peak portion and a valley portion based on a certain height (threshold).

The ratio E/G of the projection portion volume E of a surface to the surface area G of a surface is controlled by adjustment of the current density and the plating time of the roughened grains as described above. The plating treatment is performed with a high current density to provide small roughened grains, and is performed with a low current density to provide large roughened grains. The number of grains to be formed under such conditions is determined depending on the plating treatment time, and the projection portion volume E is thus determined depending on a combination of the current density and the plating time.

[Ten-Spot Average Roughness Rz of Copper Foil Surface]

The surface treated copper foil of the present invention may be a non-roughening treated copper foil or a roughening treated copper foil having roughened grains formed, and the roughening treated surface preferably has a TD ten-spot average roughness Rz measured with a contact roughness measuring tester, of 0.20 to 0.64 μm. Such a configuration allows for good adhesion to a resin with more increased peel strength, improving more the transparency of the resin after removal of the copper foil by etching. Consequently alignment of an IC chip to be mounted with a positioning pattern which is visually recognized through the resin can be more easily performed. A TD ten-spot average roughness Rz measured with a contact roughness measuring tester, less than 0.20 μm, may result in an insufficient roughening treatment of the copper foil surface, which may cause a problem of insufficient adhesion to the resin. On the other hand, a TD ten-spot average roughness Rz measured with a contact roughness measuring tester, more than 0.64 μm, may allow irregularities of the resin surface to be enlarged after removal of the copper foil by etching, which may cause a problem of defect in transparency of the resin. The TD ten-spot average roughness Rz of the treated surface, measured with a contact roughness measuring tester, is more preferably 0.40 to 0.62 μm, still more preferably 0.46 to 0.55 μm.

In order to further enhance the visibility effect of the present invention, the TD roughness (Rz) and the glossiness of one surface of the copper foil before the surface treatment, measured with a contact roughness measuring tester, are controlled. Specifically, the TD (the perpendicular direction (the width direction of the copper foil) to the rolling direction, in the case of an electrolyte copper foil, the perpendicular direction to the passing direction of the copper foil in the manufacturing device of the electrolyte copper foil) surface roughness (Rz) of one surface of the copper foil before the surface treatment, measured with a contact roughness measuring tester, is 0.20 to 0.55 μm, preferably 0.20 to 0.42 μm. Such a copper foil can be made by rolling with adjustment of the oil film equivalent of a rolling oil (high gloss rolling) or adjustment of the surface roughness of a stretch roll, chemical polishing such as chemical etching, or electrolytic polishing in a phosphoric acid solution. Since the TD surface roughness (Rz) of the copper foil before the treatment is thus controlled within the above range, and the TD glossiness of the copper foil before the treatment is thus controlled within the above range, the surface roughness (Rz) of the copper foil after the treatment, the surface area, the Sv, the Rq, the Rsk, and the ratio E/G of the projection portion volume E to the surface area G of the copper foil surface can be controlled.

One surface of the copper foil before the surface treatment has a TD glossiness of 400 to 710% at 60 degrees, preferably 500 to 710%. In the case that one surface of a copper foil has an MD glossiness at 60 degrees less than 400% before the surface treatment, more defects in transparency of the resin may be caused compared with the case of 400% or more. In the case of more than 710%, a problem of difficulty in manufacturing may be caused.

The high gloss rolling may be performed with an oil film equivalent defined by the following expression of 13,000 to 24,000 or less:

Oil film equivalent={(rolling oil viscosity [cSt])×(sheet passage rate [mpm]+roll circumferential rate [mpm])}/{(roll biting angle [rad])×(material yield stress [kg/mm²])}

The rolling oil viscosity [cSt] is kinetic viscosity at 40° C.

In order to control the oil film equivalent to be 13,000 to 24,000, a known method may be used such as use of a low-viscosity rolling oil or slowing down of sheet passage rate.

The surface roughness of the stretch roll can be, for example, 0.01 to 0.25 μm as the arithmetic average roughness Ra (JIS B0601). In the case that the arithmetic average roughness Ra of the stretch roll is large, the TD surface roughness (Rz) of the copper foil before the surface treatment tends to be increased and the TD glossiness of one surface of the copper foil before the surface treatment at 60 degrees tends to be decreased. In the case that the arithmetic average roughness Ra of the stretch roll is small, the TD surface roughness (Rz) of the copper foil before the surface treatment tends to be decreased and the TD glossiness of one surface of the copper foil before the surface treatment at 60 degrees tends to be increased.

Chemical polishing is performed with an etching solution of sulfuric acid-hydrogen peroxide-water or ammonia-hydrogen peroxide-water with a concentration lower than normal, for an extended period of time.

### (Gradient of Brightness Curve)

A surface treated copper foil of the present invention comprises an Sv defined by the expression (1) of 3.5 or more based on a brightness curve; wherein the brightness curve is obtained, after laminating the surface treated surface of the copper foil from one surface side to each of both surfaces of a polyimide substrate resin, removing the copper foil on each of both surfaces by etching, placing a printed matter with a linear mark under the exposed polyimide substrate, and photographing the printed matter with a CCD camera through the polyimide substrate, from an observation spot versus brightness graph of measurement results of the brightness of the photographed image of the printed matter for the respective observation spots along the direction perpendicular to the extending direction of the observed linear mark, and the difference between the top average Bt and the bottom average Bb in the brightness curve extending from an end of the mark to a portion without the mark is represented by ΔB (ΔB=Bt−Bb); and wherein t1 represents a value pointing the position of the intersection closest to the linear mark among the intersections of the brightness curve and Bt in the observation spot versus brightness graph, and t2 represents the intersection closest to the linear mark among the intersections of the brightness curve and 0.1ΔB in the range from the intersections of the brightness curve and Bt to a depth of 0.1ΔB with Bt as reference.

Sv=(ΔB×0.1)/(t1−t2) (1)

In the observation position-brightness graph, the transverse axis represents a position information (pixel×0.1) value, and the vertical axis represents a brightness (gradation) value.

With reference to drawing, “top average Bt of brightness curve,” “bottom average Bb of brightness curve,” and the following “t1,” “t2,” and “Sv” are described below.

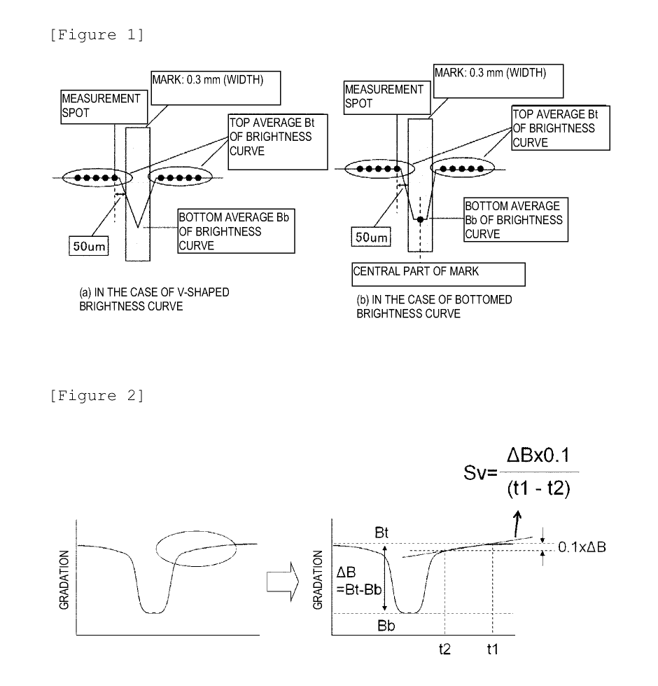

In FIG. 1(a) and FIG. 1(b), schematic diagrams for defining Bt and Bb are shown for a mark having a width of approximately 0.3 mm. In the case of a mark having a width of approximately 0.3 mm, the brightness curve may be in a V-shape as shown in FIG. 1(a), or may be in a bottomed shape as shown in FIG. 1(b). In both instances, “top average Bt of brightness curve” represents the average of brightness measured at 5 spots at intervals of 30 μm from a position 50 μm away from the end position of both sides of a mark (total 10 spots on both sides). On the other hand, “bottom average Bb of brightness curve” represents the lowest value of the brightness at the tip of the V-shaped valley for the brightness curve in a V-shape as shown in FIG. 1(a), and the value of the central part of the approximately 0.3 mm-width for the brightness curve in a bottomed shape as shown in FIG. 1(b).

A mark may have a width of about 0.2 mm, 0.16 mm, or 0.1 mm. Alternatively, “top average Bt of brightness curve” may represent the average of brightness measured at 5 spots at intervals of 30 μm from a position 100 μm away, a position 300 μm away, or a position 500 μm away from the end position of both sides of the mark (total 10 spots on both sides).

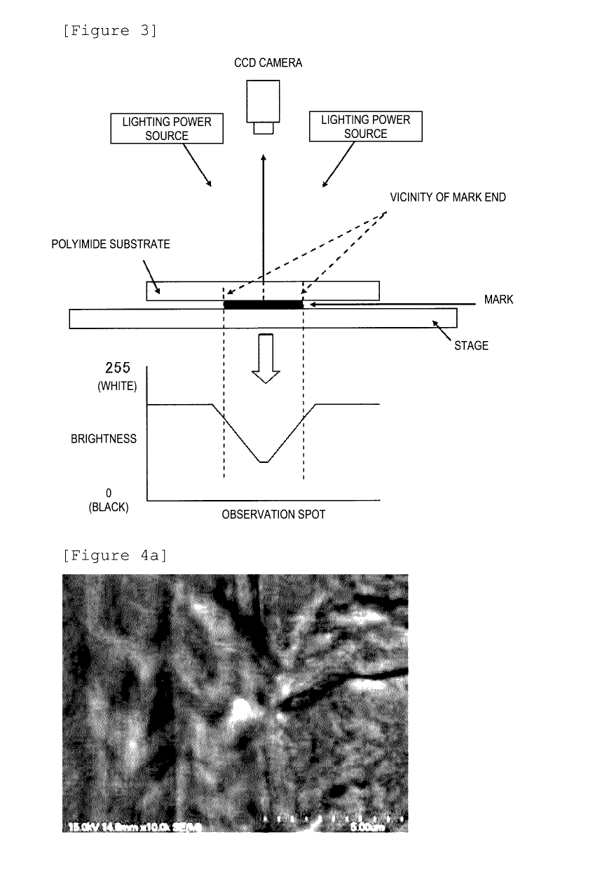

In FIG. 2, a schematic diagram for defining t1, t2, and Sv is shown. “t1 (pixel×0.1)” represents a value (value in the transverse axis of the observation spot versus brightness graph) pointing the intersection closest to the linear mark among the intersections of the brightness curve and Bt, as well as the position of the closest intersection. “t2 (pixel×0.1)” represents a value (value in the transverse axis of the observation spot versus brightness graph) pointing the intersection closest to the linear mark among the intersections of the brightness curve and 0.1ΔB in the range from the intersections of the brightness curve and Bt to a depth of 0.1ΔB with Bt as reference, as well as the position of the closest intersection. On this occasion, the gradient of the brightness curve represented by the line connecting t1 and t2 is defined by Sv (gradation/pixel×0.1) calculated from 0.1ΔB in y-axis direction and (t1−t2) in x-axis direction. One pixel in the transverse axis corresponds to a length of 10 μm. Sv represents the smaller value obtained by measurement on both sides of a mark. In the case that a plurality of “intersections of the brightness curve and Bt” are present due to instability of the shape of the brightness curve, the intersection closest to the mark is employed.

In the image photographed by a CCD camera, a portion having no mark has high brightness, while the brightness sharply falls down at the end of a mark. With good visibility of the polyimide substrate, the falling state of brightness can be clearly observed. On the other hand, with poor visibility of the polyimide substrate, the brightness does not drastically fall down from “high” to “low” at the vicinity of the end of a mark, so that the gradual falling state results in the unclear falling state of brightness.

In the present invention based on such finding, the surface treated copper foil of the present invention is laminated to a polyimide substrate and removed therefrom, and a marked printed matter is placed under the polyimide substrate so as to be photographed with a CCD camera through the polyimide substrate. From the photographed image of the mark part, an observation spot versus brightness graph is obtained and the gradient of the brightness curve in the vicinity of the end of a mark is controlled. More specifically, when the difference between the top average Bt and the bottom average Bb of the brightness curve is represented by ΔB (ΔB=Bt−Bb), t1 represents a value (value in the transverse axis of the observation spot versus brightness graph) pointing the position of the intersection closest to the linear mark among the intersections of the brightness curve and Bt in the observation spot versus brightness graph, and t2 represents a value (value in the transverse axis of the observation spot versus brightness graph) pointing the position of the intersection closest to the linear mark among the intersections of the brightness curve and 0.1ΔB in the range from the intersections of the brightness curve and Bt to a depth of 0.1ΔB with Bt as reference, the Sv defined by the expression (1) is 3.5 or more. Such a configuration allows the mark to have improved discriminating power with a CCD camera through the polyimide without influence of the type and the thickness of a substrate resin. A polyimide substrate having excellent visibility can be thus manufactured. Consequently positioning accuracy by marking is improved in a predetermined processing of a polyimide substrate in a step for manufacturing an electronic substrate or the like. The effects such as improved yields are thus obtained. Sv is preferably 3.9 or more, more preferably 4.5 or more, still more preferably 5.0 or more, and still more preferably 5.5 or more. Although it is not needed to specify the upper limit of Sv, which may be, for example, 70 or less, 30 or less, 15 or less, or 10 or less. Such a configuration allows for a clearer boundary between a mark and a portion other than a mark, improving positioning accuracy with less error in mark image recognition. More accurate alignment is thus achieved.

### (Surface Area Ratio of Copper Foil Surface)

The ratio D/C of the three dimensional surface area D on one surface of a copper foil to the two dimensional surface area C greatly affects the transparency of the above-mentioned resin. Namely, for the same surface roughness Rz, the smaller the ratio D/C of a copper foil, the better transparency of the resin is achieved. Consequently, the ratio D/C of the surface treated copper foil of the present invention is preferably 1.0 to 1.7, more preferably 1.0 to 1.6. In the specification, the ratio D/C of the three dimensional surface area D on the side of the surface treated surface to the two dimensional surface area C can be, for example, in the case of roughening treated surface, the ratio D/C of the surface area D of roughened grains to the area C of the copper foil shown in the plan view from the copper foil surface side.

The surface state of the copper foil after the surface treatment, and the morphology and the packing density of roughened grains are determined by control of the current density and the plating time of the surface treatment during the surface treatment such as roughened grain formation, so that the surface roughness Rz, the glossiness, the surface area ratio D/C of the copper foil, the Sv, the ΔB, the Rq, the Rsk, and the ratio E/G of the projection portion volume E to the surface area G of the copper foil can be controlled.

[Etching Factor]

In the case that the etching factor value in formation of a circuit by use of a copper foil is large, a skirting portion of the circuit bottom, caused in etching, is small and the space between circuits can be narrow. Consequently, a larger etching factor value is preferable because of being suitable for circuit formation by a fine pattern. The surface treated copper foil of the present invention preferably has, for example, an etching factor value of 1.8 or more, preferably 2.0 or more, preferably 2.2 or more, preferably 2.3 or more, more preferably 2.4 or more.

With respect to the printed wiring board or the copper clad laminate, the grain area ratio (A/B), the glossiness, the surface roughness Rz, the Sv, the ΔB, the Rq, the Rsk, and the ratio E/G of the projection portion volume E to the surface area G of the copper circuit or the copper foil surface can be measured after the resin is molten and removed.

[Transmission Loss]

In the case of a small transmission loss, signal attenuation in signal transmission at a high frequency is suppressed, and stable signal transmission can be thus performed in a circuit where signal transmission is performed at a high frequency. Consequently, a smaller transmission loss value is preferable because of being suitable for use in circuit applications where signal transmission is performed at a high frequency. After lamination of the surface treated copper foil and a commercially available liquid crystal polymer resin (Vecstar CTZ-50 μm made by Kuraray Co., Ltd.), a microstripline is formed by etching such that the characteristic impedance is 50Ω, the permeation coefficient is measured with a network analyzer HP8720C made by HP Development Company, L.P., and the transmission loss is determined at a frequency of 20 GHz. The transmission loss at a frequency of 20 GHz is preferably less than 5.0 dB/10 cm, more preferably less than 4.1 dB/10 cm, still more preferably less than 3.7 dB/10 cm.

In the surface treated copper foil of the present invention, a surface opposite to the joint area of a copper foil to be bonded to a resin substrate (in the present invention, the surface is also referred to as “other surface”) is also surface treated. In lamination of one surface of the surface treated copper foil to the resin substrate, the resin substrate, the surface treated copper foil and a protective film is generally laminated in this order, and laminated by a laminate roll under application of heat and pressure to the protective film. The following problem may be here caused: the protective film is attached to the surface (other surface) opposite to the resin substrate, of the surface treated copper foil (sliding between the surface treated copper foil and the protective film is not made). Such a problem may be caused to result in wrinkles and stripes on other surface of the copper foil. On the contrary, in the present invention, the other surface of the copper foil, otherwise not surface treated, is surface treated. The contact area between the copper foil and the protective film is increased, and the problem of attachment of the protective film to the copper foil in lamination to the resin substrate can be thus well suppressed.

In an aspect of the surface treated copper foil of the present invention, other surface of the treated copper foil surface has a TD ten-spot average roughness Rz measured with a laser microscope using laser light having a wavelength of 405 nm, of 0.35 μm or more. Such a configuration allows for a more increased contact area between the copper foil and the protective film, and the problem of attachment of the protective film to the copper foil in lamination to the resin substrate can be thus well suppressed. In the surface treated copper foil of the present invention, other surface of the treated copper foil surface more preferably has a TD ten-spot average roughness Rz measured with a laser microscope using laser light having a wavelength of 405 nm, of 0.40 μm or more, still more preferably 0.50 μm or more, still more preferably 0.60 μm or more, still more preferably 0.8 μm or more, typically 0.40 to 4.0 μm, more typically 0.50 to 3.0 μm. In the surface treated copper foil of the present invention, although it is not needed to particularly specify the upper limit of the TD ten-spot average roughness Rz measured with a laser microscope using laser light having a wavelength of 405 nm, of other surface of the treated copper foil surface, the upper limit may be typically 4.0 μm or less, more typically 3.0 μm or less, more typically 2.5 μm or less, more typically 2.0 μm or less.

In another aspect of the surface treated copper foil of the present invention, other surface of the treated copper foil surface has a TD arithmetic average roughness Ra measured with a laser microscope using laser light having a wavelength of 405 nm, of 0.05 μm or more. Such a configuration allows for a more increased contact area between the copper foil and the protective film, and the problem of attachment of the protective film to the copper foil in lamination to the resin substrate can be thus well suppressed. In the surface treated copper foil of the present invention, other surface of the treated copper foil surface more preferably has a TD arithmetic average roughness Ra measured with a laser microscope using laser light having a wavelength of 405 nm, of 0.08 μm or more, still more preferably 0.10 μm or more, still more preferably 0.20 μm or more, still more preferably 0.30 μm or more. In the surface treated copper foil of the present invention, although it is not needed to particularly specify the upper limit of the TD arithmetic average roughness Ra measured with a laser microscope using laser light having a wavelength of 405 nm, of other surface of the treated copper foil surface, the upper limit may be typically 0.80 μm or less, more typically 0.65 μm or less, more typically 0.50 μm or less, more typically 0.40 μm or less.

In further another aspect of the surface treated copper foil of the present invention, other surface of the treated copper foil surface has a TD root mean square height Rq measured with a laser microscope using laser light having a wavelength of 405 nm, of 0.08 μm or more. Such a configuration allows for a more increased contact area between the copper foil and the protective film, and the problem of attachment of the protective film to the copper foil in lamination to the resin substrate can be thus well suppressed. In the surface treated copper foil of the present invention, other surface of the treated copper foil surface more preferably has a TD root mean square height Rq measured with a laser microscope using laser light having a wavelength of 405 nm, of 0.10 μm or more, still more preferably 0.15 μm or more, still more preferably 0.20 μm or more, still more preferably 0.30 μm or more, typically 0.08 to 0.60 μm, more typically 0.10 to 0.50 μm. In the surface treated copper foil of the present invention, although it is not needed to particularly specify the upper limit of the TD root mean square height Rq measured with a laser microscope using laser light having a wavelength of 405 nm, of the surface treated other surface of the copper foil, the upper limit may be typically 0.80 μm or less, more typically 0.60 μm or less, more typically 0.50 μm or less, more typically 0.40 μm or less.

The surface treatment of surface treated other surface of the copper foil of the present invention is not particularly limited, and may be a roughening treatment, or a treatment where a roughening treatment is not performed and the heat-resistant layer or the rustproof layer is provided on the copper foil by plating (plating which is neither normal plating nor roughening plating).

For example, the roughening treatment may be performed with a plating solution including copper sulfate and a sulfuric acid aqueous solution, or the roughening treatment may be performed with a plating solution composed of copper sulfate and a sulfuric acid aqueous solution. The roughening treatment may also be performed by alloy plating such as copper-cobalt-nickel alloy plating, copper-nickel-phosphorus alloy plating and nickel-zinc alloy plating. The roughening treatment can be preferably performed by copper alloy plating. As a copper alloy bath, for example, preferably a plating bath including copper and at least one element other than copper, more preferably a plating bath including copper and at least any one selected from the group consisting of cobalt, nickel, arsenicum, tungsten, chromium, zinc, phosphorus, manganese and molybdenum is used.

The surface treatment of surface treated other surface of the copper foil of the present invention may be a surface treatment other than the roughening treatment and the plating treatment.

A surface treatment by electrolytic polishing may be performed as the surface treatment for forming irregularities on other surface. For example, irregularities can be formed on other surface of the copper foil by electrolytic polishing of other surface of the copper foil in a solution composed of copper sulfate and a sulfuric acid aqueous solution. While electrolytic polishing is generally performed for the purpose of smoothing, it is performed for the contrary purpose to such a usual purpose in the surface treatment of other surface in the present invention because irregularities are formed by electrolytic polishing. A method of forming irregularities by electrolytic polishing may be performed by a known technique. Such a known electrolytic polishing technique for forming irregularities includes methods described in Japanese Patent Laid-Open No. 2005-240132, Japanese Patent Laid-Open No. 2010-059547, and Japanese Patent Laid-Open No. 2010-047842. Examples of specific conditions of the treatment for forming irregularities by electrolytic polishing include:

Treatment solution: Cu: 20 g/L, H₂SO₄: 100 g/L, temperature: 50° C.

Electrolytic polishing current: 15 A/dm²

Electrolytic polishing time: 15 sec.

The surface treatment for forming irregularities on other surface may also form irregularities by, for example, mechanical polishing of other surface. Such mechanical polishing may be performed by a known technique.

After surface treated other surface of the copper foil of the present invention is surface treated, a heat-resistant layer, a rustproof layer and a weather-resistant layer may be provided thereon. The heat-resistant layer, the rustproof layer and the weather-resistant layer may be provided by the method described above, a method described in Experimental Examples, or a known technical method.

The surface treated copper foil of the present invention can be laminated to a resin substrate from one surface side so as to manufacture a laminate. The resin substrate is not specifically limited so long as having characteristics applicable to a printed wiring board or the like. For example, a paper base phenolic resin, a paper base epoxy resin, a synthetic fiber fabric base epoxy resin, a glass fabric and paper composite base epoxy resin, a glass fabric and glass nonwoven fabric composite base epoxy resin, or a glass fabric base epoxy resin can be used for a rigid PWB, while a polyester film, a polyimide film, a liquid crystal polymer (LCP) film, or a TEFLON (registered trademark) film can be used for an FPC.

In the lamination method for a rigid PWB, a prepreg is prepared by impregnating a substrate such as glass fabric with a resin and curing the resin into a semi-cured state. A copper foil is superimposed on the prepreg so as to be hot pressed from the side opposite to the coating layer. A laminate for an FPC can be manufactured by laminating and bonding a copper foil to a substrate such as a polyimide film through an adhesive or without an adhesive under high temperature and high pressure, or by the steps of applying, drying, and curing a polyimide precursor.

The thickness of a polyimide substrate resin is not specifically limited. For example, the thickness may be typically 25 μm or 50 μm.

The laminate of the present invention can be used for various kinds of printed wiring boards (PWB), and the use is not specifically limited. For example, in the view of the number of layers with a conductor pattern, the laminate can be used for a single-sided PWB, a double-sided PWB, and a multi-layer PWB (3-layer or more). In the view of the type of insulating substrate material, the laminate can be used for a rigid PWB, a flexible PWB (FPC), and a rigid flex PWB.

### (Laminate and Positioning Method of Printed Wiring Board Using the Laminate)

The positioning method of a laminate of a surface treated copper foil and a resin substrate of the present invention is described below. First, a laminate of a surface treated copper foil and a resin substrate is prepared. Specific examples of the laminate of a surface treated copper foil and a resin substrate of the present invention include a laminate for an electronic apparatus including a main body substrate, an auxiliary circuit substrate, and a flexible printed substrate for electrically connecting the above-mentioned substrates, formed of a resin substrate such as polyimide of which at least one surface is provided with a copper wiring. The flexible printed substrate is accurately positioned so as to be pressure bonded to the wiring terminals of the main body substrate and the auxiliary circuit substrate. In this case, the laminate is composed of a flexible printed substrate and a main body substrate of which wiring terminals are pressure bonded for lamination, or composed of a flexible printed substrate and a circuit substrate of which wiring terminals are pressure bonded for lamination. The laminate includes a mark formed of a part of the copper wiring or another material. The position of the mark is not specifically limited so long as the position allows for photographing with photographing means such as a CCD camera through the resin for constituting the laminate.

When the mark is photographed with photographing means through the resin of a laminate thus prepared, the position of the mark can be well detected. Based on the position of the mark thus detected, the laminate of the surface treated copper foil and the resin substrate can be well positioned. In the case of using a printed wiring board as a laminate, the position of the mark can be well detected with photographing means by the same positioning method, so that positioning of the printed wiring board can be more accurately performed.

Consequently defects in connection are decreased when a printed wiring board is connected to another printed wiring board, so that yield can be increased. Examples of the method for connecting a printed wiring board to another printed wiring board include known connecting method such as soldering, connection through an anisotropic conductive film (ACF), connection through an anisotropic conductive paste (ACP), and connection through a conductive adhesive. In the present invention, “a printed wiring board” includes a printed wiring board mounted with components, a printed circuit board, and a printed board. Two or more printed wiring boards of the present invention can be connected so that a printed wiring board including two or more printed wiring boards connected to each other can be manufactured. At least one printed wiring board of the present invention and another printed wiring board of the present invention or a printed wiring board other than the printed wiring board of the present invention can be connected to each other. An electronic apparatus may be manufactured using such a printed wiring board. In the present invention, “a copper circuit” includes a copper wiring. A printed wiring board may be manufactured by connecting the printed wiring board of the present invention to a component. A printed wiring board having two or more connected printed wiring boards may be manufactured by connecting at least one printed wiring board of the present invention to another printed wiring board of the present invention or to a printed wiring board other than the printed wiring board of the present invention, and furthermore connecting a printed wiring board having two or more of the connected printed wiring boards of the present invention to a component. “Component” includes an electronic component such as a connector, LCD (Liquid Cristal Display), and a glass substrate for use in LCD, an electronic component (for example, IC chip, LSI chip, VLSI chip and ULSI chip) comprising semiconductor integrated circuits such as IC (Integrated Circuit), LSI (Large scale integrated circuit), VLSI (Very Large scale integrated circuit) and ULSI (Ultra-Large Scale Integrated circuit), a component for shielding an electronic circuit, and a component necessary for securing a cover or the like to a printed wiring board.

The positioning method according to an embodiment of the present invention may include a step of transferring a laminate (including a laminate of a copper foil and a resin substrate and a printed wiring board). In the step of transferring, transferring may be performed, for example, with a conveyor such as a belt conveyor and a chain conveyor, with a transferring device having an arm mechanism, with a transferring device or transferring means for transferring a laminate floated by a gas, with a transferring device or transferring means for transferring a laminate through rotation of approximately cylindrical matters (including rollers and bearings), with a transferring device or transferring means having a hydraulic power source, with a transferring device or transferring means having a pneumatic power source, with a transferring device or transferring means having a motor power source, or with a transferring device or transferring means having a stage such as a gantry moving type linear guide stage, a gantry moving type air guide stage, a stack type linear guide stage, and a linear motor driven stage. Alternatively the transferring step may be performed with known transferring means.

The positioning method according to an embodiment of the present invention may be used in a surface mounting machine and a chip mounter.

The laminate of a surface treated copper foil and a resin substrate to be positioned in the present invention may be a printed wiring board having a resin board and a circuit arranged on the resin board. In this case, the mark may be the above-mentioned circuit.

In the present invention, “positioning” includes “detecting the position of a mark or an object.” In the present invention, “alignment” includes “transferring the mark or the object to a predetermined position on the basis of the detected position after detection of the position of the mark or the object.”

In the case of a printed wiring board, the circuit on the printed wiring board may be used as the mark instead of a printed mark, so that the Sv value can be measured by photographing the circuit with a CCD camera through the resin. In the case of a copper clad laminate, a linearly etched copper may be used as the mark instead of a printed mark, so that the Sv value can be measured by photographing the linear copper with a CCD camera through the resin.

One embodiment of the copper clad laminate of the present invention is a copper clad laminate having an insulating resin substrate and a copper foil arranged on the insulating resin substrate,

wherein the copper foil has one surface facing the insulating resin substrate and other surface treated surface; and
wherein an Sv defined by the expression (1) is 3.5 or more based on a brightness curve, wherein the brightness curve is obtained, after etching the copper foil of the copper clad laminate to provide a linear copper foil, and photographing the linear copper foil through the insulating resin substrate with a CCD camera, from an observation spot versus brightness graph of measurement results of the brightness of the photographed image of the linear copper foil for the respective observation spots along the direction perpendicular to the extending direction of the observed linear copper foil, the top average and the bottom average in the brightness curve extending from an end of the linear copper foil to a portion without the linear copper foil are represented by Bt and Bb, respectively, and the difference between the top average Bt and the bottom average Bb is represented by ΔB (ΔB=Bt−Bb), and wherein t1 represents a value pointing the position of the intersection closest to the surface treated linear copper foil among the intersections of the brightness curve and Bt in the observation spot versus brightness graph, and t2 represents a value pointing the position of the intersection closest to the surface treated linear copper foil among the intersections of the brightness curve and 0.1ΔB in the range from the intersections of the brightness curve and Bt to a depth of 0.1ΔB with Bt as reference.

Furthermore, one embodiment of the copper clad laminate of the present invention is a copper clad laminate configured from an insulating resin substrate, and a surface treated copper foil, one surface of which is laminated onto the insulating substrate,

wherein other surface of the copper foil is surface treated; and
wherein an Sv defined by the expression (1) is 3.5 or more based on a brightness curve: wherein the brightness curve is obtained, after etching the surface treated copper foil of the copper clad laminate to provide a surface treated linear copper foil, and photographing the linear copper foil through the insulating resin substrate, onto which the one surface is laminated, with a CCD camera, from an observation spot versus brightness graph of measurement results of the brightness of the photographed image of the respective observation spots along the direction perpendicular to the extending direction of the observed surface treated linear copper foil, the top average and the bottom average in the brightness curve extending from an end of the surface treated linear copper foil to a portion without the surface treated linear copper foil are represented by Bt and Bb, respectively, and the difference between the top average Bt and the bottom average Bb is represented by ΔB (ΔB=Bt−Bb), and wherein t1 represents a value pointing the position of the intersection closest to the surface treated linear copper foil among the intersections of the brightness curve and Bt in the observation spot versus brightness graph, and t2 represents a value pointing the position of the intersection closest to the surface treated linear copper foil among the intersections of the brightness curve and 0.1ΔB in the range from the intersections of the brightness curve and Bt to a depth of 0.1ΔB with Bt as reference.

The surface treated copper foil of the present invention can be used for the copper foil of the copper clad laminate of the present invention.

If such a copper clad laminate is used to manufacture a printed wiring board, positioning of the printed wiring board can be more accurately performed. Consequently, defects in connection are decreased in connection of one printed wiring board to another printed wiring board, so that yield can be enhanced.

In the printed wiring board or the copper clad laminate of the present invention, a surface (other surface) opposite to the joint area of the copper circuit or the copper foil to be bonded to the resin substrate is also surface treated. When the printed wiring board or the copper clad laminate is allowed to pass through a roll-to-roll manufacturing line, the following problem may be caused: a transporting roll in the manufacturing line is attached to (is not slid with) a surface opposite to the resin substrate, of the printed wiring board or copper clad laminate. If such a problem is caused, wrinkles and stripes are generated on other surface of the copper circuit or the copper foil. On the contrary, the other surface of the printed wiring board or the copper clad laminate of the present invention is surface treated. The contact area between the copper circuit or the copper foil and the protective film is increased, and the problem of attaching to (not sliding with) the transporting roll in the manufacturing line can be thus well suppressed. Furthermore, adhesion properties between other surface, and a dry film and a coverlay is better, and weather resistance of the printed wiring board or the copper clad laminate is thus enhanced.

### EXAMPLES

### Experimental Examples A1-1 to A1-30 and Experimental Examples B1-1 to B1-18

In Experimental Examples A1-1 to A1-30 and Experimental Examples B1-1 to B1-18, each copper foil described in Table 2 and Table 3 was prepared and one surface thereof was plating treated under conditions described in Table 1 as a roughening treatment.

After the roughening plating treatment was performed, a plating treatment for the next heat-resistant layer and rustproof layer formation was performed in Experimental Examples A1-1 to A1-10 and A1-12 to A1-27, and Experimental Examples B1-3, B1-4, B1-6 and B1-9 to B1-14. Formation conditions of heat-resistant layer 1 are shown below.

Solution composition: nickel: 5 to 20 g/L, cobalt: 1 to 8 g/L

pH: 2 to 3

Solution temperature: 40 to 60° C.

Current density: 5 to 20 A/dm²

Amount of coulomb: 10 to 20 As/dm²

The plating time was set to 0.5 to 2.0 sec.

Heat-resistant layer 2 was formed on the copper foil on which heat-resistant layer 1 was applied. Formation conditions of heat-resistant layer 2 are shown below.

Solution composition: nickel: 2 to 30 g/L, zinc: 2 to 30 g/L

pH: 3 to 4

Solution temperature: 30 to 50° C.

Current density: 1 to 2 A/dm²

Amount of coulomb: 1 to 2 As/dm²

In Experimental Examples B1-5, B1-7 and B1-8, the roughening plating treatment was not performed, and heat-resistant layer 3 was directly formed on the copper foil prepared. Formation conditions of heat-resistant layer 3 are shown below.

Solution composition: nickel: 25 g/L, zinc: 2 g/L

pH: 2.5

Solution temperature: 40° C.

Current density: 6 A/dm²

Amount of coulomb: 4.8 As/dm²

Plating time: 0.8 sec.

In Experimental Example B1-15, the roughening plating treatment was not performed, and heat-resistant layer 4 was directly formed on the copper foil prepared. Formation conditions of heat-resistant layer 4 are shown below.

Solution composition: nickel: 0.3 g/L, zinc: 2.5 g/L, pyrophosphoric acid bath

Solution temperature: 40° C.

Current density: 5 A/dm²

Amount of coulomb: 22.5 As/dm²

Plating time: 4.5 sec.

The same surface treatment as in Experimental Example A1-2 was performed in Experimental Example B1-16, the same surface treatment as in Experimental Example A1-10 was performed in Experimental Example B1-17, and the same surface treatment as in Experimental Example A1-11 was performed in Experimental Example B1-18.

A rustproof layer was further formed on the copper foil on which heat-resistant layers 1 and 2, heat-resistant layer 3, or heat-resistant layer 4 were applied. Formation conditions of the rustproof layer are shown below.

Solution composition: potassium dichromate: 1 to 10 g/L, zinc: 0 to 5 g/L

pH: 3 to 4

Solution temperature: 50 to 60° C.

Current density: 0 to 2 A/dm² (for immersion chromate treatment)

Amount of coulomb: 0 to 2 As/dm² (for immersion chromate treatment)

A weather-resistant layer was further formed on the copper foil on which heat-resistant layers 1 and 2, and the rustproof layer were applied. Formation conditions are shown below.

Coating and drying were performed with, as a silane coupling agent having an amino group, N-2-(aminoethyl)-3-aminopropyltrimethoxysilane (Experimental Examples A1-17 and A1-24 to A1-27), N-2-(aminoethyl)-3-aminopropyltriethoxysilane (Experimental Examples A1-1 to A1-16), N-2-(aminoethyl)-3-aminopropylmethyldimethoxysilane (Experimental Examples A1-18, A1-28, A1-29 and A1-30), 3-aminopropyltrimethoxysilane (Experimental Example A1-19), 3-aminopropyltriethoxysilane (Experimental Examples A1-20 and A1-21), 3-triethoxysilyl-N-(1,3-dimethyl-butylidene)propylamine (Experimental Example 22), or N-phenyl-3-aminopropyltrimethoxysilane (Experimental Example A1-23), to form each weather-resistant layer. Such silane coupling agents can also be used in combinations of two or more. In Experimental Examples B1-1 to B1-14, coating and drying were performed in the same manner with N-2-(aminoethyl)-3-aminopropyltrimethoxysilane, to form each weather-resistant layer.

A rolled copper foil was manufactured as follows. A copper ingot having each composition shown in Table 2 and Table 3 was manufactured to be hot rolled. Subsequently, annealing in a continuous annealing line at 300 to 800° C. and cold rolling were repeated such that a rolled sheet having a thickness of 1 to 2 mm was produced. The rolled sheet was annealed in a continuous annealing line at 300 to 800° C. so as to be recrystallized and finally cold rolled into a copper foil having a thickness described in Table 2. In Table 2 and Table 3, “tough pitch copper” described in the column of “type” represents a tough pitch copper in accordance with the standard JIS H 3100 and JIS C 1100, and “oxygen-free copper” represents an oxygen-free copper in accordance with the standard JIS H 3100 and JIS C 1020. “tough pitch copper+Ag: 100 ppm” means that 100 mass ppm of Ag was added to tough pitch copper.

HLP foil made by JX Nippon Mining & Metals Corporation, was used as the electrolyte copper foil. In the case that electrolytic polishing or chemical polishing was performed, the thickness of the foil after electrolytic polishing or chemical polishing was described.

In Tables 2 and 3, the key points in the step of manufacturing a copper foil before surface treatment are described. “High gloss rolling” means that the final cold rolling (cold rolling after final recrystallization annealing) was performed at the described oil film equivalent. “Normal rolling” means that the final cold rolling (cold rolling after final recrystallization annealing) was performed at the described oil film equivalent. “Chemical polishing” and “electrolytic polishing” were performed under the following conditions.

“Chemical polishing” was performed with an etching solution including 1 to 3 mass % of H₂SO₄, 0.05 to 0.15 mass % of H₂O₂ and the balance of water for a polishing time of 1 hour.

“Electrolytic polishing” was performed under conditions of 67% of phosphoric acid, 10% of sulfuric acid and 23% of water at a voltage of 10 V/cm² for a time described in Table 2 (when the electrolytic polishing was performed for 10 sec., the amount of polishing was 1 to 2 μm.).

### Experimental Examples A2-1 to A2-7, B2-1 to B2-2, A3-1 to A3-9, B3-1 to B3-5, A4-1 to A4-8 and B4-1 to B4-5

Each copper foil described in Tables 6, 8 and 10 was prepared and one surface thereof was surface treated under conditions described in Tables 7, 9 and 11 in Experimental Examples. A copper foil not roughening treated was also prepared. “Absent” and “present” in the column of “roughening treatment” in “surface treatment” mean that the surface treatment was not a roughening treatment and the surface treatment was a roughening treatment, respectively.

A rolled copper foil (“tough pitch copper” in the column of “type” in Tables representing a rolled copper foil.) was manufactured as follows. A prescribed copper ingot was manufactured to be hot rolled. Subsequently, annealing in a continuous annealing line at 300 to 800° C. and cold rolling were repeated such that a rolled sheet having a thickness of 1 to 2 mm was produced. The rolled sheet was annealed in a continuous annealing line at 300 to 800° C. so as to be recrystallized and finally cold rolled to a copper foil having a final thickness described in Table 1. “Tough pitch copper” in Tables represents a tough pitch copper in accordance with the standard JIS H 3100 and JIS C 1100.

In Tables, the key points in the step of manufacturing a copper foil before surface treatment on one surface are described. “High gloss rolling” means that the final cold rolling (cold rolling after final recrystallization annealing) was performed at the described oil film equivalent. Copper foils having thicknesses of 6 μm, 12 μm and 35 μm were also produced and evaluated in Experimental Examples A3-1, A3-2, A4-1 and A4-2. Consequently, the same results were obtained in the case that the thickness of the copper foil was 18 μm.

In predetermined Experimental Examples, other surface of the copper foil was surface treated as described in Table 12 to Table 15.

Various evaluations of each sample thus made in Examples were performed as follows.

Measurement of Surface Roughness (Rz)

With regard to the surface treated copper foil in Examples, the ten-spot average roughness of one surface was measured in accordance with JIS B 0601-1994 with a contact roughness meter Surfcorder SE-3C made by Kosaka Laboratory Ltd. The measurement was performed under the following conditions: measurement reference length: 0.8 mm; evaluation length: 4 mm; cutoff value: 0.25 mm; and feed rate: 0.1 mm/s. The measurement position was changed in the perpendicular direction (TD) to the rolling direction or the movement direction of an electrolyte copper foil in the manufacturing device of the electrolyte copper foil, such that the measurement was performed 10 times, respectively. The value was obtained from the 10 times measurement.

The surface roughness (Rz) of the copper foil before surface treatment was also obtained in the same way, in advance.

In the case that the copper foil surface was surface treated for providing a heat-resistant layer, a rustproof layer, a weather-resistant layer, and the like after being roughening treated or not being roughening treated, the surface of the surface treated copper foil after the surface treatment for providing a heat-resistant layer, a rustproof layer, a weather-resistant layer, and the like was used for the measurement.

The surface roughness of other surface after a surface treatment in each Experimental Example is preferably measured with a non-contact type method. Specifically, the surface state of other surface after a surface treatment in each Experimental Example is evaluated as a roughness value measured with a laser microscope, because the surface state can be evaluated in more detail.

The surface roughness (ten-spot average roughness) Rz of surface treated other surface of the copper foil was measured with a laser microscope OLS4000 made by Olympus Corporation in accordance with JIS B0601 1994. The observation of the copper foil surface by use of an objective lens with a magnifying power of 50 was performed under conditions of an evaluation length of 258 μm and a cutoff value of zero. With regard to a rolled copper foil, the values were measured in the perpendicular direction (TD) to the rolling direction. With regard to an electrolyte copper foil, the values were measured in the perpendicular direction (TD) to the movement direction of the electrolyte copper foil in the manufacturing device of the electrolyte copper foil. The surface roughness Rz was measured with the laser microscope at an environment temperature of 23 to 25° C. The Rz was measured at any 10 points, and the average of the Rz values at the ten points was defined as the surface roughness (ten-spot average roughness) Rz. The wavelength of laser light of the laser microscope used in the measurement was 405 nm.

Measurement of Surface Root Mean Square Height Rq;

The root mean square height Rq of one surface of a copper foil after a surface treatment in each Experimental Example was measured with a laser microscope OLS4000 made by Olympus Corporation. The observation of the copper foil surface with a magnifying power of 1000 was performed under conditions of an evaluation length of 647 μm and a cutoff value of zero. With regard to a rolled copper foil, the values were measured in the perpendicular direction (TD) to the rolling direction. With regard to an electrolyte copper foil, the values were measured in the perpendicular direction (TD) to the movement direction of the electrolyte copper foil in the manufacturing device of the electrolyte copper foil. The surface root mean square height Rq was measured with the laser microscope at an environment temperature of 23 to 25° C.

Furthermore, the root mean square height Rq of surface treated other surface of the copper foil was measured with a laser microscope OLS4000 made by Olympus Corporation in accordance with JIS B0601 2001. The observation of the copper foil surface by use of an objective lens with a magnifying power of 50 was performed under conditions of an evaluation length of 258 μm and a cutoff value of zero. With regard to a rolled copper foil, the values were measured in the perpendicular direction (TD) to the rolling direction. With regard to an electrolyte copper foil, the values were measured in the perpendicular direction (TD) to the movement direction of the electrolyte copper foil in the manufacturing device of the electrolyte copper foil. The surface root mean square height Rq was measured with the laser microscope at an environment temperature of 23 to 25° C. The Rq was measured at any 10 points, and the average of the Rq values at the ten points was defined as the root mean square height Rq. The wavelength of laser light of the laser microscope used in the measurement was 405 nm.

Measurement of Surface Skewness Rsk;

The skewness Rsk of one surface of a copper foil, of the surface treated surface of a copper foil after a surface treatment in each Experimental Example, was measured with a laser microscope OLS4000 made by Olympus Corporation. The Rsk was in accordance with JIS B0601 2001. The surface observation of a copper foil with a magnifying power of 1,000 was performed under conditions with an evaluation length of 647 μm and a cutoff value of zero. With regard to a rolled copper foil, the values were measured in the perpendicular direction (TD) to the rolling direction. With regard to an electrolyte copper foil, the values were measured in the perpendicular direction (TD) to the movement direction of the electrolyte copper foil in a manufacturing device of electrolyte copper foil. The surface skewness Rsk was measured with the laser microscope at an environment temperature of 23 to 25° C.

Measurement of Surface Arithmetic Average Roughness Ra;

The surface roughness Ra of other surface of a copper foil after a surface treatment in each Experimental Example was measured with a laser microscope OLS4000 made by Olympus Corporation in accordance with JIS B0601-1994. The observation of the copper foil surface by use of an objective lens with a magnifying power of 50 was performed under conditions of an evaluation length of 258 μm and a cutoff value of zero. With regard to a rolled copper foil, the values were measured in the perpendicular direction (TD) to the rolling direction. With regard to an electrolyte copper foil, the values were measured in the perpendicular direction (TD) to the movement direction of the electrolyte copper foil in the manufacturing device of the electrolyte copper foil. The surface arithmetic average roughness Ra was measured with the laser microscope at an environment temperature of 23 to 25° C. The Ra was measured at any 10 points, and the average of the Ra values at the ten points was defined as the arithmetic average roughness Ra. The wavelength of laser light of the laser microscope used in the measurement was 405 nm.

Measurement of Ratio E/G of Projection Portion Volume E to Surface Area G of Copper Foil Surface;

The surface area G of one surface of a copper foil after a surface treatment in each Experimental Example, shown in plan view, and the projection portion volume E were measured with a laser microscope OLS4000 made by Olympus Corporation, and the ratio E/G was calculated. The value was determined under conditions of an evaluation area of 647 μm×646 μm and a cutoff value of zero. The surface area G shown in plan view and the projection portion volume E were measured with the laser microscope at an environment temperature of 23 to 25° C.

Area Ratio (D/C);

The surface area of one surface of a copper foil after a surface treatment in each Experimental Example was measured with a laser microscope. The three-dimensional surface area D for an equivalent area (surface area shown in plan view) C of 647 μm×646 μm (417,953 μm² in actual data), of the treated surface of a copper foil after a surface treatment in each Experimental Example, was measured with a laser microscope OLS4000 made by Olympus Corporation with a magnifying power of 20. The ratio was calculated by the following expression: three-dimensional surface area D÷two-dimensional surface area C=area ratio (D/C). The three-dimensional surface area B was measured with the laser microscope at an environment temperature of 23 to 25° C.

Grain Area Ratio (A/B);

The surface area of roughened grains was measured with a laser microscope. The three-dimensional surface area A for an equivalent area B of 100×100 μm (9982.52 μm² in actual data), of one roughening treated surface, was measured with a laser microscope VK8500 made by Keyence Corporation with a magnifying power of 2000, and the ratio was obtained by the following expression: three-dimensional surface area A÷two-dimensional surface area B=area ratio (A/B). With respect to a copper foil surface not roughening treated, the measurement was performed and the ratio was calculated by the following expression: three-dimensional surface area A÷two-dimensional surface area B=area ratio (A/B).

In the case that one surface of a copper foil surface was surface treated for providing a heat-resistant layer, a rustproof layer, a weather-resistant layer, and the like after the copper foil surface was roughening treated or not roughening treated, the surface of the surface treated copper foil after the surface treatment for providing a heat-resistant layer, a rustproof layer, a weather-resistant layer, and the like was used for the measurement.

Glossiness;

The glossiness of one surface treated surface (roughened surface in the case that the surface treatment was a roughening treatment) was measured with a gloss meter, Handy Gloss Meter PG-1 made by Nippon Denshoku Industries Co., Ltd., in accordance with JIS Z 8741 in each of the rolling direction (MD, the passing direction in the case of an electrolyte copper foil) and the perpendicular direction to the rolling direction (TD, the perpendicular direction to the passing direction in the case of an electrolyte copper foil) at an incident angle of 60 degrees. In the case that one surface of a copper foil was surface treated for providing a heat-resistant layer, a rustproof layer, a weather-resistant layer, and the like after being roughening treated or not being roughening treated, the surface of the surface treated copper foil after the surface treatment for providing a heat-resistant layer, a rustproof layer, a weather-resistant layer, and the like was used for the measurement. The glossiness of a copper foil before surface treatment was also determined in the same manner.

Gradient of Brightness Curve

A surface treated copper foil was laminated on each of both sides of a polyimide film so that a surface treated surface as one surface thereof faced the polyimide film, and the copper foil was removed by etching (ferric chloride aqueous solution) so as to form a sample film.

In Experimental Examples A1-1 to A1-30 and Experimental Examples B1-1 to B1-14, as the polyimide film, either

(1) a polyimide film having a thickness of 25 μm or 50 μm made by Kaneka Corporation [PIXEO (polyimide type: FRS), a polyimide film provided with an adhesive layer for a copper clad laminate, a PMDA (pyromellitic anhydride) type polyimide film (PMDA-ODA (4,4′-diamino diphenyl ether) type polyimide film)], or
(2) a polyimide film having a thickness of 50 μm made by Du Pont-Toray Co., Ltd. [Kapton (registered trademark), a PMDA (pyromellitic anhydride) type polyimide film (PMDA-ODA (4, 4′-diamino diphenyl ether) type polyimide film)] was used.

In Experimental Examples A2-1 to A2-7, B2-1 to B2-2, A3-1 to A3-9, B3-1 to B3-5, A4-1 to A4-8, and B4-1 to B4-5,

(3) a polyimide film having a thickness of 50 μm made by Kaneka Corporation [Pixeo for a two-layered copper clad laminate (PIXEO (polyimide type: FRS), a polyimide film provided with an adhesive layer for a copper clad laminate, a PMDA (pyromellitic anhydride) type polyimide film (PMDA-ODA (4,4′-diamino diphenyl ether) type polyimide film)] was used.

In evaluation of “visibility (transparency of resin)”, “peel strength (adhesion strength)”, “solder heat resistance evaluation”, and “yield” described later, a polyimide film to be laminated on the surface of a surface treated copper foil according to each Experimental Example is the same as the polyimide film used in evaluation of “gradient of brightness curve” described above.

In the case that one surface of a copper foil was surface treated for providing a heat-resistant layer, a rustproof layer, a weather-resistant layer, and the like after being roughening treated or not being roughening treated, the surface treated copper foil after the surface treatment for providing a heat-resistant layer, a rustproof layer, a weather-resistant layer, and the like was laminated on each of both sides of a polyimide film so that the one surface treated surface faced the polyimide film, and the surface treated copper foil was removed by etching (ferric chloride aqueous solution) so as to form a sample film.

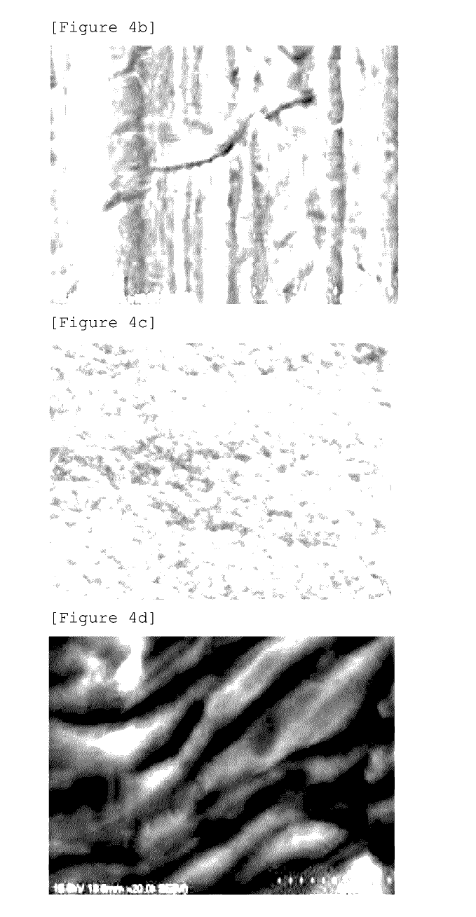

Subsequently, a printed matter with a linear black mark was placed under the sample film and the printed matter was photographed with a CCD camera (a line CCD camera with 8192 pixels) through the sample film. The brightness of the photographed image was measured for the respective observation spots along the direction perpendicular to the extending direction of the observed linear mark, so that an observation spot versus brightness graph was made. From the brightness curve extending from an end of the mark to a portion without the mark, the gradient (angle) was measured. A schematic diagram illustrating the constitution of a photographic device and a method for measuring the gradient of the brightness curve for use in the measurement is shown in FIG. 3.

The ΔB, t1, t2, and Sv were measured with the following photographing device as shown in FIG. 2. One pixel in the transverse axis corresponds to a length of 10 μm.

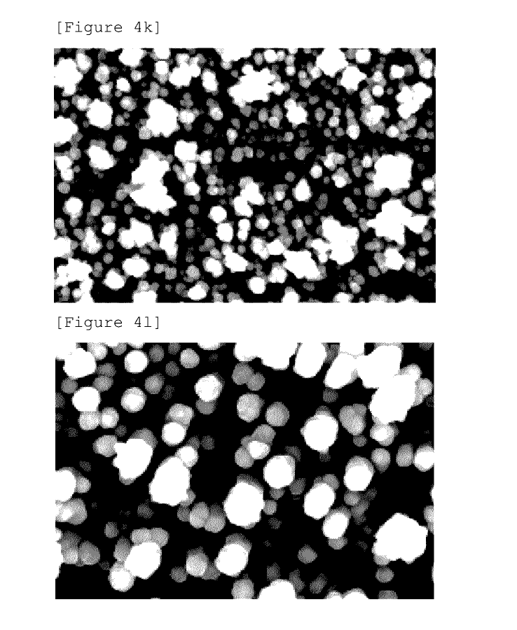

A transparent film printed with various kinds of lines or the like as shown in FIG. 6 as dirt (made by Choyokai Co., Ltd., product name: “dirt measuring chart, full size version,” product number: JQA160-20151-1 (made by National Printing Bureau, Independent Administrative Agency)), which is adopted in both of JIS P 8208 (1998) (FIG. 1: copy of dirt measuring chart) and JIS P 8145 (2011) (appendix JA (standard): dirt comparison chart for visual observation method, and Figure JA. 1: copy of dirt comparison chart for visual observation method), was placed on a sheet of white gloss paper having a glossiness of 43.0±2, for use as the “printed matter with a linear black mark”.

The glossiness of the gloss paper was measured with a gloss meter, Handy Gloss Meter PG-1 made by Nippon Denshoku Industries Co., Ltd., in accordance with JIS Z 8741 at an incident angle of 60 degrees.

The photographing device includes a CCD camera, a stage (white color) on which a polyimide substrate with a marked sheet of paper (a white gloss paper with a dirt) placed thereunder is placed, a lighting power source which allows the photographed part of the polyimide substrate to be irradiated with light, and a transporting machine (not shown in drawing) which transports the polyimide substrate for evaluation with a marked sheet of paper placed thereunder to be photographed onto the stage. The main specifications of the photographing device are as follows:

Photographing device: sheet inspection device Mujiken made by Nireco Corporation;

Line CCD camera: 8,192 pixels (160 MHz), 1,024 gradation digital (10-bit);

Lighting power source: high frequency lighting source (power unit×2); and

Lighting: fluorescent lamp (30 W, model name: FPL27EX-D, twin fluorescent lamp).

A line (width of 0.3 mm) drawn in the dirt in FIG. 6 indicated by arrow was used as the line for measuring above, having an area of 3.0 mm². The viewing field of the line CCD camera was arranged as shown by dotted lines in FIG. 6.

In photographing by a line CCD camera, signals were confirmed in a full scale with 256 gradations, and the lens aperture was adjusted such that the peak gradation signal of the spot where no black mark of a printed matter is present is controlled to be within 230±5 (when the transparent film was placed on the white gloss paper such that the spot other than the printed mark on the dirt was measured with a CCD camera from the transparent film side) in a state that no polyimide film (polyimide substrate) to be measured was placed. The scanning time of the camera (time period when the shutter of a camera is open, i.e., time period for taking light in) was fixed at 250 μs, and the aperture of a lens was adjusted to be within the gradations.

With regard to the brightness shown in FIG. 3, zero means “black,” and a brightness of 255 means “white.” The degree of gray color from “black” to “white” (density of black and white, i.e., gray scale) is thus segmented into 256 gradations for representation.

Visibility (Transparency of Resin);

A surface treated copper foil was laminated on each of both sides of a polyimide film so that a surface treated surface as one surface thereof faced the polyimide, and the copper foil was removed by etching (ferric chloride aqueous solution) so as to form a sample film. In the case that one surface of a copper foil surface was surface treated for providing a heat-resistant layer, a rustproof layer, a weather-resistant layer, and the like after being roughening treated or not roughening treated, the surface treated copper foil after the surface treatment for providing a heat-resistant layer, a rustproof layer, a weather-resistant layer, and the like was laminated on each of both sides of a polyimide film so that one surface thereof faced the polyimide, and the copper foil was removed by etching (ferric chloride aqueous solution) so as to form a sample film. A printed matter (a black circle with a diameter of 6 cm) was attached to one surface of the produced resin layer, and the visibility of the printed matter was determined through the resin layer from the opposite surface. In the evaluation, a sample having a clear contour of the black circle for 90% or more of the circumference length was ranked as “double-circle,” a sample having a clear contour of the black circle for 80% or more and less than 90% of the circumference length was ranked “circle” (the above were rated acceptable), and a sample having a clear contour of the black circle for 0 to less than 80% of the circumference length or having a broken contour was ranked “X-mark” (unacceptable).

Peel Strength (Adhesion Strength)

In accordance with IPC-TM-650, the normal peel strength was measured with a tension testing machine Autograph 100. A sample having a normal peel strength of 0.7 N/mm or higher was determined to be applicable for use in a laminated substrate. In measuring the peel strength, a sample including a polyimide film laminated to the surface treated surface as one surface of a surface treated copper foil in Experimental Examples of the present invention was used. The polyimide film was attached and fixed to a hard base material (a stainless steel plate or a synthetic resin plate (having no deformation during measurement of peel strength)) with a double stick tape or an instant adhesive for the measurement. The unit of the peel strength value in Tables is N/mm.

Solder Heat Resistance Evaluation;

A surface treated copper foil was laminated on each of both sides of a polyimide film so that a surface treated surface as one surface thereof faced the polyimide. A test coupon of the resulting double-sided laminate was produced in accordance with JIS C6471. The produced test coupon was exposed under a high-temperature and high-humidity environment of 85° C. and 85% RH for 48 hours and then floated in a solder bath at 300° C. to evaluate solder heat resistance properties. After the solder heat resistance test, an interface between a roughening treated surface of the copper foil and a polyimide resin adhesive surface was observed. A test coupon where the interface was discolored by swelling in 5% or more of the copper foil area of the test coupon was ranked as “X mark” (unacceptable), a test coupon where swelling and discoloration were observed in less than 5% of the copper foil area of the test coupon was ranked as “circle”, and a test coupon where swelling and discoloration did not occur at all was ranked as “double-circle”. In the case that a copper foil surface was surface treated for providing a heat-resistant layer, a rustproof layer, a weather-resistant layer, and the like after being roughening treated or not being roughening treated, one surface of a surface treated copper foil after the surface treatment for providing a heat-resistant layer, a rustproof layer, a weather-resistant layer, and the like was used for the measurement.

In each Experimental Example, as a polyimide film to be laminated on a surface treated copper foil,

(4) a polyimide film provided with a thermosetting adhesive for lamination [thickness: 50 μm, Upilex made by Ube Industries, Ltd.) (Upilex (registered trademark)-VT, BPDA (biphenyltetracarboxylic dianhydride) type (BPDA-PDA (p-phenylenediamine) type) polyimide resin substrate)] was used for the solder heat resistance evaluation. The results were the same as those in the solder heat resistance evaluation using either the polyimide film (having thickness of 25 μm or 50 μm, made by Kaneka Corporation) in (1) and (3), or the polyimide film (having thickness of 50 μm, made by Du Pont-Toray Co., Ltd.) in (2).

Yield;

A surface treated copper foil was laminated on each of both sides of a polyimide film so that a surface treated surface as one surface thereof faced the polyimide, and the copper foil was etched (ferric chloride aqueous solution) so as to form an FPC having a circuit width with an L/S of 30 μm/30 μm. Subsequently the detection of a 20 μm×20 μm square mark was tried through polyimide with a CCD camera. A mark detectable 9 times or more out of 10 times was rated as “double-circle,” a mark detectable 7 to 8 times was rated as “circle,” a mark detectable 6 times was rated as “triangle,” and a mark detectable 5 times or less was rated as “X-mark.” In the case that one surface of a copper foil was surface treated for providing a heat-resistant layer, a rustproof layer, a weather-resistant layer, and the like after being roughening treated or not being roughening treated, one surface of a surface treated copper foil after the surface treatment for providing a heat-resistant layer, a rustproof layer, a weather-resistant layer, and the like was used for the measurement.

Circuit Geometry by Etching (Fine Pattern Properties);

A surface treated copper foil was laminated on each of both sides of a polyimide film provided with a thermosetting adhesive for lamination (thickness: 50 μm, Upilex made by Ube Industries, Ltd.) (Upilex (registered trademark)-VT, BPDA (biphenyltetracarboxylic dianhydride) type (BPDA-PDA (p-phenylenediamine) type) polyimide resin substrate)) so that a surface treated surface as one surface thereof faced the polyimide. The thickness of a copper foil was required to be uniform among Examples in order to evaluate fine pattern circuit formability, and a thickness of a copper foil of 12 μm was a reference level. That is, in the case that the thickness was more than 12 μm, the thickness was decreased to a thickness of 12 μm by electrolytic polishing. On the other hand, in the case that the thickness was less than 12 μm, the thickness was increased to a thickness of 12 μm by a copper plating treatment. A fine pattern circuit was printed on one surface of the obtained double-sided laminate with a process of coating a copper foil glossy surface of the laminate with a photosensitive resist and exposing the resultant, and an unnecessary region on the copper foil was subjected to an etching treatment under the following conditions so as to form a fine pattern circuit satisfying L/S=20/20 μm. The circuit width here was set so that the bottom width of a circuit cross section was 20 μm.

### (Etching Conditions)

Device: spray type compact etching device
Spray pressure: 0.2 MPa
Etching solution: ferric chloride aqueous solution (specific gravity: 40 Baume)
Solution temperature: 50° C.

A fine pattern circuit was formed, and then immersed in a NaOH aqueous solution at 45° C. for 1 minute so as to peel a photosensitive resist film.

Calculation of Etching Factor (Ef);

The fine pattern circuit sample obtained above was observed from above the circuit with a scanning electron microscope 54700 made by Hitachi High-Technologies Corporation with a magnifying power of 2000, and the top width (Wa) of the upper portion of the circuit and the bottom width (Wb) of the bottom portion of the circuit were measured. The thickness (T) of a copper foil was set to 12 μm. The etching factor (Ef) was calculated by the following expression.

Etching factor (Ef)=(2×T)/(Wb−Wa)

In the case that a copper foil surface was surface treated for providing a heat-resistant layer, a rustproof layer, a weather-resistant layer, and the like after being roughening treated or not being roughening treated, the surface of a surface treated copper foil after the surface treatment for providing a heat-resistant layer, a rustproof layer, a weather-resistant layer, and the like was used for the measurement.

Measurement of Transmission Loss;

Each sample was obtained by laminating one surface of a surface treated copper foil on a commercially available liquid crystal polymer resin (Vecstar CTZ-50 μm made by Kuraray Co., Ltd., a liquid crystal polymer resin as a polycondensate of 6-hydroxy-2-naphthoic acid and p-hydroxybenzoic acid). Subsequently, a microstripline was formed on the sample by etching such that the characteristic impedance was 50Ω, the permeation coefficient was measured with a network analyzer HP8720C made by HP Development Company, L.P., and the transmission loss was determined at a frequency of 20 GHz and a frequency of 40 GHz. In order that evaluation conditions were uniformed as much as possible, the surface treated copper foil and the liquid crystal polymer resin were laminated and then the copper foil thickness was set to 18 μm. That is, in the case that the copper foil thickness more than 18 μm, the thickness was decreased to a thickness of 18 μm by electrolytic polishing. On the other hand, in the case that the copper foil thickness was less than 18 μm, the thickness was increased to a thickness of 18 μm by a copper plating treatment. The transmission loss at a frequency of 20 GHz was ranked as follow: a transmission loss at a frequency of 20 GHz of less than 3.7 dB/10 cm was ranked as “double-circle”, a transmission loss at a frequency of 20 GHz of 3.7 dB/10 cm or more and less than 4.1 dB/10 cm was ranked as “circle”, a transmission loss at a frequency of 20 GHz of 4.1 dB/10 cm or more and less than 5.0 dB/10 cm was ranked as “triangle”, and a transmission loss at a frequency of 20 GHz of 5.0 dB/10 cm or more was ranked as “X mark”.

In the case of a printed wiring board or a copper clad laminate, the respective measurements can be performed with respect to a copper circuit or a copper foil surface by melting and removing a resin.

In the case that one surface of a copper foil was surface treated for providing a heat-resistant layer, a rustproof layer, a weather-resistant layer, and the like after being roughening treated or not being roughening treated, one surface of a surface treated copper foil after the surface treatment for providing a heat-resistant layer, a rustproof layer, a weather-resistant layer, and the like was used for the measurement.

Evaluation of Copper Foil Wrinkles and the Like Caused Due to Lamination;

Each surface treated copper foil in Experimental Examples was laminated on each of both sides of a polyimide resin having a thickness of 25 μm so that one surface thereof faced the polyimide film, and a protective film (made of polyimide) having a thickness of 125 μm was laminated on other surface of each surface treated copper foil, namely, five layers of protective film/surface treated copper foil/polyimide resin/surface treated copper foil/protective film were obtained. Lamination processing was performed with a laminate roll from the outside of each of both the protective films under application of heat and pressure, and the surface treated copper foil was laminated on each of both sides of the polyimide resin. Subsequently, the protective film on each of both surfaces was peeled, surface treated other surface of the copper foil was then visually observed, and the presence of wrinkles or stripes was confirmed. A case where wrinkles and stripes did not occur at all was ranked as “double-circle”, a case where wrinkles or stripes were observed at only one point per a length of a copper foil of 5 m was ranked as “circle”, and a case where wrinkles or stripes were observed at two or more points per a length of a copper foil of 5 m was ranked as “X mark”.

The conditions and the evaluation of the respective tests are described in Tables 1 to 15.

TABLE 1

| | | Current | Plating |
|---|---|---|---|
| | Roughening | density | time |
| | plating bath | (A/dm²) | (sec) |
| Experimental Example | Cu: 15 g/L, | 25 | 1.5 |
| A1-17, A1-25 | Co: 7 g/L | | |
| Experimental Example A1-1, | Ni: 10 g/L | | 2.0 |
| A1-12, A1-15, A1-16 | pH: 3 | | |
| Experimental Example A1-10, | Temperature: 38° C. | | 2.5 |
| A1-13, A1-21, A1-22, A1-23 | | | |
| Experimental Example A1-24 | | | 3.0 |
| Experimental Example B1-13 | | | 3.5 |
| Experimental Example B1-6 | | | 4.0 |
| Experimental Example A1-8, | Cu: 15 g/L, | 35 | 0.5 |
| A1-9, A1-20, A1-27 | Co: 9 g/L | | |
| Experimental Example | Ni: 9 g/L | | 0.7 |
| A1-6, A1-7 | pH: 3 | | |
| Experimental Example | Temperature: 38° C. | | 0.8 |
| A1-4, A1-5 | | | |
| Experimental Example A1-2, | | | 1.4 |
| A1-3, A1-14 | | | |
| Experimental Example | | | 2.0 |
| B1-3, B1-4 | | | |
| Experimental Example A1-30 | | | 0.2 |
| Experimental Example | Cu: 15 g/L, | 45 | 0.5 |
| A1-18, A1-26 | Co: 9 g/L Ni: 9 g/L | | |
| Experimental Example A1-19 | pH: 3 | | 1.0 |
| Experimental Example B1-14 | Temperature: 38° C. | | 1.5 |
| Experimental Example A1-11 | Cu: 20 g/L, | 35 | 1.0 |
| | Ni: 5 g/L P: 1 g/L | | |
| | pH: 2 | | |
| | Temperature: 30° C. | | |
| Experimental Example A1-28 | Cu: 5 g/L, | 35 | 0.8 |
| | Ni: 16 g/L | | |
| | Co: 16 g/L, | | |
| | W: 1 g/L pH: 3 | | |
| | Temperature: 35° C. | | |
| Experimental Example A1-29 | Cu: 10 g/L, | 40 | 0.5 |
| | Ni: 10 g/L | | |
| | Mo: 2 g/L, | | |
| | P: 1 g/L pH: 3 | | |
| | Temperature: 35° C. | | |
| Experimental Example | Cu: 10 g/L, | 60 | 1.5 |
| B1-1, B1-2 | H₂SO₄: 50 g/L | | |
| | Temperature: 25° C. | | |
| Experimental Example B1-9 | Cu: 15 g/L, | 20 | 2.0 |
| | Co: 8.5 g/L | | |
| Experimental Example B1-10 | Ni: 8.6 g/L | 10 | 10.0 |
| Experimental Example B1-11 | pH: 2.5 | 20 | 10.0 |
| Experimental Example B1-12 | Temperature: 38° C. | 20 | 2.0 |

TABLE 2

| | Metal foil (before surface treatment) | | | | | | |
|---|---|---|---|---|---|---|---|
| | | | | Roughness | | | |
| | Type | | Thickness | TD | Glossiness % | | |
| | (ppm represents mass ppm) | Process | (μm) | Rz (μm) | MD | TD | MD/TD |
| Experimental | Tough pitch copper | High gloss rolling, oil film equivalent 24000 | 12 | 0.66 | 397 | 243 | 1.63 |
| Example A1-1 | | | | | | | |
| Experimental | Tough pitch copper | High gloss rolling, oil film equivalent 17000 | 18 | 0.40 | 541 | 507 | 1.07 |
| Example A1-2 | | | | | | | |
| Experimental | Tough pitch copper | High gloss rolling, oil film equivalent 17000 | 18 | 0.40 | 541 | 507 | 1.07 |
| Example A1-3 | | | | | | | |
| Experimental | Tough pitch copper | High gloss rolling, oil film equivalent 17000 | 18 | 0.40 | 541 | 507 | 1.07 |
| Example A1-4 | | | | | | | |
| Experimental | Tough pitch copper | High gloss rolling, oil film equivalent 17000 | 18 | 0.40 | 541 | 507 | 1.07 |
| Example A1-5 | | | | | | | |
| Experimental | Tough pitch copper | High gloss rolling, oil film equivalent 17000 | 18 | 0.40 | 541 | 507 | 1.07 |
| Example A1-6 | | | | | | | |
| Experimental | Tough pitch copper | High gloss rolling, oil film equivalent 17000 | 18 | 0.40 | 541 | 507 | 1.07 |
| Example A1-7 | | | | | | | |
| Experimental | Tough pitch copper | High gloss rolling, oil film equivalent 17000 | 18 | 0.40 | 541 | 507 | 1.07 |
| Example A1-8 | | | | | | | |
| Experimental | Tough pitch copper | High gloss rolling, oil film equivalent 17000 | 18 | 0.40 | 541 | 507 | 1.07 |
| Example A1-9 | | | | | | | |
| Experimental | Tough pitch copper + Ag: 180 ppm | High gloss rolling, oil film equivalent 14000 | 18 | 0.38 | 635 | 580 | 1.09 |
| Example A1-10 | | | | | | | |
| Experimental | Tough pitch copper | High gloss rolling, oil film equivalent 17000 | 18 | 0.50 | 549 | 409 | 1.34 |
| Example A1-11 | | | | | | | |
| Experimental | Oxygen-free copper + Sn: 1200 ppm | Normal rolling, oil film equivalent 30000 + | 5 | 0.75 | 411 | 414 | 0.99 |
| Example A1-12 | | electrolytic polishing (20 sec.) | | | | | |
| Experimental | Oxygen-free copper + Sn: 10 ppm | Normal rolling, oil film equivalent 25000 | 12 | 0.60 | 362 | 351 | 1.03 |
| Example A1-13 | | chemical polishing | | | | | |
| Experimental | Oxygen-free copper + Ag: 30 ppm | High gloss rolling, oil film equivalent | 12 | 0.25 | 792 | 771 | 1.03 |
| Example A1-14 | | 14000 + electrolytic polishing (40 sec.) | | | | | |
| Experimental | Oxygen-free copper + Ag: 100 ppm | Normal rolling, oil film equivalent | 35 | 0.61 | 352 | 330 | 1.07 |
| Example A1-15 | | 25000 + electrolytic polishing (20 sec.) | | | | | |
| Experimental | Oxygen-free copper + Ag: 100 ppm | Normal rolling, oil film equivalent | 35 | 0.61 | 352 | 330 | 1.07 |
| Example A1-16 | | 25000 + electrolytic polishing (20 sec.) | | | | | |
| Experimental | Electrolytic copper foil | Electrolytic copper foil + electrolytic | 5 | 0.68 | 432 | 421 | 1.03 |
| Example A1-17 | | polishing (40 sec.) | | | | | |
| Experimental | Electrolytic copper foil | Electrolytic copper foil + electrolytic | 18 | 0.43 | 610 | 597 | 1.02 |
| Example A1-18 | | polishing (60 sec.) | | | | | |
| Experimental | Oxygen-free copper + Ag: 100 ppm, | High gloss rolling, oil film equivalent 14000 | 12 | 0.36 | 670 | 611 | 1.10 |
| Example A1-19 | Ti: 30 ppm, Mg: 40 ppm | | | | | | |
| Experimental | Fe: 0.3 mass %, P: 0.1 mass % | High gloss rolling, oil film equivalent 14000 | 35 | 0.39 | 592 | 543 | 1.09 |
| Example A1-20 | balance Cu + unavoidable impurities | | | | | | |
| Experimental | Cr: 0.2 mass %, Zr: 0.1 mass % | High gloss rolling, oil film equivalent 14000 | 12 | 0.35 | 681 | 612 | 1.11 |
| Example A1-21 | balance Cu + unavoidable impurities | | | | | | |
| Experimental | Cr: 0.2 mass %, Zr: 0.1 mass % | High gloss rolling, oil film equivalent 14000 | 12 | 0.35 | 681 | 612 | 1.11 |
| Example A1-22 | balance Cu + unavoidable impurities | | | | | | |
| Experimental | Cr: 0.2 mass %, Zr: 0.1 mass % | High gloss rolling, oil film equivalent | 12 | 0.36 | 678 | 651 | 1.04 |
| Example A1-23 | balance Cu + unavoidable impurities | 15000 + electrolytic polishing (5 sec.) | | | | | |
| Experimental | Oxygen-free copper + | High gloss rolling, oil film equivalent 14000 | 18 | 0.38 | 629 | 571 | 1.10 |
| Example A1-24 | Ag: 180 ppm, Sn: 20 ppm | | | | | | |
| Experimental | Tough pitch copper | High gloss rolling, oil film equivalent 24000 | 9 | 0.64 | 401 | 321 | 1.25 |
| Example A1-25 | | | | | | | |
| Experimental | Tough pitch copper | High gloss rolling, oil film equivalent 13000 | 18 | 0.20 | 682 | 620 | 1.10 |
| Example A1-26 | | | | | | | |
| Experimental | Electrolytic copper foil | — | 18 | 0.55 | 520 | 523 | 0.99 |
| Example A1-27 | | | | | | | |
| Experimental | Tough pitch copper | High gloss rolling, oil film equivalent 17000 | 18 | 0.50 | 549 | 409 | 1.34 |
| Example A1-28 | | | | | | | |
| Experimental | Tough pitch copper | High gloss rolling, oil film equivalent 17000 | 18 | 0.50 | 549 | 409 | 1.34 |
| Example A1-29 | | | | | | | |
| Experimental | Tough pitch copper | High gloss rolling, oil film equivalent 17000 | 12 | 0.40 | 541 | 507 | 1.07 |
| Example A1-30 | | | | | | | |

TABLE 3

| | Metal foil (before surface treatment) | | | | | | |
|---|---|---|---|---|---|---|---|
| | Type (ppm represents | | Thickness | Roughness TD | Glossiness % | | |
| | mass ppm) | Process | (μm) | Rz (μm) | MD | TD | MD/TD |
| Experimental Example B1-1 | Tough pitch copper | Normal rolling, oil film equivalent 25000 | 18 | 0.70 | 203 | 195 | 1.04 |
| Experimental Example B1-2 | Tough pitch copper | Normal rolling, oil film equivalent 25000 | 18 | 0.70 | 203 | 195 | 1.04 |
| Experimental Example B1-3 | Tough pitch copper | Normal rolling, oil film equivalent 26000 | 18 | 0.75 | 128 | 167 | 0.77 |
| Experimental Example B1-4 | Tough pitch copper | Normal rolling, oil film equivalent 26000 | 18 | 0.75 | 128 | 167 | 0.77 |
| Experimental Example B1-5 | Tough pitch copper | High gloss rolling, oil film equivalent 24000 | 9 | 0.66 | 397 | 243 | 1.63 |
| Experimental Example B1-6 | Tough pitch copper | High gloss rolling, oil film equivalent 17000 | 12 | 0.40 | 541 | 507 | 1.07 |
| Experimental Example B1-7 | Tough pitch copper | High gloss rolling, oil film equivalent 24000 | 18 | 0.80 | 370 | 321 | 1.15 |
| Experimental Example B1-8 | Tough pitch copper | High gloss rolling, oil film equivalent 24000 | 18 | 0.59 | 404 | 337 | 1.20 |
| Experimental Example B1-9 | Tough pitch copper | Normal rolling, oil film equivalent 26000 | 18 | 0.75 | 128 | 167 | 0.77 |
| Experimental Example B1-10 | Tough pitch copper | Normal rolling, oil film equivalent 26000 | 18 | 0.75 | 128 | 167 | 0.77 |
| Experimental Example B1-11 | Tough pitch copper | Normal rolling, oil film equivalent 26000 | 18 | 0.75 | 128 | 167 | 0.77 |
| Experimental Example B1-12 | Electrolytic copper | — | 12 | 0.71 | 131 | 141 | 0.93 |
| | foil | | | | | | |
| Experimental Example B1-13 | Tough pitch copper | High gloss rolling, oil film equivalent 17000 | 12 | 0.40 | 541 | 507 | 1.07 |
| Experimental Example B1-14 | Electrolytic copper | Electrolytic copper foil + | 18 | 0.43 | 610 | 597 | 1.02 |
| | foil | electrolytic polishing (60 sec.) | | | | | |
| Experimental Example B1-15 | Tough pitch copper | High gloss rolling, oil film equivalent 24000 | 9 | 0.66 | 397 | 243 | 1.63 |

TABLE 4

| | | | Difference | | | | | |
|---|---|---|---|---|---|---|---|---|
| | | | between top | | | | | |
| | Composition of | | average and | | | | | |
| | roughening | | bottom | | | | | |
| | treatment | | average in | | Surface treated metal foil | | | |
| | bath, plating | Resin | brightness | | | Glossiness | | |
| | time | thickness | curve | Sv = 0.1ΔB/ | Roughness | MD | TD | MD/TD |
| | (Table 1) | (μm) | ΔB | (t1 − t2) | TD Rz (μm) | (%) | (%) | (—) |
| Experimental Example A1-1 | 2.0 sec. | 50 | 43 | 3.5 | 0.66 | 91 | 70 | 1.30 |
| Experimental Example A1-2 | 1.4 sec. | 25 | 68 | 6.8 | 0.46 | 94 | 75 | 1.25 |
| Experimental Example A1-3 | 1.4 sec. | 50 | 47 | 5.9 | 0.46 | 94 | 75 | 1.25 |
| Experimental Example A1-4 | 0.8 sec. | 25 | 64 | 6.4 | 0.45 | 143 | 120 | 1.19 |
| Experimental Example A1-5 | 0.8 sec. | 50 | 52 | 5.2 | 0.45 | 143 | 120 | 1.19 |
| Experimental Example A1-6 | 0.7 sec. | 25 | 61 | 6.1 | 0.44 | 222 | 196 | 1.13 |
| Experimental Example A1-7 | 0.7 sec. | 50 | 55 | 5.6 | 0.44 | 222 | 196 | 1.13 |
| Experimental Example A1-8 | 0.5 sec. | 25 | 68 | 5.2 | 0.42 | 298 | 356 | 0.84 |
| Experimental Example A1-9 | 0.5 sec. | 50 | 49 | 6.1 | 0.42 | 298 | 356 | 0.84 |
| Experimental Example A1-10 | 2.5 sec. | 50 | 54 | 3.8 | 0.40 | 90 | 80 | 1.13 |
| Experimental Example A1-11 | 1.0 sec. | 50 | 43 | 3.6 | 0.56 | 122 | 87 | 1.40 |
| Experimental Example A1-12 | 2.0 sec. | 25 | 55 | 5.0 | 0.80 | 134 | 145 | 0.92 |
| Experimental Example A1-13 | 2.5 sec. | 25 | 53 | 4.4 | 0.62 | 101 | 98 | 1.03 |
| Experimental Example A1-14 | 1.4 sec. | 50 | 73 | 5.8 | 0.30 | 349 | 341 | 1.02 |
| Experimental Example A1-15 | 2.0 sec. | 25 | 62 | 6.3 | 0.63 | 209 | 191 | 1.09 |
| Experimental Example A1-16 | 2.0 sec. | 50 | 55 | 5.7 | 0.63 | 209 | 191 | 1.09 |
| Experimental Example A1-17 | 1.5 sec. | 50 | 38 | 3.7 | 0.72 | 115 | 100 | 1.15 |
| Experimental Example A1-18 | 0.5 sec. | 50 | 56 | 4.0 | 0.49 | 142 | 131 | 1.08 |
| Experimental Example A1-19 | 1.0 sec. | 50 | 50 | 5.4 | 0.37 | 112 | 98 | 1.14 |
| Experimental Example A1-20 | 0.5 sec. | 25 | 66 | 6.5 | 0.40 | 295 | 392 | 0.75 |
| Experimental Example A1-21 | 2.5 sec. | 25 | 61 | 6.2 | 0.41 | 181 | 123 | 1.47 |
| Experimental Example A1-22 | 2.5 sec. | 50 | 56 | 5.1 | 0.41 | 181 | 123 | 1.47 |
| Experimental Example A1-23 | 2.5 sec. | 25 | 67 | 6.4 | 0.42 | 182 | 131 | 1.39 |
| Experimental Example A1-24 | 3.0 sec. | 50 | 42 | 4.1 | 0.42 | 80 | 71 | 1.13 |
| Experimental Example A1-25 | 1.5 sec. | 50 | 51 | 5.0 | 0.65 | 120 | 101 | 1.19 |
| Experimental Example A1-26 | 0.5 sec. | 50 | 69 | 6.7 | 0.32 | 122 | 102.0 | 1.20 |
| Experimental Example A1-27 | 0.5 sec. | 25 | 68 | 6.6 | 0.60 | 115 | 114.0 | 1.01 |
| Experimental Example A1-28 | 0.8 sec. | 50 | 55 | 5.4 | 0.54 | 109 | 99.0 | 1.10 |
| Experimental Example A1-29 | 0.5 sec. | 50 | 57 | 5.6 | 0.53 | 118 | 98.0 | 1.20 |
| Experimental Example A1-30 | 0.2 sec. | 50 | 58 | 3.7 | 0.42 | 360 | 301 | 1.20 |

| | Surface treated | | | | | | | |
|---|---|---|---|---|---|---|---|---|
| | metal foil | | | | Solder | | | |
| | Surface | Surface | | Peel | heat | | Etching | |
| | area (A) | area ratio | | strength | resistance | | factor | Transmission |
| | μm² | A/B | Visibility | kg/cm | evaluation | Yield | Ef | loss |
| Experimental Example A1-1 | 20230.4 | 2.03 | ◯ | 1.10 | ⊚ | ⊚ | 2.0 | ◯ |
| Experimental Example A1-2 | 20218.4 | 2.03 | ⊚ | 1.30 | ⊚ | ⊚ | 2.3 | ◯ |
| Experimental Example A1-3 | 20218.4 | 2.03 | ⊚ | 1.40 | ⊚ | ⊚ | 2.3 | ◯ |
| Experimental Example A1-4 | 20086.6 | 2.01 | ⊚ | 1.20 | ⊚ | ⊚ | 2.5 | ⊚ |
| Experimental Example A1-5 | 20086.6 | 2.01 | ⊚ | 1.30 | ⊚ | ⊚ | 2.5 | ⊚ |
| Experimental Example A1-6 | 20076.2 | 2.01 | ⊚ | 1.00 | ⊚ | ⊚ | 2.6 | ⊚ |
| Experimental Example A1-7 | 20076.2 | 2.01 | ⊚ | 1.20 | ⊚ | ⊚ | 2.6 | ⊚ |
| Experimental Example A1-8 | 20185.0 | 2.02 | ⊚ | 1.15 | ⊚ | ⊚ | 2.4 | ⊚ |
| Experimental Example A1-9 | 20185.0 | 2.02 | ⊚ | 1.30 | ⊚ | ⊚ | 2.4 | ⊚ |
| Experimental Example A1-10 | 20364.3 | 2.04 | ⊚ | 1.40 | ⊚ | ⊚ | 2.6 | ⊚ |
| Experimental Example A1-11 | 20190.4 | 2.02 | ⊚ | 1.80 | ⊚ | ⊚ | 2.6 | ⊚ |
| Experimental Example A1-12 | 23988.6 | 2.40 | ⊚ | 1.10 | ⊚ | ⊚ | 2.0 | ◯ |
| Experimental Example A1-13 | 20090.4 | 2.01 | ⊚ | 1.10 | ◯ | ⊚ | 2.2 | ⊚ |
| Experimental Example A1-14 | 18991.0 | 1.90 | ⊚ | 1.00 | ◯ | ⊚ | 2.8 | ⊚ |
| Experimental Example A1-15 | 19790.6 | 1.98 | ⊚ | 1.30 | ◯ | ⊚ | 2.6 | ◯ |
| Experimental Example A1-16 | 19790.6 | 1.98 | ⊚ | 1.40 | ◯ | ⊚ | 2.6 | ◯ |
| Experimental Example A1-17 | 22289.4 | 2.23 | ◯ | 1.60 | ◯ | ◯ | 2.0 | ◯ |
| Experimental Example A1-18 | 23089.0 | 2.31 | ⊚ | 1.50 | ◯ | ⊚ | 2.4 | ⊚ |
| Experimental Example A1-19 | 19990.5 | 2.00 | ⊚ | 1.30 | ⊚ | ⊚ | 2.4 | ⊚ |
| Experimental Example A1-20 | 19890.5 | 1.99 | ⊚ | 1.50 | ◯ | ⊚ | 2.1 | ⊚ |
| Experimental Example A1-21 | 21189.9 | 2.12 | ⊚ | 1.00 | ◯ | ⊚ | 2.5 | ◯ |
| Experimental Example A1-22 | 21189.9 | 2.12 | ⊚ | 1.20 | ◯ | ⊚ | 2.5 | ◯ |
| Experimental Example A1-23 | 21689.7 | 2.17 | ⊚ | 1.15 | ⊚ | ⊚ | 2.5 | ◯ |
| Experimental Example A1-24 | 20364.3 | 2.31 | ⊚ | 1.30 | ⊚ | ◯ | 2.0 | ◯ |
| Experimental Example A1-25 | 20154.3 | 2.02 | ⊚ | 0.85 | ◯ | ⊚ | 2.1 | ◯ |
| Experimental Example A1-26 | 20098.6 | 2.01 | ⊚ | 1.40 | ⊚ | ⊚ | 2.8 | ⊚ |
| Experimental Example A1-27 | 20204.6 | 2.02 | ⊚ | 1.70 | ⊚ | ⊚ | 2.4 | ⊚ |
| Experimental Example A1-28 | 20350.1 | 2.04 | ⊚ | 1.40 | ◯ | ⊚ | 2.5 | ⊚ |
| Experimental Example A1-29 | 20289.0 | 2.03 | ⊚ | 1.40 | ◯ | ⊚ | 2.3 | ⊚ |
| Experimental Example A1-30 | 20087.2 | 2.01 | ⊚ | 0.67 | ◯ | ⊚ | 3.0 | ⊚ |

TABLE 5

| | | | Difference | | | | | |
|---|---|---|---|---|---|---|---|---|
| | | | between top | | | | | |
| | | | average and | | | | | |
| | Composition of | | bottom | | | | | |
| | roughening | | average in | | Surface treated metal foil | | | |
| | treatment bath, | Resin | brightness | | | Glossiness | | |
| | plating time | thickness | curve | Sv = 0.1ΔB/ | Roughness | MD | TD | MD/TD |
| | (Table 1) | (μm) | ΔB | (t1 − t2) | TD Rz (μm) | (%) | (%) | (—) |
| Experimental Example B1-1 | 1.5 sec. | 25 | 25 | 1.4 | 1.10 | 1.6 | 1.8 | 0.89 |
| Experimental Example B1-2 | 1.5 sec. | 50 | 20 | 1.3 | 1.10 | 1.6 | 1.8 | 0.89 |
| Experimental Example B1-3 | 2.0 sec. | 25 | 37 | 2.8 | 0.78 | 0.7 | 0.8 | 0.88 |
| Experimental Example B1-4 | 2.0 sec. | 50 | 27 | 2.3 | 0.78 | 0.7 | 0.8 | 0.88 |
| Experimental Example B1-5 | (No roughening) | 50 | 40 | 3.6 | 0.66 | 406 | 249 | 1.63 |
| Experimental Example B1-6 | 4.0 sec. | 50 | 25 | 2.1 | 0.48 | 19 | 12 | 1.58 |
| Experimental Example B1-7 | (No roughening) | 50 | 60 | 3.7 | 0.80 | 375 | 326 | 1.15 |
| Experimental Example B1-8 | (No roughening) | 50 | 61 | 3.7 | 0.59 | 409 | 342 | 1.20 |
| Experimental Example B1-9 | 2.0 sec. | 50 | 24 | 1.9 | 0.79 | 3.2 | 4.2 | 0.76 |
| Experimental Example B1-10 | 10.0 sec. | 25 | 33 | 3.3 | 0.98 | 1.1 | 1.2 | 0.92 |
| Experimental Example B1-11 | 10.0 sec. | 50 | 21 | 1.9 | 1.34 | 0.5 | 0.4 | 1.25 |
| Experimental Example B1-12 | 2.0 sec. | 25 | 34 | 1.7 | 1.12 | 0.6 | 0.7 | 0.86 |
| Experimental Example B1-13 | 3.5 sec. | 50 | 20 | 1.2 | 0.47 | 75 | 67 | 1.12 |
| Experimental Example B1-14 | 1.5 sec. | 25 | 39 | 3.4 | 0.49 | 142 | 131 | 1.08 |
| Experimental Example B1-15 | (No roughening) | 50 | 38 | 3.4 | 0.66 | 381 | 242 | 1.57 |

| | Surface treated | | | | | | | |
|---|---|---|---|---|---|---|---|---|
| | metal foil | | | | Solder | | | |
| | Surface | Surface | | Peel | heat | | Etching | |
| | area (A) | area ratio | | strength | resistance | | factor | Transmission |
| | μm² | A/B | Visibility | kg/cm | evaluation | Yield | Ef | loss |
| Experimental Example B1-1 | 23790.2 | 2.38 | X | 2.20 | X | X | 1.1 | Δ |
| Experimental Example B1-2 | 23790.2 | 2.38 | X | 2.30 | X | X | 1.1 | Δ |
| Experimental Example B1-3 | 22404.0 | 2.24 | X | 1.80 | X | Δ | 1.8 | Δ |
| Experimental Example B1-4 | 22404.0 | 2.24 | X | 1.95 | X | Δ | 1.8 | Δ |
| Experimental Example B1-5 | 20092.2 | 2.01 | ⊚ | 0.68 | X | ⊚ | 2.5 | ⊚ |
| Experimental Example B1-6 | 20698.5 | 2.07 | X | 1.40 | X | Δ | 1.9 | Δ |
| Experimental Example B1-7 | 15428.2 | 1.54 | ⊚ | 0.50 | X | ⊚ | 2.6 | ◯ |
| Experimental Example B1-8 | 15334.1 | 1.53 | ⊚ | 0.50 | X | ⊚ | 2.1 | ⊚ |
| Experimental Example B1-9 | 20398.5 | 2.04 | X | 1.85 | X | Δ | 1.6 | Δ |
| Experimental Example B1-10 | 20700.0 | 2.07 | X | 1.74 | X | Δ | 1.7 | X |
| Experimental Example B1-11 | 24800.0 | 2.48 | X | 1.93 | X | X | 1.8 | X |
| Experimental Example B1-12 | 24498.2 | 2.45 | X | 2.23 | X | X | 1.3 | X |
| Experimental Example B1-13 | 20698.51 | 2.01 | X | 1.10 | X | X | 1.8 | ◯ |
| Experimental Example B1-14 | 24998.2 | 2.50 | X | 1.80 | X | Δ | 1.9 | ◯ |
| Experimental Example B1-15 | 20904.5 | 2.03 | X | 0.68 | X | X | 2.3 | ⊚ |

TABLE 6

| | Metal foil (before surface treatment) | | | | |
|---|---|---|---|---|---|
| | | | | Rough- | |
| | | | | ness | Glossiness |
| | | | Thick- | TD | TD |
| | Type | Process | ness | Rz (μm) | (%) |
| Example A2-1 | Tough pitch copper | High gloss rolling, oil film | 5 um | 0.40 | 500 |
| | | equivalent 17,000 | | | |
| Example A2-2 | Tough pitch copper + | High gloss rolling, oil film | 70 um | 0.38 | 550 |
| | Ag180 ppm | equivalent 17,000 | | | |
| Example A2-3 | Tough pitch copper | High gloss rolling, oil film | 18 um | 0.50 | 410 |
| | | equivalent 25,000 | | | |
| Example A2-4 | Electrolyte copper foil | Electrolyte copper foil | 18 um | 0.50 | 500 |
| Example A2-5 | Tough pitch copper + Zn200 ppm + | Normal rolling, oil film | 18 um | 0.55 | 310 |
| | Ni200 ppm + Cr50 ppm | equivalent 26,000 | | | |
| Example A2-6 | Oxygen free copper + Ag10 ppm | High gloss rolling, oil film | 18 um | 0.35 | 650 |
| | | equivalent 14,000 | | | |
| Example A2-7 | Oxygen free copper + | High gloss rolling, oil film | 18 um | 0.50 | 410 |
| | Sn2500 ppm | equivalent 25,000 | | | |
| Example B2-1 | Tough pitch copper | Normal rolling, oil film | 18 um | 0.70 | 193 |
| | | equivalent 26,000 | | | |
| Example B2-2 | Tough pitch copper | High gloss rolling, oil film | 18 um | 0.40 | 500 |
| | | equivalent 17,000 | | | |

TABLE 7

| | | Surface treatment | | | | | | | | | | | | |
|---|---|---|---|---|---|---|---|---|---|---|---|---|---|---|
| | Resin | | | | | Rough- | Surface | | | | | | | |
| | thick- | Rough- | | Current | Plating | ness | Area | | Peel | | | | Etching | Trans- |
| | ness | ening | Plating | density | time | TD | ratio | | strength | | | Visi- | factor | mission |
| | (μm) | treatment | bath | (A/dm²) | (sec) | Rz (μm) | A/B | Rsk | (N/mm) | Yield | Sv | bility | EF | loss |
| Example A2-1 | 50 | Present | *1 | 35 | 1.2 | 0.50 | 1.55 | −0.35 | 1.50 | ○ | 3.5 | ○ | 2.0 | ⊚ |
| Example A2-2 | 50 | Present | | 35 | 1.0 | 0.42 | 1.43 | −0.30 | 1.40 | ⊚ | 5.2 | ⊚ | 2.4 | ⊚ |
| Example A2-3 | 50 | Present | *2 | 30 | 1.0 | 0.56 | 1.23 | 0.24 | 1.60 | ⊚ | 3.7 | ⊚ | 2.0 | ⊚ |
| Example A2-4 | 50 | Present | | 35 | 0.8 | 0.65 | 1.10 | 0.13 | 1.70 | ○ | 3.5 | ○ | 2.1 | ⊚ |
| Example A2-5 | 50 | Absent | *3 | 6 | 1.0 | 0.55 | 1.20 | −0.10 | 1.10 | ⊚ | 6.0 | ⊚ | 2.4 | ⊚ |
| Example A2-6 | 50 | Absent | | | | 0.38 | 1.03 | 0.39 | 1.00 | ⊚ | 4.3 | ⊚ | 2.2 | ⊚ |
| Example A2-7 | 50 | Absent | | | | 0.51 | 1.01 | 0.53 | 1.55 | ○ | 3.5 | ○ | 2.0 | ⊚ |
| Example B2-1 | 50 | Present | *1 | 35 | 2.0 | 0.80 | 1.80 | −0.39 | 1.70 | × | 2.8 | × | 1.8 | Δ |

| | | | | | | | | | | | | |
|---|---|---|---|---|---|---|---|---|---|---|---|---|
| Example B2-2 | 50 | Present | *4 | 0.80 | 1.50 | 0.64 | 1.80 | × | 1.8 | × | 1.5 | ○ |

*1 Cu 15 g/L, Co 8.5 g/L, Ni 8.6 g/L, pH 2.5, 38° C.
*2 Cu 10 g/L, Ni 20 g/L, P1 g/L, pH 2.5, 40° C.
*3 Ni 20 g/L, pH 2.5, 40° C.
*4 (Cu 15 g/L, H₂SO₄ 50 g/L, 25° C., 50 A/dm², 1.5 sec) + (Cu 20 g/L, H₂SO₄ 100 g/L, 50° C., 2A/dm², 15 sec)

TABLE 8

| | Metal foil (before surface treatment) | | | | |
|---|---|---|---|---|---|
| | | | | Roughness | Glossiness |
| | | | | TD | TD |
| | Type | Process | Thickness | Rz (μm) | (%) |
| Experimental Example B3-1 | Tough pitch copper | High gloss rolling, oil film equivalent 8,500 | 18 um | 0.12 | 740 |
| Experimental Example A3-1 | Tough pitch copper | High gloss rolling, oil film equivalent 9,500 | 18 um | 0.20 | 710 |
| Experimental Example A3-2 | Electrolytic | Copper 100 g/L, Sulfuric acid 100 g/L, Chlorine 50 ppm, | 18 um | 0.23 | 660 |
| | copper foil | Leveling agent 1:10-30 ppm, Leveling | | | |
| | | agent 2:10-30 ppm, Electrolyte temperature 50-60° C., | | | |
| | | Current density 70-100 A/dm², Electrolysis | | | |
| | | time 1 min, Linear velocity of electrolyte 4 m/sec | | | |
| Experimental Example A3-3 | Tough pitch copper | High gloss rolling, oil film equivalent 12,000 | 18 um | 0.26 | 640 |
| Experimental Example A3-4 | Tough pitch copper | High gloss rolling, oil film equivalent 14,000 | 18 um | 0.40 | 590 |
| Experimental Example A3-5 | Tough pitch copper | High gloss rolling, oil film equivalent 17,000 | 18 um | 0.42 | 500 |
| Experimental Example A3-6 | Tough pitch copper | High gloss rolling, oil film equivalent 17,000 | 18 um | 0.42 | 500 |
| Experimental Example A3-7 | Tough pitch copper | High gloss rolling, oil film equivalent 17,000 | 18 um | 0.42 | 500 |
| Experimental Example A3-8 | Tough pitch copper | High gloss rolling, oil film equivalent 17,000 | 18 um | 0.42 | 500 |
| Experimental Example A3-9 | Tough pitch copper | High gloss rolling, oil film equivalent 17,000 | 18 um | 0.42 | 500 |
| Experimental Example B3-2 | Tough pitch copper | High gloss rolling, oil film equivalent 17,000 | 18 um | 0.42 | 500 |
| Experimental Example B3-3 | Tough pitch copper | High gloss rolling, oil film equivalent 17,000 | 18 um | 0.42 | 500 |
| Experimental Example B3-4 | Tough pitch copper | High gloss rolling, oil film equivalent 18,000 | 18 um | 0.58 | 380 |
| Experimental Example B3-5 | Tough pitch copper | High gloss rolling, oil film equivalent 19,000 | 18 um | 0.61 | 350 |

TABLE 9

| | | Surface treatment | | | | | |
|---|---|---|---|---|---|---|---|
| | Resin | | | Current | Plating | | Surface |
| | thickness | Roughening | | density | time | Roughness | area ratio |
| | (μm) | treatment | Plating bath | (A/dm²) | (sec) | TD Rz (μm) | D/C |
| Experimental Example B3-1 | 50 | Absent | Ni 20 g/L | 6 | 1.0 | 0.12 | 1.0 |
| Experimental Example A3-1 | 50 | Absent | pH 2.5 | | | 0.20 | 1.0 |
| Experimental Example A3-2 | 50 | Absent | 40° C. | | | 0.23 | 1.0 |
| Experimental Example A3-3 | 50 | Absent | | | | 0.26 | 1.0 |
| Experimental Example A3-4 | 50 | Absent | | | | 0.40 | 1.0 |
| Experimental Example A3-5 | 50 | Present | Cu 15 g/L | 30 | 1.0 | 0.43 | 1.2 |
| Experimental Example A3-6 | 50 | Present | Co 8.5 g/L | 35 | 1.0 | 0.46 | 1.4 |
| Experimental Example A3-7 | 50 | Present | Ni 8.6 g/L | 35 | 1.3 | 0.55 | 1.5 |
| Experimental Example A3-8 | 50 | Present | pH 2.5 | 35 | 1.7 | 0.62 | 1.6 |
| Experimental Example A3-9 | 50 | Present | 38° C. | 40 | 1.7 | 0.64 | 1.7 |
| Experimental Example B3-2 | 50 | Present | | 40 | 2.0 | 0.70 | 1.8 |
| Experimental Example B3-3 | 50 | Present | | 50 | 1.5 | 0.74 | 1.9 |
| Experimental Example B3-4 | 50 | Absent | Ni 0.3 g/L | 7 | 5.0 | 0.58 | 1.6 |
| Experimental Example B3-5 | 50 | Absent | Zn 2.5 g/L | 5 | 4.5 | 0.61 | 1.7 |
| | | | Pyrophosphoric | | | | |
| | | | acid 40° C. | | | | |

| | | Peel | Solder heat | | | | | |
|---|---|---|---|---|---|---|---|---|
| | Rq | strength | resistance | | | | Etching | Transmission |
| | (μm) | (N/mm) | evaluation | Yield | Sv | Visibility | factor Ef | loss |
| Experimental Example B3-1 | 0.10 | 0.65 | X | ⊚ | 7.0 | ⊚ | 3.0 | ⊚ |
| Experimental Example A3-1 | 0.14 | 0.70 | ◯ | ⊚ | 7.0 | ⊚ | 3.0 | ⊚ |
| Experimental Example A3-2 | 0.20 | 0.72 | ◯ | ⊚ | 6.5 | ⊚ | 2.8 | ◯ |
| Experimental Example A3-3 | 0.25 | 0.72 | ⊚ | ⊚ | 6.5 | ⊚ | 2.7 | ⊚ |
| Experimental Example A3-4 | 0.32 | 0.76 | ⊚ | ⊚ | 6.0 | ⊚ | 2.6 | ⊚ |
| Experimental Example A3-5 | 0.40 | 0.80 | ⊚ | ⊚ | 6.0 | ⊚ | 2.5 | ⊚ |
| Experimental Example A3-6 | 0.51 | 0.80 | ⊚ | ⊚ | 6.0 | ⊚ | 2.5 | ⊚ |
| Experimental Example A3-7 | 0.56 | 0.82 | ⊚ | ⊚ | 5.0 | ⊚ | 2.3 | ◯ |
| Experimental Example A3-8 | 0.60 | 0.82 | ⊚ | ⊚ | 3.9 | ⊚ | 2.0 | ◯ |
| Experimental Example A3-9 | 0.63 | 0.82 | ⊚ | ◯ | 3.5 | ◯ | 2.0 | ◯ |
| Experimental Example B3-2 | 0.67 | 0.85 | ⊚ | Δ | 3.0 | X | 1.8 | Δ |
| Experimental Example B3-3 | 0.77 | 0.90 | ⊚ | X | 2.5 | X | 1.6 | Δ |
| Experimental Example B3-4 | 0.65 | 0.80 | ⊚ | X | 3.3 | X | 1.9 | ⊚ |
| Experimental Example B3-5 | 0.66 | 0.83 | ⊚ | X | 3.1 | X | 1.9 | ⊚ |

TABLE 10

| | Metal foil (before surface treatment) | | | | |
|---|---|---|---|---|---|
| | | | | Roughness | Glossiness |
| | | | | TD | TD |
| | Type | Process | Thickness | Rz (μm) | (%) |
| Experimental Example B4-1 | Tough pitch copper | High gloss rolling, oil film equivalent 8,500 | 18 um | 0.12 | 740 |
| Experimental Example A4-1 | Tough pitch copper | High gloss rolling, oil film equivalent 9,500 | 18 um | 0.20 | 710 |
| Experimental Example A4-2 | Electrolytic | Copper 100 g/L, Sulfuric acid 100 g/L, Chlorine 50 ppm, | 18 um | 0.23 | 660 |
| | copper foil | Leveling agent 1:10-30 ppm, Leveling | | | |
| | | agent 2:10-30 ppm, Electrolyte temperature 50-60° C., | | | |
| | | Current density 70-100A/dm², Electrolysis | | | |
| | | time 1 min, Linear velocity of electrolyte 4 m/sec | | | |
| Experimental Example A4-3 | Tough pitch copper | High gloss rolling, oil film equivalent 12,000 | 18 um | 0.26 | 640 |
| Experimental Example A4-4 | Tough pitch copper | High gloss rolling, oil film equivalent 14,000 | 18 um | 0.40 | 590 |
| Experimental Example A4-5 | Tough pitch copper | High gloss rolling, oil film equivalent 17,000 | 18 um | 0.42 | 500 |
| Experimental Example A4-6 | Tough pitch copper | High gloss rolling, oil film equivalent 17,000 | 18 um | 0.42 | 500 |
| Experimental Example A4-7 | Tough pitch copper | High gloss rolling, oil film equivalent 17,000 | 18 um | 0.42 | 500 |
| Experimental Example A4-8 | Tough pitch copper | High gloss rolling, oil film equivalent 17,000 | 18 um | 0.55 | 400 |
| Experimental Example B4-2 | Tough pitch copper | High gloss rolling, oil film equivalent 20,000 | 18 um | 0.68 | 200 |
| Experimental Example B4-3 | Tough pitch copper | High gloss rolling, oil film equivalent 20,000 | 18 um | 0.68 | 200 |
| Experimental Example B4-4 | Tough pitch copper | High gloss rolling, oil film equivalent 18,000 | 18 um | 0.58 | 380 |
| Experimental Example B4-5 | Tough pitch copper | High gloss rolling, oil film equivalent 19,000 | 18 um | 0.61 | 350 |

TABLE 11

| | | Surface treatment | | | | | | |
|---|---|---|---|---|---|---|---|---|
| | | | | | | | Surface | |
| | Resin | | | Current | Plating | Roughness | area | |
| | thickness | Roughening | | density | time | TD Rz | ratio | Measurement |
| | (μm) | treatment | Plating bath | (A/dm²) | (sec) | (μm) | D/C | area G (μm²) |
| Experimental | 50 | Absent | Ni 20 g/L | 6 | 1.0 | 0.12 | 1.0 | 417,953 |
| Example B4-1 | | | pH 2.5 | | | | | |
| Experimental | 50 | Absent | 40° C. | | | 0.20 | 1.0 | 417,953 |
| Example A4-1 | | | | | | | | |
| Experimental | 50 | Absent | | | | 0.23 | 1.0 | 417,953 |
| Example A4-2 | | | | | | | | |
| Experimental | 50 | Absent | | | | 0.26 | 1.0 | 417,953 |
| Example A4-3 | | | | | | | | |
| Experimental | 50 | Absent | | | | 0.40 | 1.0 | 417,952 |
| Example A4-4 | | | | | | | | |
| Experimental | 50 | Present | Cu 15 g/L | 35 | 1.0 | 0.46 | 1.4 | 417,953 |
| Example A4-5 | | | Co 8.5 g/L | | | | | |
| Experimental | 50 | Present | Ni 8.6 g/L | 35 | 1.3 | 0.55 | 1.5 | 417,953 |
| Example A4-6 | | | pH 2.5 | | | | | |
| Experimental | 50 | Present | 38° C. | 35 | 1.7 | 0.62 | 1.6 | 417,953 |
| Example A4-7 | | | | | | | | |
| Experimental | 50 | Present | | 40 | 1.7 | 0.64 | 1.7 | 417,953 |
| Example A4-8 | | | | | | | | |
| Experimental | 50 | Present | | 50 | 1.5 | 0.74 | 1.9 | 417,953 |
| Example B4-2 | | | | | | | | |
| Experimental | 50 | Present | | 50 | 2.0 | 0.80 | 2.0 | 417,953 |
| Example B4-3 | | | | | | | | |
| Experimental | 50 | Absent | Ni 0.3 g/L | 7 | 5.0 | 0.58 | 1.6 | 417,953 |
| Example B4-4 | | | Zn 2.5 g/L | | | | | |
| Experimental | 50 | Absent | Pyrophosphoric | 5 | 4.5 | 0.61 | 1.7 | 417,953 |
| Example B4-5 | | | acid 40° C. | | | | | |

| | | | | Solder | | | | | |
|---|---|---|---|---|---|---|---|---|---|
| | Measurement | | Peel | heat | | | | | |
| | volume E | | strength | resistance | | | | Etching | Transmission |
| | (μm³) | E/G | (N/mm) | evaluation | Yield | Sv | Visibility | factor Ef | loss |
| Experimental | 758,685 | 1.82 | 0.65 | X | ⊚ | 7.0 | ⊚ | 3.0 | ⊚ |
| Example B4-1 | | | | | | | | | |
| Experimental | 882,196 | 2.11 | 0.70 | ◯ | ⊚ | 7.0 | ⊚ | 3.0 | ⊚ |
| Example A4-1 | | | | | | | | | |
| Experimental | 1,020,383 | 2.44 | 0.72 | ◯ | ⊚ | 6.5 | ⊚ | 2.8 | ◯ |
| Example A4-2 | | | | | | | | | |
| Experimental | 1,232,196 | 2.95 | 0.72 | ◯ | ⊚ | 6.5 | ⊚ | 2.7 | ⊚ |
| Example A4-3 | | | | | | | | | |
| Experimental | 2,844,915 | 6.81 | 0.76 | ⊚ | ⊚ | 6.0 | ⊚ | 2.6 | ⊚ |
| Example A4-4 | | | | | | | | | |
| Experimental | 4,407,151 | 10.54 | 0.80 | ⊚ | ⊚ | 6.0 | ⊚ | 2.5 | ⊚ |
| Example A4-5 | | | | | | | | | |
| Experimental | 5,560,760 | 13.30 | 0.82 | ⊚ | ⊚ | 5.0 | ⊚ | 2.3 | ◯ |
| Example A4-6 | | | | | | | | | |
| Experimental | 8,954,423 | 21.42 | 0.82 | ⊚ | ⊚ | 3.9 | ⊚ | 2.0 | ◯ |
| Example A4-7 | | | | | | | | | |
| Experimental | 9,994,423 | 23.91 | 0.82 | ⊚ | ◯ | 3.5 | ◯ | 2.0 | ◯ |
| Example A4-8 | | | | | | | | | |
| Experimental | 10,665,609 | 25.52 | 0.90 | ⊚ | X | 2.5 | X | 1.6 | Δ |
| Example B4-2 | | | | | | | | | |
| Experimental | 13,665,609 | 32.70 | 0.95 | ⊚ | X | 1.5 | X | 1.2 | Δ |
| Example B4-3 | | | | | | | | | |
| Experimental | 9,800,998 | 23.45 | 0.80 | ⊚ | X | 3.3 | X | 1.9 | ⊚ |
| Example B4-4 | | | | | | | | | |
| Experimental | 11,418,476 | 27.32 | 0.83 | ⊚ | X | 3.1 | X | 1.9 | ⊚ |
| Example B4-5 | | | | | | | | | |

TABLE 12

| | Surface treatment of other surface | | | | | | Wrinkles or |
|---|---|---|---|---|---|---|---|
| | | Current | | Rz of other | Ra of other | Rq of other | stripes on |
| | | density | Plating time | surface | surface | surface | other |
| | Plating bath | (A/dm²) | (sec) | (μm) | (μm) | (μm) | surface |
| A1-1 | Cu: 15 g/L, | 15 | 15 | 0.81 | 0.1 | 0.14 | ⊚ |
| A1-2 | Co: 9 g/L, | | | 0.61 | 0.06 | 0.1 | ⊚ |
| A1-3 | Ni: 9 g/L | | | 0.61 | 0.06 | 0.1 | ⊚ |
| A1-4 | pH: 3 | 20 | 3 | 0.75 | 0.07 | 0.11 | ⊚ |
| A1-5 | Temperature: 38° C. | | | 0.75 | 0.07 | 0.11 | ⊚ |
| A1-6 | | | | 0.75 | 0.07 | 0.11 | ⊚ |
| A1-7 | | 25 | 2 | 0.62 | 0.06 | 0.1 | ⊚ |
| A1-8 | | | | 0.62 | 0.06 | 0.1 | ⊚ |
| A1-9 | | | | 0.62 | 0.06 | 0.1 | ⊚ |
| A1-10 | | 30 | 1 | 0.42 | 0.05 | 0.09 | ◯ |
| A1-11 | | | | 0.65 | 0.06 | 0.1 | ⊚ |
| A1-12 | | | | 0.85 | 0.07 | 0.15 | ⊚ |
| A1-13 | | 35 | 1 | 0.68 | 0.06 | 0.11 | ⊚ |
| A1-14 | | | | 0.35 | 0.05 | 0.08 | ◯ |
| A1-15 | | | | 0.59 | 0.06 | 0.09 | ⊚ |
| A1-16 | | 40 | 3 | 1.06 | 0.09 | 0.15 | ⊚ |
| A1-17 | | | | 1.15 | 0.1 | 0.16 | ⊚ |
| A1-18 | | | | 1.25 | 0.11 | 0.18 | ⊚ |
| A1-19 | Cu: 10 g/L, | 60 | 2 | 1.4 | 0.16 | 0.23 | ⊚ |
| A1-20 | H2SO4: 50 g/L, | | | 1.45 | 0.17 | 0.24 | ⊚ |
| A1-21 | Temperature: 25° C. | | | 1.55 | 0.2 | 0.27 | ⊚ |
| A1-22 | Cu: 20 g/L, | 40 | 15 | 0.67 | 0.06 | 0.1 | ⊚ |
| A1-23 | H2SO4: 100 g/L, | | | 0.68 | 0.07 | 0.1 | ⊚ |
| A1-24 | Temperature: 50° C. | | | 0.7 | 0.07 | 0.12 | ⊚ |
| A1-25 | Cu: 20 g/L, | 40 | 0.5 | 0.67 | 0.07 | 0.1 | ⊚ |
| A1-26 | Ni: 5 g/L, | | 1 | 0.36 | 0.05 | 0.08 | ◯ |
| A1-27 | P: 1 g/L, | | 2 | 0.52 | 0.06 | 0.09 | ⊚ |
| | pH: 2, | | | | | | |
| | Temperature: 30° C. | | | | | | |
| A1-28 | Ni: 30 g/L, | 1.5 | 10 | 0.61 | 0.06 | 0.1 | ⊚ |
| A1-29 | Zn: 10 g/L, | | | 0.65 | 0.06 | 0.1 | ⊚ |
| A1-30 | pH: 5 | | | 0.68 | 0.06 | 0.11 | ⊚ |
| | Temperature: 40° C. | | | | | | |
| B1-5 | Cu: 15 g/L, | 30 | 0.8 | 0.73 | 0.07 | 0.11 | ⊚ |
| B1-7 | Co: 9 g/L, | | | 0.84 | 0.11 | 0.14 | ⊚ |
| B1-8 | Ni: 9 g/L | | | 0.66 | 0.06 | 0.09 | ⊚ |
| | pH: 3 | | | | | | |
| | Temperature: 38° C. | | | | | | |
| B1-1 | No treatment | — | — | 0.6 | 0.06 | 0.1 | X |
| B1-2 | | | | 0.61 | 0.06 | 0.1 | X |
| B1-3 | | | | 0.65 | 0.06 | 0.1 | X |
| B1-4 | | | | 0.65 | 0.06 | 0.1 | X |
| B1-6 | | | | 0.34 | 0.04 | 0.07 | X |
| B1-9 | | | | 0.65 | 0.06 | 0.1 | X |
| B1-10 | | | | 0.65 | 0.06 | 0.1 | X |
| B1-11 | | — | — | 0.65 | 0.06 | 0.1 | X |
| B1-12 | | | | 0.6 | 0.06 | 0.1 | X |
| B1-13 | | | | 0.34 | 0.04 | 0.06 | X |
| B1-14 | | | | 0.38 | 0.04 | 0.07 | X |
| B1-15 | | | | 0.59 | 0.05 | 0.09 | X |
| B1-16 | No treatment | — | — | 0.31 | 0.038 | 0.053 | X |
| B1-17 | No treatment | — | — | 0.27 | 0.033 | 0.045 | X |
| B1-18 | No treatment | — | — | 0.34 | 0.04 | 0.07 | X |

TABLE 13

| | Surface treatment of other surface | | | | | | Wrinkles or |
|---|---|---|---|---|---|---|---|
| | | Current | | Rz of other | Ra of other | Rq of other | stripes on |
| | | density | Plating | surface | surface | surface | other |
| | Plating bath | (A/dm²) | time (sec) | (μm) | (μm) | (μm) | surface |
| A2-1 | Cu: 15 g/L, | 25 | 1.5 | 0.59 | 0.06 | 0.1 | ⊚ |
| A2-2 | Co: 7 g/L, | | | 0.4 | 0.05 | 0.09 | ◯ |
| A2-3 | Ni: 7 g/L | 35 | 1 | 0.65 | 0.06 | 0.1 | ⊚ |
| A2-4 | pH: 3 | | | 0.63 | 0.06 | 0.1 | ⊚ |
| A2-5 | Temperature: 38° C. | 40 | 0.7 | 0.71 | 0.07 | 0.12 | ⊚ |
| A2-6 | Cu: 20 g/L, | 35 | 15 | 0.35 | 0.05 | 0.08 | ⊚ |
| A2-7 | H2SO4: 100 g/L, | | | 0.59 | 0.06 | 0.09 | ⊚ |
| | Temperature: 50° C. | | | | | | |
| B2-1 | No surface treatment | — | — | 0.75 | 0.07 | 0.08 | X |
| B2-2 | | | | 0.5 | 0.06 | 0.08 | X |

TABLE 14

| | Surface treatment of other surface | | | | | | Wrinkles or |
|---|---|---|---|---|---|---|---|
| | | Current | | Rz of other | Ra of other | Rq of other | stripes on |
| | | density | Plating | surface | surface | surface | other |
| | Plating bath | (A/dm²) | time (sec) | (μm) | (μm) | (μm) | surface |
| A3-1 | Cu: 15 g/L, | 25 | 1 | 0.35 | 0.05 | 0.08 | ◯ |
| A3-2 | Co: 7 g/L, | | | 0.36 | 0.05 | 0.08 | ◯ |
| A3-3 | Ni: 7 g/L, | 30 | 1 | 0.37 | 0.06 | 0.1 | ⊚ |
| A3-4 | pH: 3 | | | 0.39 | 0.07 | 0.12 | ⊚ |
| A3-5 | Temperature: 38° C. | 35 | 2 | 1.21 | 0.18 | 0.25 | ⊚ |
| A3-6 | | | | 1.33 | 0.23 | 0.61 | ⊚ |
| A3-7 | | 40 | 2 | 1.64 | 0.28 | 0.67 | ⊚ |
| B3-1 | | 40 | 1 | 0.35 | 0.05 | 0.08 | ◯ |
| A3-8 | Cu: 20 g/L, H2SO4: 100 g/L, | 15 | 15 | 0.44 | 0.06 | 0.12 | ⊚ |
| A3-9 | Temperature 50° C. | 20 | | 0.56 | 0.07 | 0.15 | ⊚ |
| | (electrolytic polishing) | | | | | | |
| B3-2 | No surface treatment | — | — | 0.34 | 0.04 | 0.07 | X |
| B3-3 | | | | 0.34 | 0.04 | 0.07 | X |
| B3-4 | | | | 0.53 | 0.05 | 0.08 | X |
| B3-5 | | | | 0.56 | 0.06 | 0.09 | X |

TABLE 15

| | Surface treatment of other surface | | | | | | Wrinkles or |
|---|---|---|---|---|---|---|---|
| | | Current | | Rz of other | Ra of other | Rq of other | stripes on |
| | | density | Plating | surface | surface | surface | other |
| | Plating bath | (A/dm²) | time (sec) | (μm) | (μm) | (μm) | surface |
| A4-1 | Cu: 20 g/L, | 25 | 0.8 | 0.35 | 0.05 | 0.08 | ◯ |
| A4-2 | Ni: 5 g/L, | | 1.5 | 0.38 | 0.07 | 0.11 | ⊚ |
| A4-3 | P: 1 g/L, | | 2.5 | 0.56 | 0.1 | 0.19 | ⊚ |
| | pH; 2, | | | | | | |
| | Temperature: 30° C. | | | | | | |
| A4-4 | Cu: 10 g/L, | 60 | 0.8 | 0.61 | 0.12 | 0.21 | ⊚ |
| A4-5 | H2SO4: 50 g/L, | | 4 | 2.43 | 0.32 | 0.76 | ⊚ |
| A4-6 | Temperature: 25° C. | | 7 | 3.34 | 0.54 | 0.93 | ⊚ |
| A4-7 | Ni: 30 g/L, | 1 | 15 | 0.54 | 0.09 | 0.12 | ⊚ |
| A4-8 | Zn: 10 g/L, | 1.5 | 10 | 0.57 | 0.1 | 0.13 | ⊚ |
| B4-1 | pH: 5 | 2 | 8 | 0.36 | 0.05 | 0.09 | ◯ |
| | Temperature: 40° C. | | | | | | |
| B4-2 | No surface treatment | — | — | 0.58 | 0.07 | 0.09 | X |
| B4-3 | | | | 0.58 | 0.07 | 0.09 | X |
| B4-4 | | | | 0.55 | 0.06 | 0.08 | X |
| B4-5 | | | | 0.54 | 0.06 | 0.08 | X |

In Experimental Examples where the Sv was in the range of the present invention, good visibility and good yield were achieved.

In Experimental Examples where other surface was surface treated, the occurrence of wrinkles and stripes on the other surface of a copper foil was well suppressed by double-sided lamination.

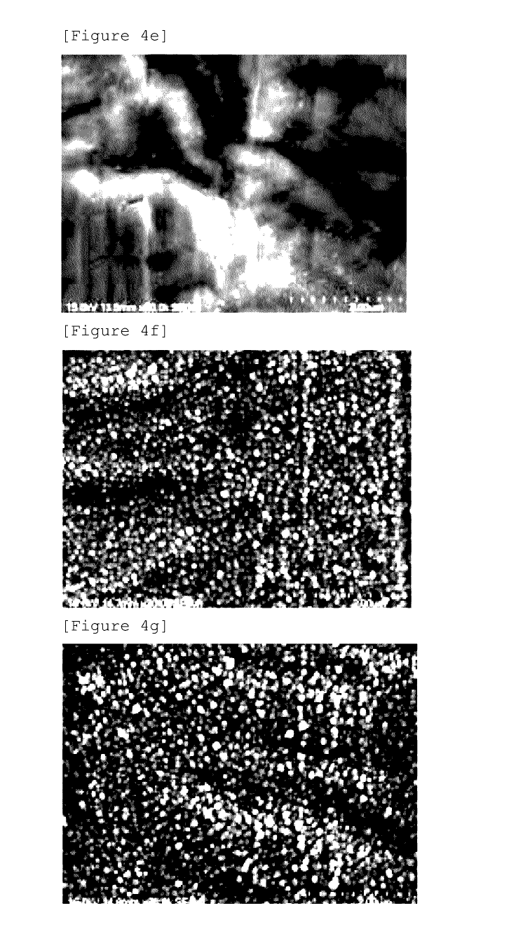

The SEM observation photographs of the copper foil surfaces in Experimental Example B3-1, Experimental Example A3-1, Experimental Example A3-2, Experimental Example A3-3, Experimental Example A3-4, Experimental Example A3-5, Experimental Example A3-6, Experimental Example A3-7, Experimental Example A3-8, Experimental Example A3-9, Experimental Example B3-2, and Experimental Example B3-3 for the evaluation of Rz are shown in FIGS. 4(a), 4(b), 4(c), 4 (d), 4(e), 4(f), 4(g), 4(h), 4(i), 4(j), 4(k), and 4(l), respectively.

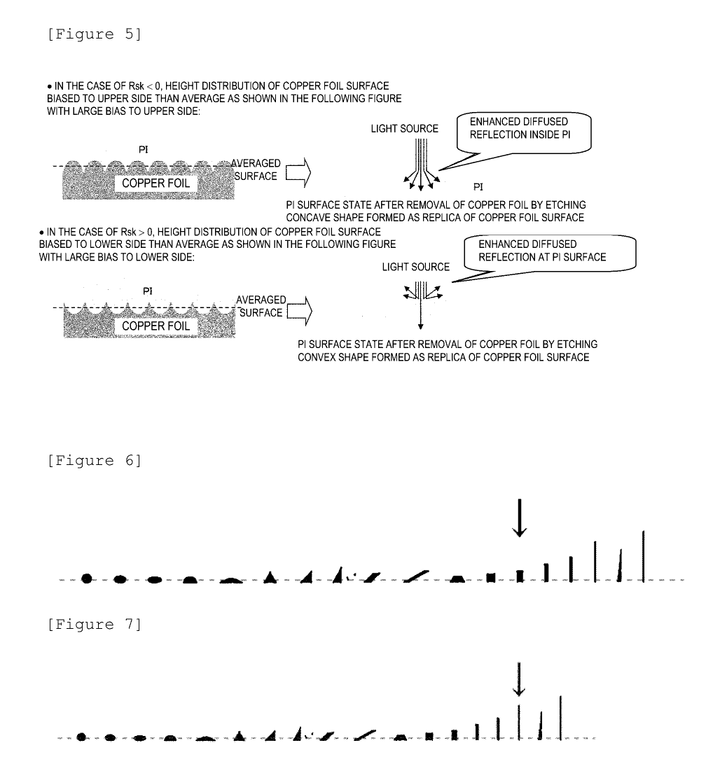

In Examples, the width of the mark were changed from 0.3 mm to 0.16 mm (a mark arranged thirdly closer to the description 0.5 having an area of 0.5 mm² in the sheet of dirt (mark indicated by arrow in FIG. 7)) for the same measurement of ΔB and t1, t2, Sv. As a result, the same values as for the mark having a width of 0.3 mm were obtained in any of the ΔB and t1, t2, Sv.

Furthermore, in Examples, the “top average Bt of brightness curve” representing the average of brightness measured at 5 spots at intervals of 30 μm from a position 50 μm away from the end position of both sides of the mark (total 10 spots on both sides) was changed to the average of brightness measured at 5 spots at intervals of 30 μm from a position 100 μm away, from a position 300 μm away, and from a position 500 μm away, from the end position of both sides of the mark (total 10 spots on both sides), respectively for the same measurement of ΔB and t1, t2, Sv. As a result, the same values as for the “top average Bt of brightness curve” representing the average of brightness measured at 5 spots at intervals of 30 μm from a position 50 μm away from the end position of both sides of the mark (total 10 spots on both sides) were obtained in any of the ΔB and t1, t2, Sv.

The same copper foil as in Experimental Examples above was used and both surfaces thereof were surface treated under the same conditions as those in the surface treatment of one surface so as to produce a surface treated copper foil. The surface treated copper foil was used for the evaluations, and the evaluation results of both surfaces were the same as those of one surface in each Experimental Example. In the case that a copper foil was subjected to electrolytic polishing or chemical polishing, both surfaces were subjected to electrolytic polishing or chemical polishing and then surface treated. In Experimental Example A1-27, Experimental Example B1-12, and Experimental Example A2-4, a glossy surface (a surface in contact with a drum in manufacturing of an electrolyte copper foil) of a copper foil was subjected to electrolytic polishing and/or chemical polishing so as to have the same TD roughness Rz and glossiness as those of a deposition surface, and then was subjected to a predetermined surface treatment or formation of an interlayer and the like.

In the case that both surfaces of a copper foil are surface treated, for example, roughening treated, both surfaces may be simultaneously surface treated or one surface and other surface may be separately surface treated. In the case that both surfaces are simultaneously surface treated, both surfaces of a copper foil may be surface treated with a surface treatment device (plating device) provided with an anode. In the present Experimental Examples, both surfaces were simultaneously surface treated.

All roughening treated copper foil surfaces in respective Experimental Examples had a TD ten-spot average roughness Rz measured with a laser microscope using laser light having a wavelength of 405 nm, of 0.35 μm or more. In addition, all roughening treated copper foil surfaces in respective Experimental Examples had a TD arithmetic average roughness Ra measured with a laser microscope using laser light having a wavelength of 405 nm, of 0.05 μm or more. Moreover, all roughening treated copper foil surfaces in respective Experimental Examples had a TD root mean square height Rq measured with a laser microscope using laser light having a wavelength of 405 nm, of 0.08 μm or more.

1. A surface treated copper foil having one surface and other surface each surface treated,
wherein an Sv defined by the following expression (1) is 3.5 or more based on a brightness curve:
Sv=(ΔB×0.1)/(t1−t2) (1)
wherein the brightness curve is obtained, after laminating one surface of the copper foil to each of both surfaces of a polyimide resin substrate, removing the copper foil on each of both surfaces by etching, placing a printed matter with a linear mark under the exposed polyimide resin substrate, and photographing the printed matter through the polyimide resin substrate with a CCD camera, from an observation spot versus brightness graph of measurement results of the brightness of the photographed image of the printed matter for the respective observation spots along the direction perpendicular to the extending direction of the observed linear mark, the difference between the top average Bt and the bottom average Bb in the brightness curve extending from an end of the mark to a portion without the mark is represented by ΔB (ΔB=Bt−Bb), and wherein t1 represents a value pointing the position of the intersection closest to the linear mark among the intersections of the brightness curve and Bt in the observation spot versus brightness graph, and t2 represents a value pointing the position of the intersection closest to the linear mark among the intersections of the brightness curve and 0.1ΔB in the range from the intersections of the brightness curve and Bt to a depth of 0.1ΔB with Bt as reference; and
wherein the surface treated other surface of the copper foil has a TD ten-spot average roughness Rz measured with a laser microscope using laser light having a wavelength of 405 nm, of 0.35 μm or more.

2. The surface treated copper foil according to claim 1, wherein the surface treated other surface of the copper foil has a TD arithmetic average roughness Ra measured with a laser microscope using laser light having a wavelength of 405 nm, of 0.05 μm or more.

3. A surface treated copper foil having one surface and other surface each surface treated,
wherein an Sv defined by the following expression (1) is 3.5 or more based on a brightness curve:
Sv=(ΔB×0.1)/(t1−t2) (1)
wherein the brightness curve is obtained, after laminating one surface of the copper foil to each of both surfaces of a polyimide resin substrate, removing the copper foil on each of both surfaces by etching, placing a printed matter with a linear mark under the exposed polyimide resin substrate, and photographing the printed matter through the polyimide resin substrate with a CCD camera, from an observation spot versus brightness graph of measurement results of the brightness of the photographed image of the printed matter for the respective observation spots along the direction perpendicular to the extending direction of the observed linear mark, the difference between the top average Bt and the bottom average Bb in the brightness curve extending from an end of the mark to a portion without the mark is represented by ΔB (ΔB=Bt−Bb), and wherein t1 represents a value pointing the position of the intersection closest to the linear mark among the intersections of the brightness curve and Bt in the observation spot versus brightness graph, and t2 represents a value pointing the position of the intersection closest to the linear mark among the intersections of the brightness curve and 0.1ΔB in the range from the intersections of the brightness curve and Bt to a depth of 0.1ΔB with Bt as reference; and
wherein the surface treated other surface of the copper foil has a TD arithmetic average roughness Ra measured with a laser microscope using laser light having a wavelength of 405 nm, of 0.05 μm or more.

4. The surface treated copper foil according to claim 1, wherein the surface treated other surface of the copper foil has a TD root mean square height Rq measured with a laser microscope using laser light having a wavelength of 405 nm, of 0.08 μm or more.

5. A surface treated copper foil having one surface and other surface each surface treated,
wherein an Sv defined by the following expression (1) is 3.5 or more based on a brightness curve:
Sv=(ΔB×0.1)/(t1−t2) (1)
wherein the brightness curve is obtained, after laminating one surface of the copper foil to each of both surfaces of a polyimide resin substrate, removing the copper foil on each of both surfaces by etching, placing a printed matter with a linear mark under the exposed polyimide resin substrate, and photographing the printed matter through the polyimide resin substrate with a CCD camera, from an observation spot versus brightness graph of measurement results of the brightness of the photographed image of the printed matter for the respective observation spots along the direction perpendicular to the extending direction of the observed linear mark, the difference between the top average Bt and the bottom average Bb in the brightness curve extending from an end of the mark to a portion without the mark is represented by ΔB (ΔB=Bt−Bb), and wherein t1 represents a value pointing the position of the intersection closest to the linear mark among the intersections of the brightness curve and Bt in the observation spot versus brightness graph, and t2 represents a value pointing the position of the intersection closest to the linear mark among the intersections of the brightness curve and 0.1ΔB in the range from the intersections of the brightness curve and Bt to a depth of 0.1ΔB with Bt as reference; and
wherein the surface treated other surface of the copper foil has a TD root mean square height Rq measured with a laser microscope using laser light having a wavelength of 405 nm, of 0.08 μm or more.

6. The surface treated copper foil according to claim 1, wherein the surface treatment of the other surface is a roughening treatment.

7. The surface treated copper foil according to claim 1, wherein the difference ΔB (ΔB=Bt−Bb) between the top average Bt and the bottom average Bb in the brightness curve extending from the end of the mark to the portion without the mark is 40 or more.

8. The surface treated copper foil according to claim 7, wherein ΔB in the observation spot versus brightness graph produced from the photographed image is 50 or more.

9. The surface treated copper foil according to claim 1, wherein the Sv defined by the expression (1) in the brightness curve is 3.9 or more.

10. The surface treated copper foil according to claim 9, wherein the Sv defined by the expression (1) in the brightness curve is 5.0 or more.

11. The surface treated copper foil according to claim 1, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and
the ratio A/B of the surface area A of the roughening treated surface to the area B of the roughening treated surface shown in the plan view from one surface side of the copper foil is 1.90 to 2.40.

12. The surface treated copper foil according to claim 11, wherein the MD glossiness at 60 degrees is 90 to 250%.

13. The surface treated copper foil according to claim 11, wherein the one surface has a TD ten-spot average roughness Rz measured with a contact roughness measuring tester, of 0.30 to 0.60 μm.

14. The surface treated copper foil according to claim 11, wherein the A/B is 2.00 to 2.20.

15. The surface treated copper foil according to claim 11, wherein the roughening treated surface has a ratio F of the MD glossiness at 60 degrees to the TD glossiness at 60 degrees (F=(MD glossiness at 60 degrees)/(TD glossiness at 60 degrees)) of 0.80 to 1.40.

16. The surface treated copper foil according to claim 15, wherein the roughening treated surface has a ratio F of the MD glossiness at 60 degrees to the TD glossiness at 60 degrees (F=(MD glossiness at 60 degrees)/(TD glossiness at 60 degrees)) of 0.90 to 1.35.

17. The surface treated copper foil according to claim 1, wherein the one surface has a root mean square height Rq of 0.14 to 0.63 μm.

18. The surface treated copper foil according to claim 17, wherein the one surface has a root mean square height Rq of 0.25 to 0.60 μm.

19. The surface treated copper foil according to claim 1, wherein the one surface has a skewness Rsk of −0.35 to 0.53 based on JIS B 0601-2001.

20. The surface treated copper foil according to claim 19, wherein the one surface has a skewness Rsk of −0.30 to 0.39.

21. The surface treated copper foil according to claim 1, wherein the ratio E/G of the volume E of the projection portion of the one surface to the surface area G of the one surface shown in plan view is 2.11 to 23.91.

22. The surface treated copper foil according to claim 21, wherein the ratio E/G is 2.95 to 21.42.

23. The surface treated copper foil according to claim 1, wherein the one surface has a TD ten-spot average roughness Rz measured with a contact roughness measuring tester, of 0.20 to 0.64 μm.

24. The surface treated copper foil according to claim 23, wherein the one surface has a TD ten-spot average roughness Rz measured with a contact roughness measuring tester, of 0.40 to 0.62 μm.

25. The surface treated copper foil according to claim 1, wherein the D/C of the three-dimensional surface area D to the two-dimensional surface area (the surface area of the surface shown in plan view) C of the one surface is 1.0 to 1.7.

26. The surface treated copper foil according to claim 25, wherein the D/C is 1.0 to 1.6.

27. A copper clad laminate comprising a lamination of the surface treated copper foil according to claim 1 and a resin substrate.

28. A printed wiring board comprising the surface treated copper foil according to claim 1.

29. An electronic apparatus comprising the printed wiring board according to claim 28.

30. A method for manufacturing a printed wiring board having two or more connected printed wiring boards comprising connecting two or more of the printed wiring boards according to claim 28.

31. A method for manufacturing a printed wiring board having two or more connected printed wiring boards comprising at least the step of connecting at least one printed wiring board according to claim 28 to another printed wiring board according to claim 28 or to a printed wiring board other than the printed wiring board according to claim 28.

32. (canceled)

33. A method for manufacturing a printed wiring board, comprising the step of connecting the printed wiring board according to claim 28 to a component.

34. A method for manufacturing a printed wiring board having two or more connected printed wiring boards, comprising at least
the step of connecting at least one printed wiring board according to claim 28 to another printed wiring board according to claim 28 or a printed wiring board other than the printed wiring board according to claim 28, and
the step of connecting a printed wiring board having two or more of the connected printed wiring boards according to claim 28 or the printed wiring boards manufactured by a method for manufacturing a printed wiring board having two or more connected printed wiring boards comprising at least the step of connecting at least one printed wiring board according to claim 28 to another printed wiring board according to claim 28 or to a printed wiring board other than the printed wiring board according to claim 28, to a component.

35.-48. (canceled)

49. The surface treated copper foil according to claim 2, wherein the surface treated other surface of the copper foil has a TD root mean square height Rq measured with a laser microscope using laser light having a wavelength of 405 nm, of 0.08 μm or more.

50. The surface treated copper foil according to claim 3, wherein the surface treated other surface of the copper foil has a TD root mean square height Rq measured with a laser microscope using laser light having a wavelength of 405 nm, of 0.08 μm or more.

51. The surface treated copper foil according to claim 1, satisfying one, two, or three items of the following items (1) to (3);
(1) the surface treated other surface of the copper foil has a TD ten-spot average roughness Rz measured with a laser microscope using laser light having a wavelength of 405 nm, of 0.40 μm or more,
(2) the surface treated other surface of the copper foil has a TD arithmetic average roughness Ra measured with a laser microscope using laser light having a wavelength of 405 nm, of 0.08 μm or more,
(3) the surface treated other surface of the copper foil has a TD root mean square height Rq measured with a laser microscope using laser light having a wavelength of 405 nm, of 0.10 μm or more.

52. The surface treated copper foil according to claim 3, satisfying one, two, or three items of the following items (1) to (3);
(1) the surface treated other surface of the copper foil has a TD ten-spot average roughness Rz measured with a laser microscope using laser light having a wavelength of 405 nm, of 0.40 μm or more,
(2) the surface treated other surface of the copper foil has a TD arithmetic average roughness Ra measured with a laser microscope using laser light having a wavelength of 405 nm, of 0.08 μm or more,
(3) the surface treated other surface of the copper foil has a TD root mean square height Rq measured with a laser microscope using laser light having a wavelength of 405 nm, of 0.10 μm or more.

53. The surface treated copper foil according to claim 5, satisfying one, two, or three items of the following items (1) to (3);
(1) the surface treated other surface of the copper foil has a TD ten-spot average roughness Rz measured with a laser microscope using laser light having a wavelength of 405 nm, of 0.40 μm or more,
(2) the surface treated other surface of the copper foil has a TD arithmetic average roughness Ra measured with a laser microscope using laser light having a wavelength of 405 nm, of 0.08 μm or more,
(3) the surface treated other surface of the copper foil has a TD root mean square height Rq measured with a laser microscope using laser light having a wavelength of 405 nm, of 0.10 μm or more.

54. The surface treated copper foil according to claim 2, wherein the surface treatment of the other surface is a roughening treatment.

55. The surface treated copper foil according to claim 3, wherein the surface treatment of the other surface is a roughening treatment.

56. The surface treated copper foil according to claim 4, wherein the surface treatment of the other surface is a roughening treatment.

57. The surface treated copper foil according to claim 49, wherein the surface treatment of the other surface is a roughening treatment.

58. The surface treated copper foil according to claim 50, wherein the surface treatment of the other surface is a roughening treatment.

59. The surface treated copper foil according to claim 5, wherein the surface treatment of the other surface is a roughening treatment.

60. The surface treated copper foil according to claim 2, wherein the difference ΔB (ΔB=Bt−Bb) between the top average Bt and the bottom average Bb in the brightness curve extending from the end of the mark to the portion without the mark is 40 or more.

61. The surface treated copper foil according to claim 3, wherein the difference ΔB (ΔB=Bt−Bb) between the top average Bt and the bottom average Bb in the brightness curve extending from the end of the mark to the portion without the mark is 40 or more.

62. The surface treated copper foil according to claim 4, wherein the difference ΔB (ΔB=Bt−Bb) between the top average Bt and the bottom average Bb in the brightness curve extending from the end of the mark to the portion without the mark is 40 or more.

63. The surface treated copper foil according to claim 49, wherein the difference ΔB (ΔB=Bt−Bb) between the top average Bt and the bottom average Bb in the brightness curve extending from the end of the mark to the portion without the mark is 40 or more.

64. The surface treated copper foil according to claim 50, wherein the difference ΔB (ΔB=Bt−Bb) between the top average Bt and the bottom average Bb in the brightness curve extending from the end of the mark to the portion without the mark is 40 or more.

65. The surface treated copper foil according to claim 5, wherein the difference ΔB (ΔB=Bt−Bb) between the top average Bt and the bottom average Bb in the brightness curve extending from the end of the mark to the portion without the mark is 40 or more.

66. The surface treated copper foil according to claim 2, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughening treated surface to the area B of the roughening treated surface shown in the plan view from one surface side of the copper foil is 1.90 to 2.40.

67. The surface treated copper foil according to claim 3, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughening treated surface to the area B of the roughening treated surface shown in the plan view from one surface side of the copper foil is 1.90 to 2.40.

68. The surface treated copper foil according to claim 4, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughening treated surface to the area B of the roughening treated surface shown in the plan view from one surface side of the copper foil is 1.90 to 2.40.

69. The surface treated copper foil according to claim 49, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughening treated surface to the area B of the roughening treated surface shown in the plan view from one surface side of the copper foil is 1.90 to 2.40.

70. The surface treated copper foil according to claim 50, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughening treated surface to the area B of the roughening treated surface shown in the plan view from one surface side of the copper foil is 1.90 to 2.40.

71. The surface treated copper foil according to claim 5, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughening treated surface to the area B of the roughening treated surface shown in the plan view from one surface side of the copper foil is 1.90 to 2.40.

72. The surface treated copper foil according to claim 7, wherein the surface treatment of the one surface is a roughening treatment, the roughening treated surface has a TD ten-spot average roughness Rz measured with a contact roughness measuring tester, of 0.20 to 0.80 μm, the roughening treated surface has an MD glossiness at 60 degrees of 76 to 350%, and the ratio A/B of the surface area A of the roughening treated surface to the area B of the roughening treated surface shown in the plan view from one surface side of the copper foil is 1.90 to 2.40.

73. The surface treated copper foil according to claim 2, wherein the one surface has a root mean square height Rq of 0.14 to 0.63 μm.

74. The surface treated copper foil according to claim 3, wherein the one surface has a root mean square height Rq of 0.14 to 0.63 μm.

75. The surface treated copper foil according to claim 4, wherein the one surface has a root mean square height Rq of 0.14 to 0.63 μm.

76. The surface treated copper foil according to claim 49, wherein the one surface has a root mean square height Rq of 0.14 to 0.63 μm.

77. The surface treated copper foil according to claim 50, wherein the one surface has a root mean square height Rq of 0.14 to 0.63 μm.

78. The surface treated copper foil according to claim 5, wherein the one surface has a root mean square height Rq of 0.14 to 0.63 μm.

79. The surface treated copper foil according to claim 72, wherein the one surface has a root mean square height Rq of 0.14 to 0.63 μm.

80. The surface treated copper foil according to claim 2, wherein the one surface has a skewness Rsk of −0.35 to 0.53 based on JIS B 0601-2001.

81. The surface treated copper foil according to claim 3, wherein the one surface has a skewness Rsk of −0.35 to 0.53 based on JIS B 0601-2001.

82. The surface treated copper foil according to claim 4, wherein the one surface has a skewness Rsk of −0.35 to 0.53 based on JIS B 0601-2001.

83. The surface treated copper foil according to claim 49, wherein the one surface has a skewness Rsk of −0.35 to 0.53 based on JIS B 0601-2001.

84. The surface treated copper foil according to claim 50, wherein the one surface has a skewness Rsk of −0.35 to 0.53 based on JIS B 0601-2001.

85. The surface treated copper foil according to claim 5, wherein the one surface has a skewness Rsk of −0.35 to 0.53 based on JIS B 0601-2001.

86. The surface treated copper foil according to claim 79, wherein the one surface has a skewness Rsk of −0.35 to 0.53 based on JIS B 0601-2001.

87. The surface treated copper foil according to claim 2, wherein the ratio E/G of the volume E of the projection portion of the one surface to the surface area G of the one surface shown in plan view is 2.11 to 23.91.

88. The surface treated copper foil according to claim 3, wherein the ratio E/G of the volume E of the projection portion of the one surface to the surface area G of the one surface shown in plan view is 2.11 to 23.91.

89. The surface treated copper foil according to claim 4, wherein the ratio E/G of the volume E of the projection portion of the one surface to the surface area G of the one surface shown in plan view is 2.11 to 23.91.

90. The surface treated copper foil according to claim 49, wherein the ratio E/G of the volume E of the projection portion of the one surface to the surface area G of the one surface shown in plan view is 2.11 to 23.91.

91. The surface treated copper foil according to claim 50, wherein the ratio E/G of the volume E of the projection portion of the one surface to the surface area G of the one surface shown in plan view is 2.11 to 23.91.

92. The surface treated copper foil according to claim 5, wherein the ratio E/G of the volume E of the projection portion of the one surface to the surface area G of the one surface shown in plan view is 2.11 to 23.91.

93. The surface treated copper foil according to claim 86, wherein the ratio E/G of the volume E of the projection portion of the one surface to the surface area G of the one surface shown in plan view is 2.11 to 23.91.

94. The surface treated copper foil according to claim 3, wherein the one surface has a TD ten-spot average roughness Rz measured with a contact roughness measuring tester, of 0.20 to 0.64 μm.

95. The surface treated copper foil according to claim 5, wherein the one surface has a TD ten-spot average roughness Rz measured with a contact roughness measuring tester, of 0.20 to 0.64 μm.

96. The surface treated copper foil according to claim 3, wherein the D/C of the three-dimensional surface area D to the two-dimensional surface area (the surface area of the surface shown in plan view) C of the one surface is 1.0 to 1.7.

97. The surface treated copper foil according to claim 5, wherein the D/C of the three-dimensional surface area D to the two-dimensional surface area (the surface area of the surface shown in plan view) C of the one surface is 1.0 to 1.7.

98. A copper clad laminate comprising a lamination of the surface treated copper foil according to claim 3 and a resin substrate.

99. A copper clad laminate comprising a lamination of the surface treated copper foil according to claim 5 and a resin substrate.

100. A printed wiring board comprising the surface treated copper foil according to claim 3.

101. A printed wiring board comprising the surface treated copper foil according to claim 5.
